(19) United States
(12) Patent Application Publication
(10) Pub. No.: US 2025/0318175 A1
(43) Pub. Date: Oct. 9, 2025

(54) SEMICONDUCTOR DEVICE AND ELECTRONIC APPARATUS

(71) Applicant: SONY SEMICONDUCTOR SOLUTIONS CORPORATION, KANAGAWA (JP)

(72) Inventors: RYOHEI TAKAYANAGI, KANAGAWA (JP); NAOKI SAKA, KANAGAWA (JP)

(21) Appl. No.: 18/865,026

(22) PCT Filed: Apr. 12, 2023
(86) PCT No.: PCT/JP2023/014806

§ 371 Date: Nov. 12, 2024

(30) Foreign Application Priority Data
May 20, 2022 (JP) 2022-082693

(51) Int. Cl. H10D 30/62; H10D 30/01; H10D 62/10; H10D 62/40; H10D 64/23; H10F 39/18

(52) U.S. Cl. CPC H10D 30/62; H10D 62/102; H10D 62/40; H10D 64/256; H10D 64/258; H10F 39/182; H10D 30/024; H10D 62/124

(57) ABSTRACT

Transconductance (gm) of a field effect transistor is improved. A semiconductor device includes: a semiconductor portion having an island shape having an upper surface portion and a side surface portion; a field effect transistor having a gate electrode provided on the semiconductor portion with a gate insulating film interposed therebetween; an insulating layer covering the field effect transistor; and a contact electrode provided on the insulating layer to overlap the semiconductor portion outside the gate electrode in plan view. Then, the contact electrode is connected to the upper surface portion and the side surface portion of the semiconductor portion.

### TECHNICAL FIELD

The present technology (technology according to the present disclosure) relates to a semiconductor device and an electronic apparatus, and particularly relates to a technology effective when applied to a semiconductor device having a fin-type field effect transistor and an electronic apparatus including the same.

### BACKGROUND ART

As a semiconductor device, for example, a solid-state imaging device called a CMOS image sensor is known. The CMOS image sensor includes a pixel circuit (readout circuit) that converts signal charges photoelectrically converted by the photoelectric conversion element into a pixel signal and outputs the pixel signal. The pixel circuit includes pixel transistors such as an amplification transistor, a selection transistor, and a reset transistor.

Meanwhile, as a field effect transistor mounted on a semiconductor device, a fin-type field effect transistor (Fin-FET) is known in which a gate electrode is provided in an island-shaped semiconductor portion (fin portion) with a gate insulating film interposed therebetween, and a pair of main electrode regions functioning as a source region and a drain region is provided in the semiconductor portion on both sides in a gate length direction of the gate electrode. Since this fin-type field effect transistor can improve short channel characteristics and shorten a gate length to realize a necessary operation, it is possible to miniaturize a planar size and it is useful for high integration.

Wiring on the insulating layer is electrically connected to the pair of main electrode regions of the fin-type field effect transistor via a contact electrode provided in the insulating layer covering the field effect transistor. The contact electrode is connected to the upper surface portion of the semiconductor portion.

Patent Document 1 discloses a solid-state imaging device in which an amplification transistor included in a pixel circuit is configured by a fin-type field effect transistor.

In addition, Non-Patent Document 1 discloses a field effect transistor having an SOI-Fin structure.

### CITATION LIST

### Patent Document

Patent Document 1: Japanese Patent Application Laid-Open No. 2021-034435

### Non-Patent Document

Non-Patent Document 1: W. Xiong, et. al., “Full/partial depletion effects in FinFETs”, IEEE International SOI Conference, 10/4, 2004

### SUMMARY OF THE INVENTION

### Problems to be Solved by the Invention

By the way, with miniaturization of fin-type field effect transistors, the width in the lateral direction of the semiconductor portion and the diameter (width of thickness) of the contact electrode tend to decrease, and the contact resistance between the semiconductor portion and the contact electrode increases. In the generation in which the diameter (width) of the contact electrode is miniaturized, the influence of the parasitic resistance by the contact resistance increases, and the transconductance (gm) of the fin-type field effect transistor decreases.

An object of the present technology is to improve transconductance (gm) of a transistor.

### Solutions to Problems

(1) A semiconductor device according to one aspect of the present technology includes:
a semiconductor portion having an island shape having an upper surface portion and a side surface portion;
a field effect transistor having a gate electrode provided on the semiconductor portion with a gate insulating film interposed therebetween;
an insulating layer covering the field effect transistor; and
a contact electrode provided on the insulating layer to overlap the semiconductor portion outside the gate electrode in plan view. Then, the contact electrode is connected to the upper surface portion and the side surface portion of the semiconductor portion.
(2) A semiconductor device according to another aspect of the present technology includes:
a semiconductor portion having an island shape having an upper surface portion and a side surface portion;
a field effect transistor having a gate electrode provided on the semiconductor portion with a gate insulating film interposed therebetween;
an insulating layer covering the field effect transistor; and
a contact electrode provided on the insulating layer to overlap the semiconductor portion outside the gate electrode in plan view. Then, the contact electrode is connected to the upper surface portion and the side surface portion of the semiconductor portion, and is formed in a same layer as the gate electrode.
(3) An electronic apparatus according to another aspect of the present technology includes: the semiconductor device; an optical system that forms an image of image light from a subject on the semiconductor device; and a signal processing circuit that performs signal processing on a signal output from the semiconductor device.

### BRIEF DESCRIPTION OF DRAWINGS

FIG. 1 is a schematic plan view illustrating a configuration example of a semiconductor device according to a first embodiment of the present technology.

FIG. 2 is a schematic longitudinal cross-sectional view illustrating a longitudinal cross-sectional structure taken along a cutting line a1-a1 in FIG. 1.

FIG. 3 is a schematic longitudinal cross-sectional view illustrating a longitudinal cross-sectional structure taken along a cutting line b1-b1 in FIG. 1.

FIG. 4 is a schematic longitudinal cross-sectional view illustrating a longitudinal cross-sectional structure taken along a cutting line c1-c1 in FIG. 1.

FIG. 5 is a schematic plan view illustrating a step of the method for manufacturing the semiconductor device according to the first embodiment of the present technology.

FIG. 6A is a schematic longitudinal cross-sectional view illustrating a longitudinal cross-sectional structure taken along a cutting line a5-a5 in FIG. 5.

FIG. 6B is a schematic longitudinal cross-sectional view illustrating a longitudinal cross-sectional structure taken along a cutting line b5-b5 in FIG. 5.

FIG. 7 is a schematic plan view illustrating a step subsequent to FIG. 5.

FIG. 8A is a schematic longitudinal cross-sectional view illustrating a longitudinal cross-sectional structure taken along a cutting line a7-a7 in FIG. 7.

FIG. 8B is a schematic longitudinal cross-sectional view illustrating a longitudinal cross-sectional structure taken along a cutting line b7-b7 in FIG. 7.

FIG. 9 is a schematic plan view illustrating a step subsequent to FIG. 7.

FIG. 10A is a schematic longitudinal cross-sectional view illustrating a longitudinal cross-sectional structure taken along a cutting line a9-a9 in FIG. 9.

FIG. 10B is a schematic longitudinal cross-sectional view illustrating a longitudinal cross-sectional structure taken along a cutting line b9-b9 in FIG. 9.

FIG. 11 is a schematic plan view illustrating a step subsequent to FIG. 9.

FIG. 12A is a schematic longitudinal cross-sectional view illustrating a longitudinal cross-sectional structure taken along a cutting line a11-a11 in FIG. 11.

FIG. 12B is a schematic longitudinal cross-sectional view illustrating a longitudinal cross-sectional structure taken along a cutting line c11-c11 in FIG. 11.

FIG. 13 is a schematic plan view illustrating a step subsequent to FIG. 11.

FIG. 14A is a schematic longitudinal cross-sectional view illustrating a longitudinal cross-sectional structure taken along a cutting line a13-a13 in FIG. 13.

FIG. 14B is a schematic longitudinal cross-sectional view illustrating a longitudinal cross-sectional structure taken along a cutting line c13-c13 in FIG. 13.

FIG. 15 is a schematic plan view illustrating a step subsequent to FIG. 13.

FIG. 16A is a schematic longitudinal cross-sectional view illustrating a longitudinal cross-sectional structure taken along a cutting line a15-a15 in FIG. 15.

FIG. 16B is a schematic longitudinal cross-sectional view illustrating a longitudinal cross-sectional structure taken along a cutting line c15-c15 in FIG. 15.

FIG. 17 is a schematic plan view illustrating a step subsequent to FIG. 15.

FIG. 18A is a schematic longitudinal cross-sectional view illustrating a longitudinal cross-sectional structure taken along a cutting line a17-a17 in FIG. 17.

FIG. 18B is a schematic longitudinal cross-sectional view illustrating a longitudinal cross-sectional structure taken along a cutting line c17-c17 in FIG. 17.

FIG. 19 is a schematic plan view illustrating a step subsequent to FIG. 17.

FIG. 20A is a schematic longitudinal cross-sectional view illustrating a longitudinal cross-sectional structure taken along a cutting line a19-a19 in FIG. 19.

FIG. 20B is a schematic longitudinal cross-sectional view illustrating a longitudinal cross-sectional structure taken along a cutting line c19-c19 in FIG. 19.

FIG. 21 is a schematic plan view illustrating a step subsequent to FIG. 19.

FIG. 22A is a schematic longitudinal cross-sectional view illustrating a longitudinal cross-sectional structure taken along a cutting line a21-a21 in FIG. 21.

FIG. 22B is a schematic longitudinal cross-sectional view illustrating a longitudinal cross-sectional structure taken along a cutting line c21-c21 in FIG. 21.

FIG. 23 is a schematic plan view illustrating a schematic configuration of a semiconductor device according to a second embodiment of the present technology.

FIG. 24 is a schematic longitudinal cross-sectional view illustrating a longitudinal cross-sectional structure taken along a cutting line a23-a23 in FIG. 23.

FIG. 25 is a schematic longitudinal cross-sectional view illustrating a longitudinal cross-sectional structure taken along a cutting line c23-c23 in FIG. 23.

FIG. 26 is a schematic plan view illustrating two semiconductor portions and two field effect transistors arranged in series in the semiconductor device according to the first embodiment of the present technology.

FIG. 27 is a schematic longitudinal cross-sectional view illustrating a modification of the second embodiment of the present technology.

FIG. 28 is a schematic plan view illustrating a schematic configuration of a semiconductor device according to a third embodiment of the present technology.

FIG. 29 is a schematic longitudinal cross-sectional view illustrating a longitudinal cross-sectional structure taken along a cutting line c28-c28 in FIG. 28.

FIG. 30 is a schematic plan view illustrating a first modification of the third embodiment of the present technology.

FIG. 31 is a schematic plan view illustrating a second modification of the third embodiment of the present technology.

FIG. 32 is a schematic cross-sectional view illustrating a third modification of the third embodiment of the present technology.

FIG. 33 is a schematic plan view illustrating a schematic configuration of a semiconductor device according to a fourth embodiment of the present technology.

FIG. 34 is a schematic longitudinal cross-sectional view illustrating a longitudinal cross-sectional structure taken along a cutting line b33-b33 in FIG. 33.

FIG. 35 is a schematic longitudinal cross-sectional view illustrating a longitudinal cross-sectional structure taken along a cutting line c33-c33 in FIG. 33.

FIG. 36 is a schematic plan layout diagram illustrating a configuration example of a solid-state imaging device according to a fifth embodiment of the present technology.

FIG. 37 is a block diagram illustrating a configuration example of the solid-state imaging device according to the fifth embodiment of the present technology.

FIG. 38 is an equivalent circuit diagram illustrating a configuration example of a pixel and a pixel circuit of the solid-state imaging device according to the fifth embodiment of the present technology.

FIG. 39 is a schematic longitudinal cross-sectional view illustrating a longitudinal cross-sectional structure of a pixel array unit in FIG. 36.

FIG. 40 is a schematic plan view illustrating a configuration example of a semiconductor device according to a sixth embodiment of the present technology.

FIG. 41 is a schematic longitudinal cross-sectional view illustrating a longitudinal cross-sectional structure taken along a cutting line a40-a40 in FIG. 40.

FIG. 41A is a schematic longitudinal cross-sectional view illustrating a part of FIG. 41 in an enlarged manner.

FIG. 42 is a schematic longitudinal cross-sectional view illustrating a longitudinal cross-sectional structure taken along a cutting line b40-b40 in FIG. 40.

FIG. 43 is a schematic longitudinal cross-sectional view illustrating a longitudinal cross-sectional structure taken along a cutting line c40-c40 in FIG. 40.

FIG. 44 is a schematic plan view illustrating a step of the method for manufacturing the semiconductor device according to the sixth embodiment of the present technology.

FIG. 45A is a schematic longitudinal cross-sectional view illustrating a longitudinal cross-sectional structure taken along a cutting line a44-a44 in FIG. 44.

FIG. 45B is a schematic longitudinal cross-sectional view illustrating a longitudinal cross-sectional structure taken along a cutting line b44-b44 in FIG. 44.

FIG. 46 is a schematic plan view illustrating a step subsequent to FIG. 44.

FIG. 47A is a schematic longitudinal cross-sectional view illustrating a longitudinal cross-sectional structure taken along a cutting line a46-a46 in FIG. 46.

FIG. 47B is a schematic longitudinal cross-sectional view illustrating a longitudinal cross-sectional structure taken along a cutting line b46-b46 in FIG. 46.

FIG. 47C is a schematic longitudinal cross-sectional view illustrating a longitudinal cross-sectional structure taken along a cutting line c46-c46 in FIG. 46.

FIG. 48A is a diagram illustrating a step subsequent to FIG. 46, and is a schematic longitudinal cross-sectional view illustrating a longitudinal cross-sectional structure at the same position as a cutting line a46-a46 in FIG. 46.

FIG. 48B is a diagram illustrating a step subsequent to FIG. 46, and is a schematic longitudinal cross-sectional view illustrating a longitudinal cross-sectional structure at the same position as a cutting line b46-b46 in FIG. 46.

FIG. 48C is a diagram illustrating a step subsequent to FIG. 46, and is a schematic longitudinal cross-sectional view illustrating a longitudinal cross-sectional structure at the same position as a cutting line c46-c46 in FIG. 46.

FIG. 49A is a diagram illustrating a step subsequent to FIG. 48A, and is a schematic longitudinal cross-sectional view illustrating a longitudinal cross-sectional structure at the same position as a cutting line a46-a46 in FIG. 46.

FIG. 49B is a diagram illustrating a step subsequent to FIG. 48B, and is a schematic longitudinal cross-sectional view illustrating a longitudinal cross-sectional structure at the same position as a cutting line b46-b46 in FIG. 46.

FIG. 49C is a diagram illustrating a step subsequent to FIG. 48C, and is a schematic longitudinal cross-sectional view illustrating a longitudinal cross-sectional structure at the same position as a cutting line c46-c46 in FIG. 46.

FIG. 50 is a schematic plan view illustrating a step subsequent to FIG. 49A.

FIG. 51A is a schematic longitudinal cross-sectional view illustrating a longitudinal cross-sectional structure taken along a cutting line a50-a50 in FIG. 50.

FIG. 51B is a schematic longitudinal cross-sectional view illustrating a longitudinal cross-sectional structure taken along a cutting line b50-b50 in FIG. 50.

FIG. 51C is a schematic longitudinal cross-sectional view illustrating a longitudinal cross-sectional structure taken along a cutting line c50-c50 in FIG. 50.

FIG. 51D is a schematic longitudinal cross-sectional view in which a part of FIG. 51A is enlarged.

FIG. 51E is a schematic longitudinal cross-sectional view in which a part of FIG. 51C is enlarged.

FIG. 52 is a schematic plan view illustrating a step subsequent to FIG. 50.

FIG. 53A is a schematic longitudinal cross-sectional view illustrating a longitudinal cross-sectional structure taken along a cutting line a52-a52 in FIG. 52.

FIG. 53B is a schematic longitudinal cross-sectional view illustrating a longitudinal cross-sectional structure taken along a cutting line c52-c52 in FIG. 52.

FIG. 54A is a schematic cross-sectional view illustrating a granular oxide changed by heat treatment in the cross section of FIG. 53A.

FIG. 54B is a schematic cross-sectional view illustrating a granular oxide changed by heat treatment in the cross section of FIG. 53B.

FIG. 55 is a schematic plan view illustrating a step subsequent to FIG. 52.

FIG. 56A is a schematic longitudinal cross-sectional view illustrating a longitudinal cross-sectional structure taken along a cutting line a55-a55 in FIG. 55.

FIG. 56B is a schematic longitudinal cross-sectional view illustrating a longitudinal cross-sectional structure taken along a cutting line c55-c55 in FIG. 55.

FIG. 57 is a schematic plan view illustrating a step subsequent to FIG. 55.

FIG. 58A is a schematic longitudinal cross-sectional view illustrating a longitudinal cross-sectional structure taken along a cutting line a57-a57 in FIG. 57.

FIG. 58B is a schematic longitudinal cross-sectional view illustrating a longitudinal cross-sectional structure taken along a cutting line c57-c57 in FIG. 57.

FIG. 59 is a schematic plan view illustrating a step subsequent to FIG. 57.

FIG. 60A is a schematic longitudinal cross-sectional view illustrating a longitudinal cross-sectional structure taken along a cutting line a59-a59 in FIG. 59.

FIG. 60B is a schematic longitudinal cross-sectional view illustrating a longitudinal cross-sectional structure taken along a cutting line b59-b59 in FIG. 59.

FIG. 60C is a schematic longitudinal cross-sectional view illustrating a longitudinal cross-sectional structure taken along a cutting line c59-c59 in FIG. 59.

FIG. 61 is a diagram illustrating a step subsequent to FIG. 59, and is a schematic longitudinal cross-sectional view illustrating a longitudinal cross-sectional structure at the same position as a cutting line a59-a59 in FIG. 59.

FIG. 62 is a diagram illustrating a step subsequent to FIG. 61, and is a schematic longitudinal cross-sectional view illustrating a longitudinal cross-sectional structure at the same position as a cutting line a59-a59 in FIG. 59.

FIG. 63 is a schematic plan view illustrating a step subsequent to FIG. 62.

FIG. 64 is a schematic longitudinal cross-sectional view illustrating a longitudinal cross-sectional structure taken along a cutting line a63-a63 in FIG. 63.

FIG. 65 is a diagram illustrating a step subsequent to FIG. 63, and is a schematic longitudinal cross-sectional view illustrating a longitudinal cross-sectional structure at the same position as a cutting line a63-a63 in FIG. 63.

FIG. 66 is a diagram illustrating a step subsequent to FIG. 65, and is a schematic longitudinal cross-sectional view illustrating a longitudinal cross-sectional structure at the same position as a cutting line a63-a63 in FIG. 63.

FIG. 67 is a diagram illustrating a step subsequent to FIG. 66, and is a schematic longitudinal cross-sectional view illustrating a longitudinal cross-sectional structure at the same position as a cutting line a63-a63 in FIG. 63.

FIG. 68 is a diagram illustrating a step subsequent to FIG. 67, and is a schematic longitudinal cross-sectional view illustrating a longitudinal cross-sectional structure at the same position as a cutting line a63-a63 in FIG. 63.

FIG. 69 is a schematic plan view illustrating a first modification of the sixth embodiment of the present technology.

FIG. 70A is a schematic longitudinal cross-sectional view illustrating a longitudinal cross-sectional structure taken along a cutting line a69-a69 in FIG. 69.

FIG. 70B is a schematic longitudinal cross-sectional view illustrating a longitudinal cross-sectional structure taken along a cutting line c69-c69 in FIG. 69.

FIG. 71 is a schematic plan view illustrating a second modification of the sixth embodiment of the present technology.

FIG. 72 is a schematic longitudinal cross-sectional view illustrating a longitudinal cross-sectional structure taken along a cutting line a71-a71 in FIG. 71.

FIG. 73 is a schematic longitudinal cross-sectional view illustrating a third modification of the sixth embodiment of the present technology.

FIG. 74 is a schematic plan view illustrating a configuration example of a semiconductor device according to a seventh embodiment of the present technology.

FIG. 75 is a schematic longitudinal cross-sectional view illustrating a longitudinal cross-sectional structure taken along a cutting line a74-a74 in FIG. 74.

FIG. 76 is a schematic plan view illustrating a configuration example of a semiconductor device according to an eighth embodiment of the present technology.

FIG. 77 is a schematic plan view illustrating a modification of the eighth embodiment of the present technology.

FIG. 78 is a schematic longitudinal cross-sectional view illustrating a configuration example of a solid-state imaging device according to a ninth embodiment of the present technology.

FIG. 79 is a schematic plan view illustrating a configuration example of a semiconductor device according to a 10th embodiment of the present technology.

FIG. 80 is a schematic longitudinal cross-sectional view illustrating a longitudinal cross-sectional structure taken along a cutting line a79-a79 in FIG. 79.

FIG. 81 is a schematic longitudinal cross-sectional view illustrating a longitudinal cross-sectional structure taken along a cutting line b79-b79 in FIG. 79.

FIG. 82 is a schematic longitudinal cross-sectional view illustrating a longitudinal cross-sectional structure taken along a cutting line c79-c79 in FIG. 79.

FIG. 83 is a schematic plan view illustrating a step of the method for manufacturing the semiconductor device according to the 10th embodiment of the present technology.

FIG. 84 is a diagram illustrating a step of the method for manufacturing the semiconductor device according to the 10th embodiment of the present technology ((a) is a schematic cross-sectional view illustrating a longitudinal cross-sectional structure taken along a cutting line a83-a83 in FIG. 83, (b) is a schematic longitudinal cross-sectional view illustrating a longitudinal cross-sectional structure taken along a cutting line b83-b83 in FIG. 83, and (c) is a schematic longitudinal cross-sectional view illustrating a longitudinal cross-sectional structure taken along a cutting line c83-c83 in FIG. 83).

FIG. 85 is a diagram illustrating a step subsequent to FIGS. 83 and 84 ((a) is a schematic longitudinal cross-sectional view illustrating a longitudinal cross-sectional structure at the same position as a cutting line a83-a83 in FIG. 83, (b) is a schematic longitudinal cross-sectional view illustrating a longitudinal cross-sectional structure at the same position as a cutting line b83-b83 in FIG. 83, and (c) is a schematic longitudinal cross-sectional view illustrating a longitudinal cross-sectional structure at the same position as a cutting line c83-c83 in FIG. 83).

FIG. 86 is a schematic plan view illustrating a step subsequent to FIG. 85.

FIG. 87 is a diagram illustrating a longitudinal cross-sectional structure in FIG. 86 ((a) is a schematic longitudinal cross section illustrating a longitudinal cross-sectional structure taken along a cutting line a86-a86 in FIG. 86, (b) is a schematic longitudinal cross section illustrating a longitudinal cross-sectional structure taken along a cutting line b86-b86 in FIG. 86, and (c) is a schematic longitudinal cross section illustrating a longitudinal cross-sectional structure taken along a cutting line c86-c86 in FIG. 86).

FIG. 88 is a schematic plan view illustrating a step subsequent to FIG. 86.

FIG. 89 is a diagram illustrating a longitudinal cross-sectional structure in FIG. 88 ((a) is a schematic longitudinal cross section illustrating a longitudinal cross-sectional structure taken along a cutting line a88-a88 in FIG. 88, and (b) is a schematic longitudinal cross section illustrating a longitudinal cross-sectional structure taken along a cutting line c88-c88 in FIG. 88).

FIG. 90 is a schematic plan view illustrating a step subsequent to FIG. 88.

FIG. 91 is a diagram illustrating a longitudinal cross-sectional structure in FIG. 90 ((a) is a schematic longitudinal cross section illustrating a longitudinal cross-sectional structure taken along a cutting line a90-a90 in FIG. 90, and (b) is a schematic longitudinal cross section illustrating a longitudinal cross-sectional structure taken along a cutting line c90-c90 in FIG. 90).

FIG. 92 is a schematic plan view illustrating a step subsequent to FIG. 90.

FIG. 93 is a diagram illustrating a longitudinal cross-sectional structure in FIG. 92 ((a) is a schematic longitudinal cross section illustrating a longitudinal cross-sectional structure taken along a cutting line a92-a92 in FIG. 92, and (b) is a schematic longitudinal cross section illustrating a longitudinal cross-sectional structure taken along a cutting line c92-c92 in FIG. 92).

FIG. 94 is a schematic plan view illustrating a step subsequent to FIG. 92.

FIG. 95 is a diagram illustrating a longitudinal cross-sectional structure in FIG. 94 ((a) is a schematic longitudinal cross section illustrating a longitudinal cross-sectional structure taken along a cutting line a94-a94 in FIG. 94, (b) is a schematic longitudinal cross section illustrating a longitudinal cross-sectional structure taken along a cutting line b94-b94 in FIG. 94, and (c) is a schematic longitudinal cross section illustrating a longitudinal cross-sectional structure taken along a cutting line c94-c94 in FIG. 94).

FIG. 96 is a diagram illustrating a step subsequent to FIG. 94, and is a schematic longitudinal cross-sectional view illustrating a longitudinal cross-sectional structure at the same position as a cutting line a94-a94 in FIG. 94.

FIG. 97 is a diagram illustrating a step subsequent to FIG. 96, and is a schematic longitudinal cross-sectional view illustrating a longitudinal cross-sectional structure at the same position as a cutting line a94-a94 in FIG. 94.

FIG. 98 is a schematic plan view illustrating a step subsequent to FIG. 97.

FIG. 99 is a schematic longitudinal cross-sectional view illustrating a longitudinal cross-sectional structure taken along a cutting line a98-a98 in FIG. 98.

FIG. 100 is a diagram illustrating a step subsequent to FIG. 98, and is a schematic longitudinal cross-sectional view illustrating a longitudinal cross-sectional structure at the same position as a cutting line a98-a98 in FIG. 98.

FIG. 101 is a diagram illustrating a step subsequent to FIG. 100, and is a schematic longitudinal cross-sectional view illustrating a longitudinal cross-sectional structure at the same position as a cutting line a98-a98 in FIG. 98.

FIG. 102 is a diagram illustrating a step subsequent to FIG. 101, and is a schematic longitudinal cross-sectional view illustrating a longitudinal cross-sectional structure at the same position as a cutting line a98-a98 in FIG. 98.

FIG. 103 is a diagram illustrating a configuration example of an electronic apparatus according to a 106th embodiment of the present technology.

### MODE FOR CARRYING OUT THE INVENTION

Hereinafter, embodiments of the present technology will be described in detail with reference to the drawings.

In the description of the drawings referred to in the following description, the same or similar parts are denoted by the same or similar reference signs. However, it should be noted that the drawings are schematic, and the relationship between the thickness and the plane dimension, the ratio of the thickness of each layer, and the like are different from actual ones. Therefore, specific thicknesses and dimensions should be determined in consideration of the following description.

In addition, it is needless to say that portions having different dimensional relationships and ratios are included between the drawings. Furthermore, the effects described in the present specification are merely examples and are not limited, and other effects may be provided.

In addition, the following embodiments illustrate a device and a method for embodying the technical idea of the present technology, and do not specify the configuration as follows. That is, various modifications can be made to the technical idea of the present technology within the technical scope described in the claims.

In addition, the definitions of directions such as up and down in the following description are merely definitions for convenience of description, and do not limit the technical idea of the present technology. For example, it is a matter of course that when an object is observed by rotating the object by 90°, the upper and lower sides are converted into left and right and read, and when the object is observed by rotating the object by 180°, the upper and lower sides are inverted and read.

In addition, in the following embodiments, as the conductivity type of the semiconductor, a case where the first conductivity type is p-type and the second conductivity type is n-type will be exemplarily described, but the conductivity type may be selected in an opposite relationship, and the first conductivity type may be n-type and the second conductivity type may be p-type.

In addition, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, the thickness direction of the semiconductor portions 3 and 33 to be described later will be described as the Z direction.

### First Embodiment

In a first embodiment, an example in which the present technology is applied to a semiconductor device having a fin-type field effect transistor will be described.

### <<Configuration of Semiconductor Device>>

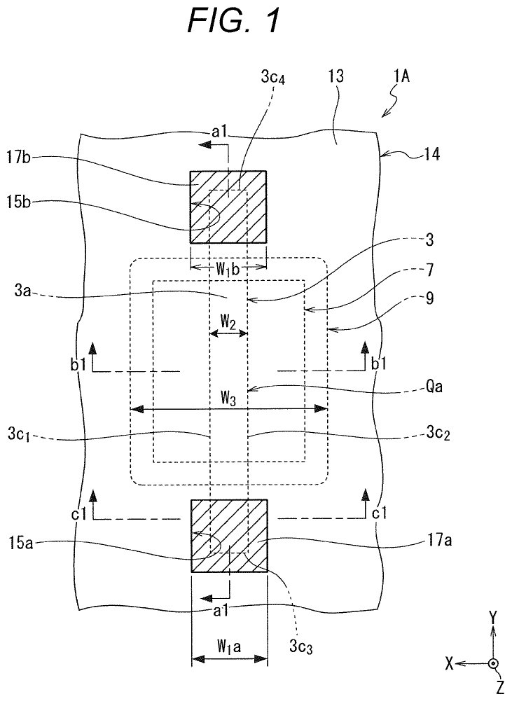

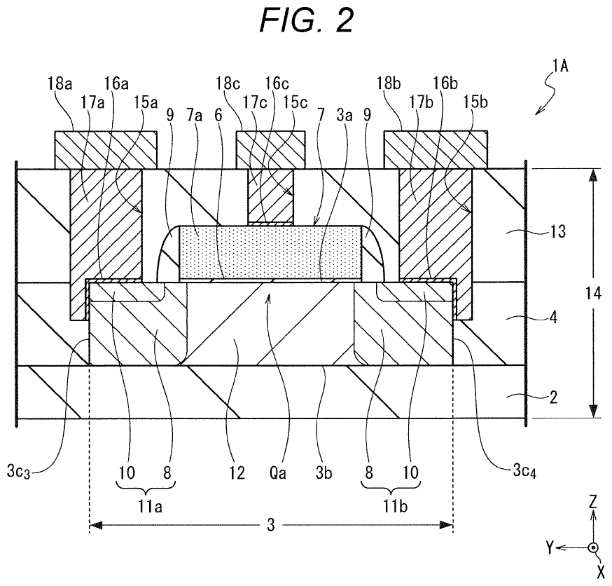

First, an overall configuration of a semiconductor device 1A will be described with reference to FIGS. 1, 2, 3, and 4. In FIG. 1, illustration of wirings 18a, 18b, and 18c illustrated in FIGS. 2 to 4 is omitted for convenience of description.

As illustrated in FIGS. 1 to 4, the semiconductor device 1A according to the first embodiment of the present technology includes an island-shaped semiconductor portion 3 and a field effect transistor Qa in which a channel formation portion (channel region) 12 is provided in the island-shaped semiconductor portion 3.

In addition, as illustrated in FIGS. 1 to 4, the semiconductor device 1A according to the first embodiment of the present technology further includes an insulating layer 14 including the semiconductor portion 3 and the field effect transistor Qa, and contact electrodes 17a, 17 b, and 17c provided in the insulating layer 14 so as to overlap the island-shaped semiconductor portion 3 in plan view.

Here, in FIG. 1, illustration of the contact electrode 17c is omitted.

### <Semiconductor Portion>

As illustrated in FIGS. 1 to 4, the semiconductor portion 3 is formed in a rectangular parallelepiped shape having, for example, an upper surface portion 3a, a lower surface portion (bottom surface portion) 3b, and four side surface portions 3c₁, 3c₂, 3c₃, and 3c₄. Then, as an example, the semiconductor portion 3 extends in the Y direction, the thickness direction is the Z direction, the longitudinal direction is the Y direction, and the lateral direction is the X direction. The upper surface portion 3a and the lower surface portion 3b are located on opposite sides in the thickness direction (Z direction) of the semiconductor portion 3. Among the four side surface portions 3c₁, 3c₂, 3c₃, and 3c₄, the two side surface portions 3c₁ and 3c₂ are located opposite to each other in the lateral direction (X direction), and the remaining two side surface portions 3c₃ and 3c₄ are located opposite to each other in the longitudinal direction (Y direction).

Here, in the first embodiment, the semiconductor portion 3 corresponds to a specific example of the “semiconductor portion” of the present technology. Then, the four side surface portions 3c₁, 3c₂, 3c₃, and 3c₄ of the semiconductor portion 3 correspond to a specific example of the “side surface portion of the semiconductor portion” of the present technology. Then, the four side surface portions 3c₁, 3c₂, 3c₃, and 304 may be referred to as a first side surface portion 3c₁, a second side surface portion 3c₂, a third side surface portion 3c₃, and a fourth side surface portion 3c₄, respectively.

Furthermore, in the first embodiment, the lateral direction of the semiconductor portion 3 corresponds to a specific example of the “first direction of the semiconductor portion” of the present technology, and the longitudinal direction of the semiconductor portion 3 corresponds to a specific example of the “second direction of the semiconductor portion” of the present technology. Then, the side surface portions 3c₃ and 3c₄ in the longitudinal direction (second direction) of the semiconductor portion 3 correspond to a specific example of the “end portion in the second direction intersecting the first direction of the semiconductor portion” of the present technology.

Although not limited thereto, the semiconductor portion 3 is constituted by, for example, silicon (Si) as a semiconductor material, for example, a single crystal as crystallinity, and for example, i-type (intrinsic type) as a conductivity type. That is, the semiconductor portion 3 is constituted by i-type monocrystalline silicon. In addition to Si, germanium (Ge), silicon germanium (SiGe), gallium arsenide (GaAs), indium phosphide (InP), or the like can also be used as the material of the semiconductor portion 3.

### <Insulating Layer>

As illustrated in FIGS. 1 to 4, the insulating layer 14 has a multilayer structure including a first insulating film (base insulating film) 2 provided in contact with the lower surface portion 3b on the side of the lower surface portion 3b opposite to the upper surface portion 3a of the semiconductor portion 3, a second insulating film (surrounding insulating film) 4 provided on the first insulating film 2 so as to surround the semiconductor portion 3, and a third insulating film (covering insulating film) 13 provided on the second insulating film 4 so as to cover the semiconductor portion 3 and a gate electrode 7 to be described later. Each of the first insulating film 2, the second insulating film 4, and the third insulating film 13 is constituted by, for example, a silicon oxide (SiO₂) film. That is, the semiconductor device 1A of the first embodiment has a silicon on insulator (SOI) structure in which the semiconductor portion 3 of silicon (Si) is provided on the first insulating film 2. Furthermore, the insulating layer 14 includes the semiconductor portion 3 and the field effect transistor Qa.

### <Field Effect Transistor>

The field effect transistor Qa is not limited thereto, but is configured to have, for example, an n-channel conductivity type. Then, the field effect transistor Qa includes a metal oxide semiconductor field effect transistor (MOSFET) having a silicon oxide (SiO₂) film as a gate insulating film. The field effect transistor Qa may be of a p-channel conductivity type. In addition, a metal insulator semiconductor FET (MISFET) using a silicon nitride film or a laminated film (composite film) such as a silicon nitride (Si₃N₄) film and a silicon oxide film as a gate insulating film may be used.

As illustrated in FIGS. 1 to 4, the field effect transistor Qa includes the channel formation portion 12 provided in the semiconductor portion 3, and a gate electrode 7 provided over the upper surface portion 3a and the two side surface portions 3c₁ and 3c₂ of the semiconductor portion 3 with a gate insulating film 6 interposed in the channel formation portion 12 of the semiconductor portion 3 in the lateral direction (X direction) of the semiconductor portion 3.

Furthermore, the field effect transistor Qa further includes a pair of main electrode regions 11a and 11b provided outside the semiconductor portion 3 to be separated from each other with the channel formation portion 12 interposed therebetween in the channel length direction (gate length direction) of the channel formation portion 12. In other words, the field effect transistor Qa includes a pair of main electrode regions 11a and 11b provided in the semiconductor portion 3 on both sides in the gate length direction (longitudinal direction) of the gate electrode 7. The pair of main electrode regions 11a and 11b functions as a source region and a drain region.

Furthermore, the field effect transistor Qa further includes a sidewall spacer 9 provided on the sidewall of the gate electrode 7.

Here, for convenience of description, one main electrode region 11a of the pair of main electrode regions 11a and 11b may be referred to as a source region 11a, and the other main electrode region 11b may be referred to as a drain region 11b.

Furthermore, the distance between the pair of main electrode regions 11a and 11b is the channel length (L) of the channel formation portion 12 (the gate length (Lg) of the gate electrode 7), and the direction of the channel length is referred to as a channel length direction (gate length direction). Then, the direction of the channel width (W) (gate width (Wg)) of the channel formation portion 12 is referred to as a channel width direction (gate width direction). Then, in the first embodiment, as an example, since the pair of main electrode regions 11a and 11b is separated in the Y direction with the channel formation portion 12 interposed therebetween, the channel length direction is the Y direction.

In the field effect transistor Qa, a channel (inversion layer) electrically connecting a source region (one main electrode region) 11a and a drain region (the other main electrode region) 11b is formed (induced) in the channel formation portion 12 by a voltage applied to the gate electrode 7, and a current (drain current) flows from the drain region 11b side to the source region 11a side through the channel formation portion 12.

### <Gate Electrode, Gate Insulating Film, and Sidewall Spacer>

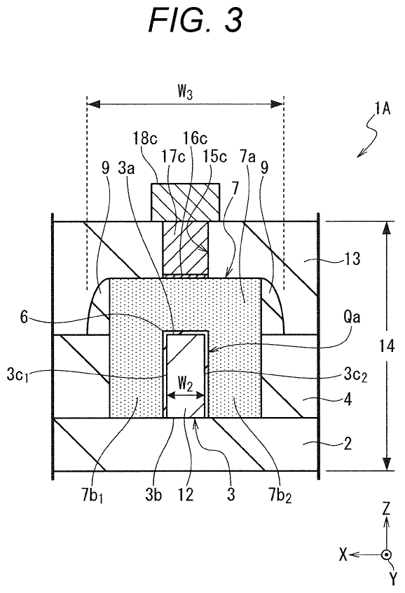

As illustrated in FIGS. 2 and 3, the gate electrode 7 includes, but is not limited to, for example, a head portion (first portion) 7a provided on the upper surface portion 3a side of the semiconductor portion 3 with the gate insulating film 6 interposed therebetween, and two leg portions (second portions) 7b₁ and 7b₂ integrated with the head portion 7a and provided outside each of the two side surface portions 3c₁ and 3c₂ located on opposite sides in the lateral direction (X direction) of the semiconductor portion 3 with the gate insulating film 6 interposed therebetween. That is, the gate electrode 7 is provided over the upper surface portion 3a and the two side surface portions 3c₁ and 3c₂ of the semiconductor portion 3, and has a C-shaped cross-sectional shape orthogonal to the longitudinal direction (Y direction). The gate electrode 7 is constituted by, for example, a polycrystalline silicon film into which an impurity for reducing the resistance value is introduced.

The head portion 7a of the gate electrode 7 is located above the second insulating film 4 and covered with the third insulating film 13. The leg portions 7b₁ and 7b₂ of the gate electrode 7 are provided in the film of the second insulating film 4.

The gate insulating film 6 is provided between the semiconductor portion 3 and the gate electrode 7 over the upper surface portion 3a and the two side surface portions 3c₁ and 3c₂ of the semiconductor portion 3. The gate insulating film 6 is constituted by, for example, a silicon oxide film.

The sidewall spacer 9 is provided on the sidewall of the head portion 7a of the gate electrode 7 so as to surround the head portion 7a of the gate electrode 7, and extends on the second insulating film 4 of the insulating layer 14 and the semiconductor portion 3 in plan view. Then, the sidewall spacer 9 is formed so as to be aligned with the gate electrode 7. The sidewall spacer 9 can be formed, for example, by forming an insulating film (spacer material) by a CVD method so as to cover the gate electrode 7, and then performing anisotropic dry etching such as reactive ion etching (RIE) on the insulating film.

The sidewall spacer 9 is constituted by a material having a selectivity ratio with respect to the second insulating film 4 and the semiconductor portion 3 included in the insulating layer 14. In the first embodiment, the sidewall spacer 9 is constituted by, for example, a silicon nitride film having selectivity with respect to the silicon oxide film of the second insulating film 4 and the silicon of the semiconductor portion 3. The sidewall spacer 9 secures a distance between the gate electrode 7 and a contact region 10 (see FIG. 2) of each of the pair of main electrode regions 11a and 11b described later.

### <Main Electrode Region>

As illustrated in FIG. 2, each of the pair of main electrode regions 11a and 11b includes an n-type extension region 8 including an n-type semiconductor region provided in the semiconductor portion 3 so as to be aligned with the gate electrode 7, and an n-type contact region 10 including an n-type semiconductor region provided in the semiconductor portion 3 so as to be aligned with the sidewall spacer 9 of the sidewall of the gate electrode 7. That is, the pair of main electrode regions 11a and 11b having the n-type extension region 8 and the n-type contact region 10 is provided in the semiconductor portion 3 so as to be aligned with the gate electrode 7.

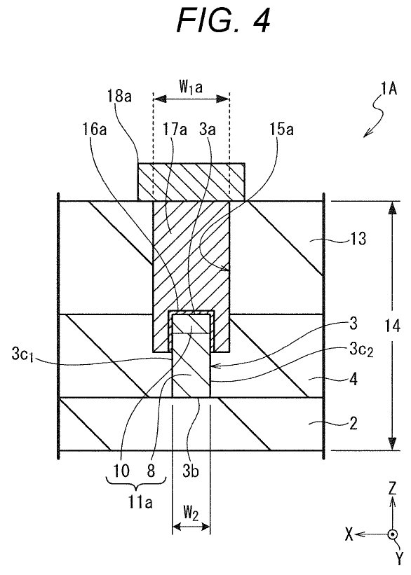

As illustrated in FIGS. 2 and 4, the n-type contact region 10 is provided in the region of the n-type extension region 8. Each of the n-type extension region 8 and the n-type contact region 10 has a thickness in the thickness direction (Z direction) of the semiconductor portion 3 and in the height direction of the semiconductor portion 3. Then, the n-type extension region 8 is formed deeper than, in other words, thicker than the n-type contact region 10. In the first embodiment, although not limited thereto, the n-type extension region 8 extends from the upper surface portion 3a side to the lower surface portion 3b side of the semiconductor portion 3 and has a depth in contact with the first insulating film 2 on the lower surface portion 3b side of the semiconductor portion 3.

As illustrated in FIGS. 2 to 4, the field effect transistor Qa of the first embodiment is configured as a so-called fin type in which the gate electrode 7 is provided in the island-shaped semiconductor portion 3 as a fin portion with the gate insulating film 6 interposed therebetween.

In the fin-type field effect transistor Qa, the length between the pair of main electrode regions 11a and 11b is the channel length L (≈ gate length Lg), and in the region where the gate electrode 7 and the semiconductor portion 3 three-dimensionally overlap, a value obtained by multiplying the length (the length around the semiconductor portion 3) including the width W₂ in the lateral direction on the upper surface portion 3a side of the semiconductor portion 3 and the heights of the side surface portions 3b₁ and 3b₂ of the semiconductor portion 3 by the number of semiconductor portions 3 is the channel width W (˜ gate width).

Therefore, in the fin-type field effect transistor Qa, since the channel width W is increased by increasing the width W₂ of the semiconductor portion 3 in the lateral direction (Y direction) and increasing the height of the semiconductor portion 3 in the thickness direction (Z direction), the effective channel area (channel length L×channel width W) can be increased. Then, the fin-type field effect transistor Qa can increase the channel area (channel length L×channel width W) by increasing the number of semiconductor portions 3. In the first embodiment, a case where the field effect transistor Qa is provided in one semiconductor portion 3 has been described, but a plurality of semiconductor portions 3 may be provided.

Examples of the field effect transistor Qa include an enhancement type (normally-off type) in which a drain current flows by applying a gate voltage equal to or higher than a threshold voltage to the gate electrode 7, and a depression type (normally-off type) in which a drain current flows without applying a voltage to the gate electrode 7. In the first embodiment, although not limited thereto, for example, an enhancement type is used. In the case of the enhancement type, in the field effect transistor Qa, a channel (inversion layer) electrically connecting the pair of main electrode regions 11a and 11b is formed (induced) in the channel formation portion 12 by a voltage applied to the gate electrode 7, and a current (drain current) flows from the drain region side (for example, the main electrode region 11b side) through the channel of the channel formation portion 12 to the source region side (for example, the main electrode region 11a side).

### <Contact Electrode and Wiring>

As illustrated in FIGS. 2 and 3, the gate electrode 7 is electrically connected to the wiring 18c provided in the wiring layer on the insulating layer 14 via the contact electrode 17c provided in the insulating layer 14 (specifically, the third insulating film 13) and the barrier metal film 16c provided in the semiconductor layer 3. Further, one main electrode region 11a of the pair of main electrode regions 11a and 11b is electrically connected to the wiring 18a provided in the wiring layer on the insulating layer 14 via the contact electrode 17a provided in the insulating layer 14 (specifically, the third insulating film 13) and the barrier metal film 16a provided in the semiconductor layer 3. Then, of the pair of main electrode regions 11a and 11b, the other main electrode region 11b is electrically connected to the wiring 18b provided in the wiring layer on the insulating layer 14 via the contact electrode 17b provided in the insulating layer 14 (specifically, the third insulating film 13) and the barrier metal film 16b provided in the semiconductor layer 3. As a material of the contact electrodes 17a, 17 b, and 17c, for example, tungsten (W) of a high melting point metal can be used. As the barrier metal films 16a, 16b, and 16c, for example, a composite film (Ti/TiN) including a titanium (Ti) film and a titanium nitride (TiN) film can be used. As the material of the wirings 18a, 18b, and 18c, for example, a metal material such as aluminum (Al) or copper (Cu), an alloy material mainly containing Al or Cu, or the like can be used.

Note that, in the first embodiment, the contact electrodes 17a, 17 b, and 17c and the barrier metal films 16a, 16b, and 16c are described separately, but the contact electrodes 17a, 17 b, and 17c including the barrier metal films 16a, 16b, and 16c may be used. Furthermore, although the barrier metal films 16a, 16b, and 16c may be omitted, it is preferable that the barrier metal films 16a, 16b, and 16c are interposed between the semiconductor portion 3 and the gate electrode 7, and the contact electrodes 17a, 17 b, and 17c as in the first embodiment.

### <Connection Between Contact Electrode and Semiconductor Portion>

As illustrated in FIGS. 2 and 4, the contact electrode 17a is provided in a dug portion 15a that extends along the thickness direction (Z direction) of the insulating layer 14, penetrates the third insulating film 13 from the upper surface side of the third insulating film 13 of the insulating layer 14, and enters the film of the second insulating film 4. Similarly, the contact electrode 17b is also provided in a dug portion 15b extending along the thickness direction (Z direction) of the insulating layer 14 and penetrating the third insulating film 13 from the upper surface side of the third insulating film 13 of the insulating layer 14 to enter the film of the second insulating film 4. Then, the contact electrodes 17a and 17b are not limited thereto, but are configured to have a depth at which the insulating layer 14 is separated from the first insulating film 2 in the thickness direction (Z direction) of the insulating layer 14.

As illustrated in FIGS. 2 and 4, the contact electrodes 17a and 17b are connected to the upper surface portion 3a and the side surface portion of the semiconductor portion 3. Specifically, the contact electrode 17a is connected to each of the upper surface portion 3a and the three side surface portions 3c₁, 3c₂, and 3c₃ of the semiconductor portion 3 and is electrically connected to the one main electrode region 11a on one end portion side (main electrode region 11a side) in the longitudinal direction (Y direction) of the semiconductor portion 3. In addition, the contact electrode 17b is connected to each of the upper surface portion 3a and the three side surface portions 3c₁, 3c₂, and 3c₄ of the semiconductor portion 3 and is electrically connected to the other main electrode region 11b on the other end portion side (main electrode region 11b side) in the longitudinal direction (Y direction) of the semiconductor portion 3.

In the first embodiment, although not limited thereto, the contact electrode 17a is connected to each of the upper surface portion 3a and the three side surface portions 3c₁, 3c₂, and 3c₃ of the semiconductor portion 3 via the barrier metal film 16a. Furthermore, the contact electrode 17b is also connected to each of the upper surface portion 3a and the three side surface portions 3c₁, 3c₂, and 3c₄ of the semiconductor portion 3 via the barrier metal film 16b.

### <Width of Contact Electrode>

As illustrated in FIGS. 1, 2, and 3, in the lateral direction (X direction) of the semiconductor portion 3, the width W₁a of the contact electrode 17a is wider than the width W₂ of the semiconductor portion 3. Then, the width W₁a of the contact electrode 17a is narrower than the width W₃ (width of gate electrode+width of sidewall spacer×2) including the head portion 7a of the gate electrode 7 and the sidewall spacers 19 provided on both sides of the gate electrode 7.

Similarly, in the lateral direction (X direction) of the semiconductor portion 3, the width W₁b of the contact electrode 17b is wider than the width W₂ of the semiconductor portion 3. Then, the width W₁b of the contact electrode 17b is narrower than the width W₂ including the gate electrode 7 and the sidewall spacers 19 provided on both sides of the gate electrode 7.

### <<Method for Manufacturing Semiconductor Device>>

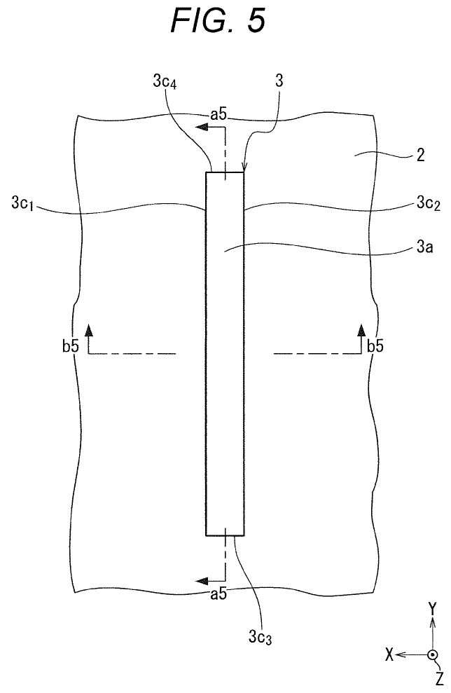

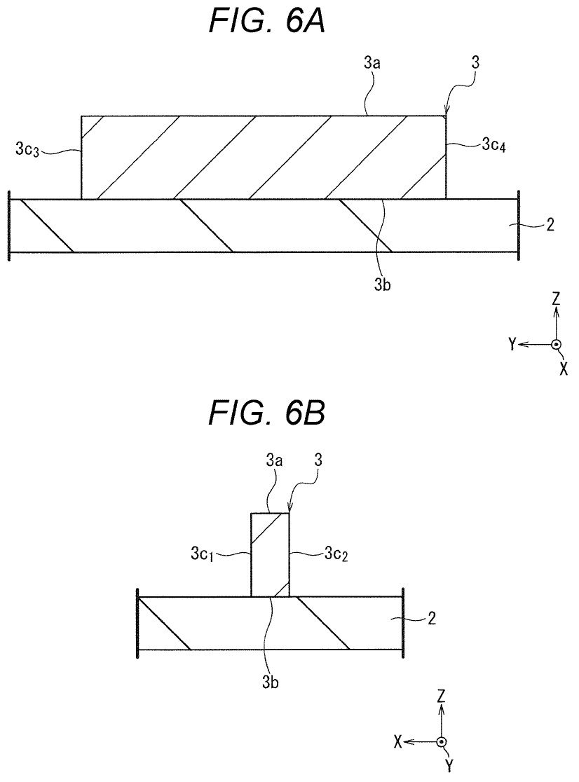

FIG. 5 is a schematic plan view illustrating a step of the method for manufacturing the semiconductor device 1A, FIG. 6A is a schematic longitudinal cross-sectional view illustrating a longitudinal cross-sectional structure taken along a cutting line a5-a5 in FIG. 5, and FIG. 6B is a schematic longitudinal cross-sectional view illustrating a longitudinal cross-sectional structure taken along a cutting line b5-b5 in FIG. 5.

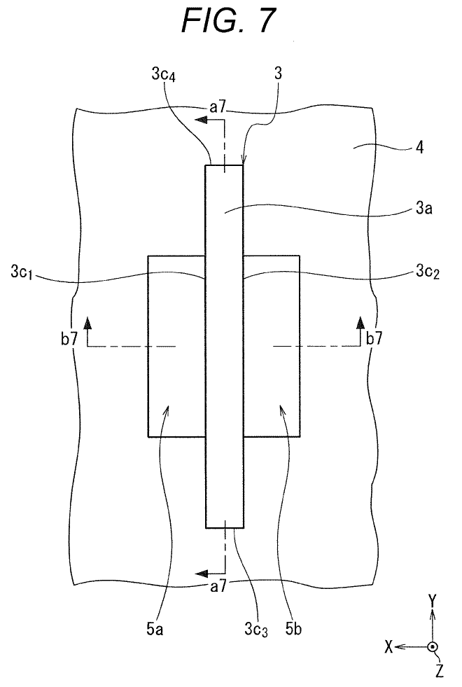

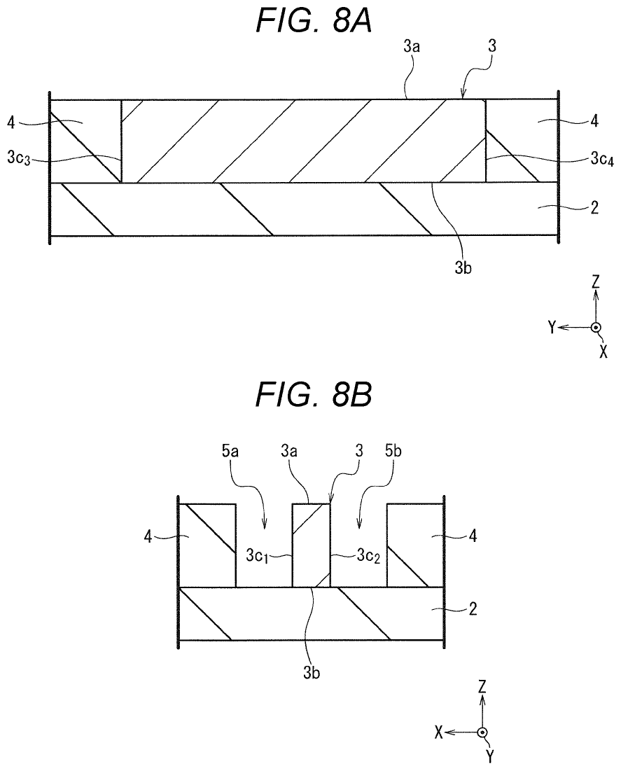

FIG. 7 is a schematic plan view illustrating a step subsequent to FIG. 5, FIG. 8A is a schematic longitudinal cross-sectional view illustrating a longitudinal cross-sectional structure taken along a cutting line a7-a7 in FIG. 7, and FIG. 8B is a schematic longitudinal cross-sectional view illustrating a longitudinal cross-sectional structure taken along a cutting line b7-b7 in FIG. 7.

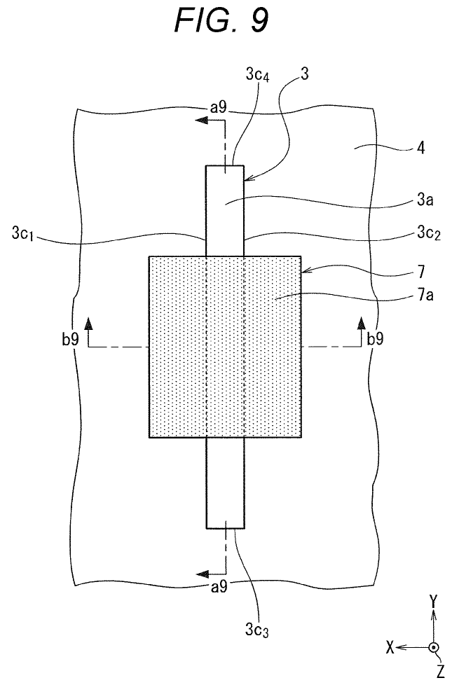

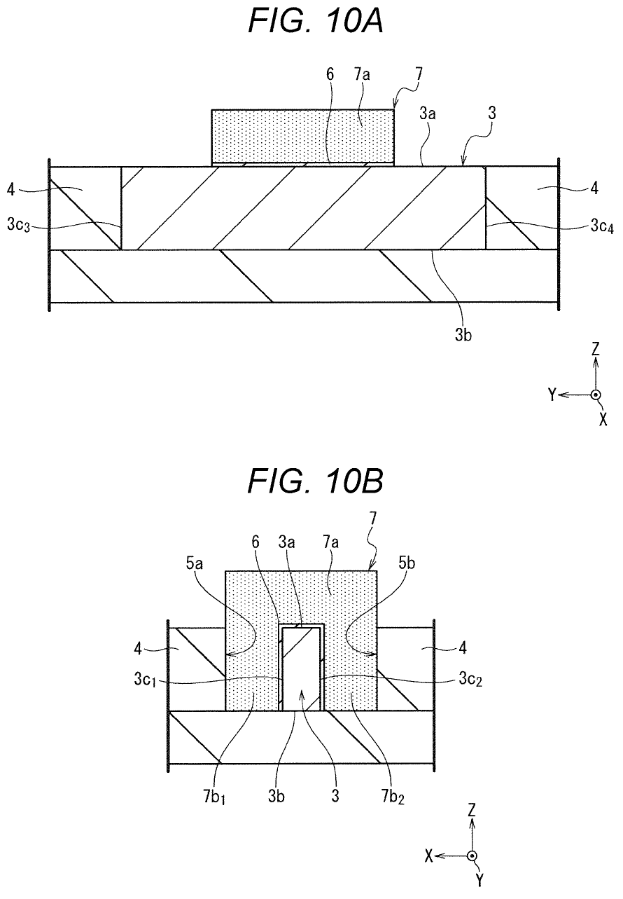

FIG. 9 is a schematic plan view illustrating a step subsequent to FIG. 7, FIG. 10A is a schematic longitudinal cross-sectional view illustrating a longitudinal cross-sectional structure taken along a cutting line a9-a9 in FIG. 9, and FIG. 10B is a schematic longitudinal cross-sectional view illustrating a longitudinal cross-sectional structure taken along a cutting line b9-b9 in FIG. 9.

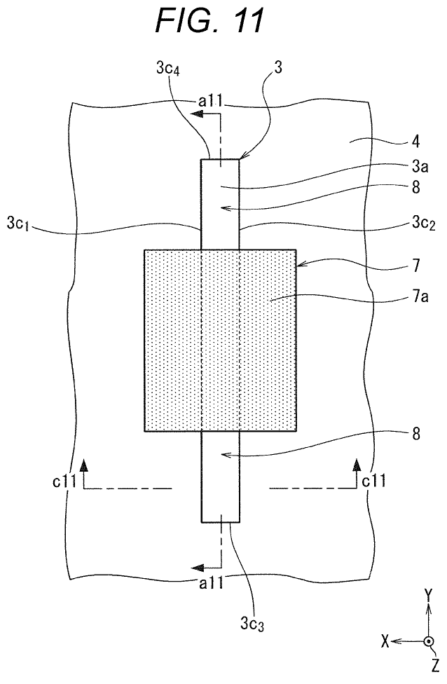

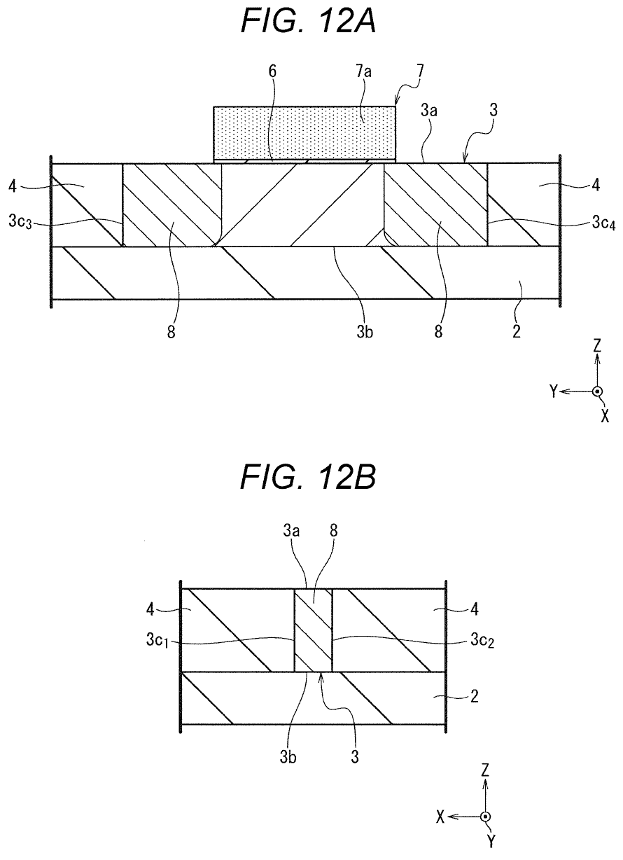

FIG. 11 is a schematic plan view illustrating a step subsequent to FIG. 9, FIG. 12A is a schematic longitudinal cross-sectional view illustrating a longitudinal cross-sectional structure taken along a cutting line a11-a11 in FIG. 11, and FIG. 12B is a schematic longitudinal cross-sectional view illustrating a longitudinal cross-sectional structure taken along a cutting line c11-c11 in FIG. 11.

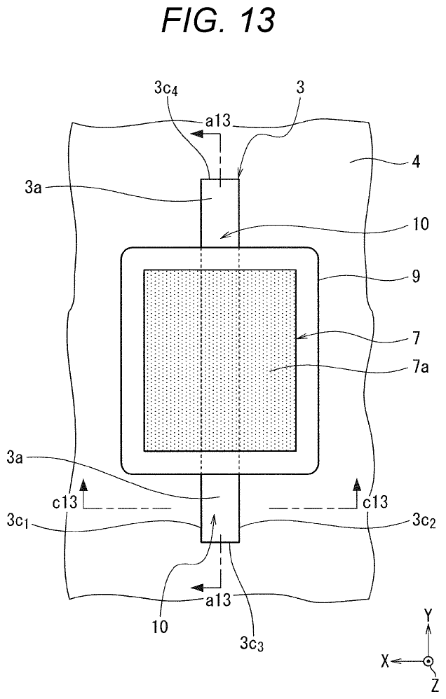

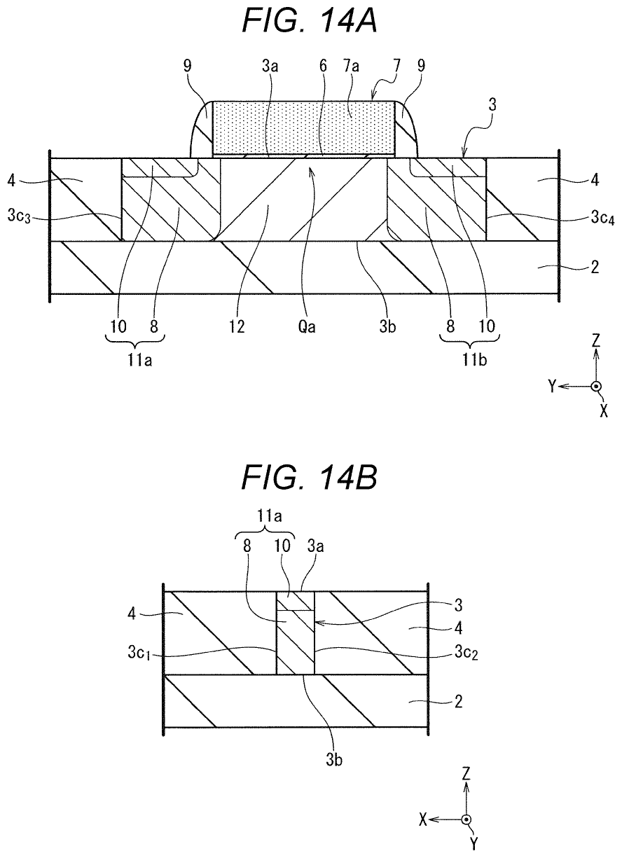

FIG. 13 is a schematic plan view illustrating a step subsequent to FIG. 11, FIG. 14A is a schematic longitudinal cross-sectional view illustrating a longitudinal cross-sectional structure taken along a cutting line a13-a13 in FIG. 13, and FIG. 14B is a schematic longitudinal cross-sectional view illustrating a longitudinal cross-sectional structure taken along a cutting line c13-c13 in FIG. 13.

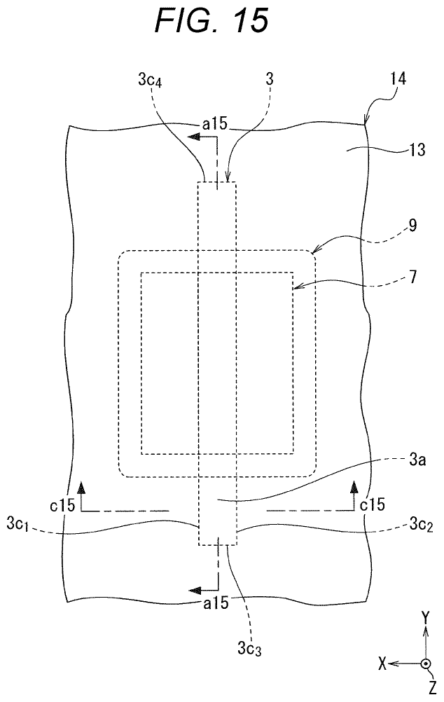

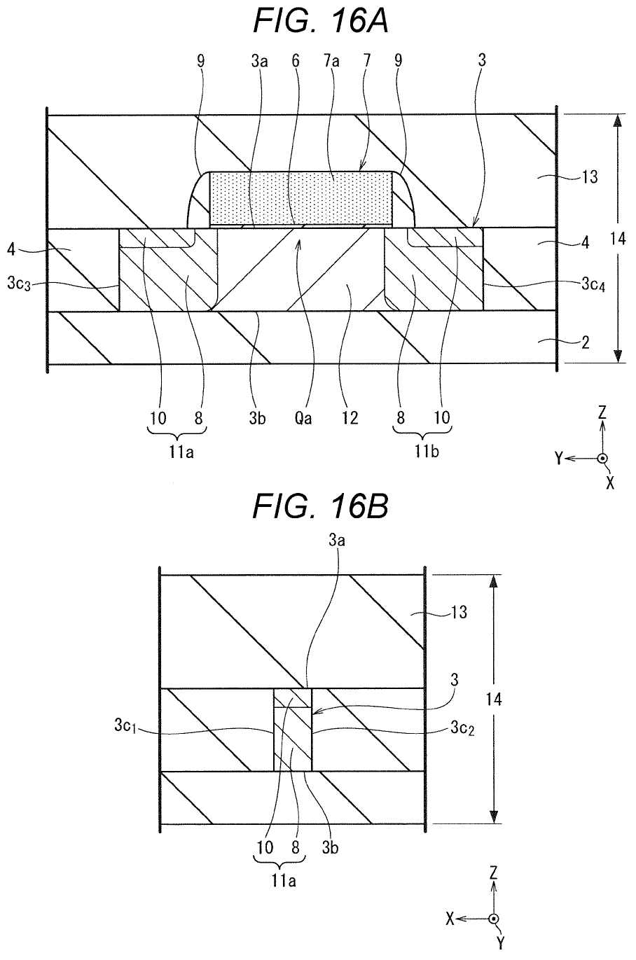

FIG. 15 is a schematic plan view illustrating a step subsequent to FIG. 13, FIG. 16A is a schematic longitudinal cross-sectional view illustrating a longitudinal cross-sectional structure taken along a cutting line a15-a15 in FIG. 15, and FIG. 16B is a schematic longitudinal cross-sectional view illustrating a longitudinal cross-sectional structure taken along a cutting line c15-c15 in FIG. 15.

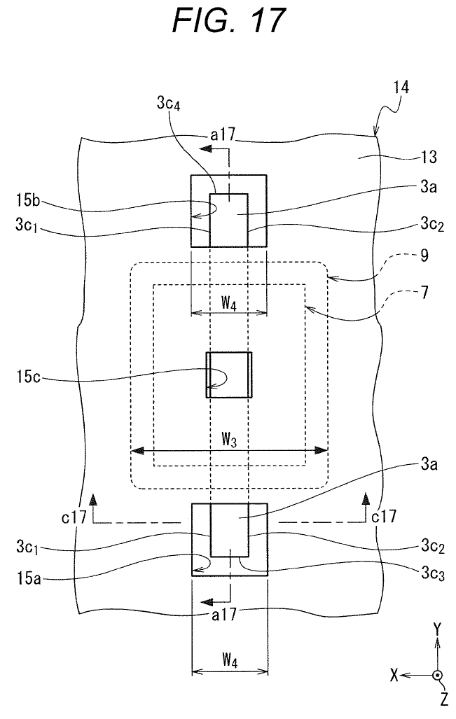

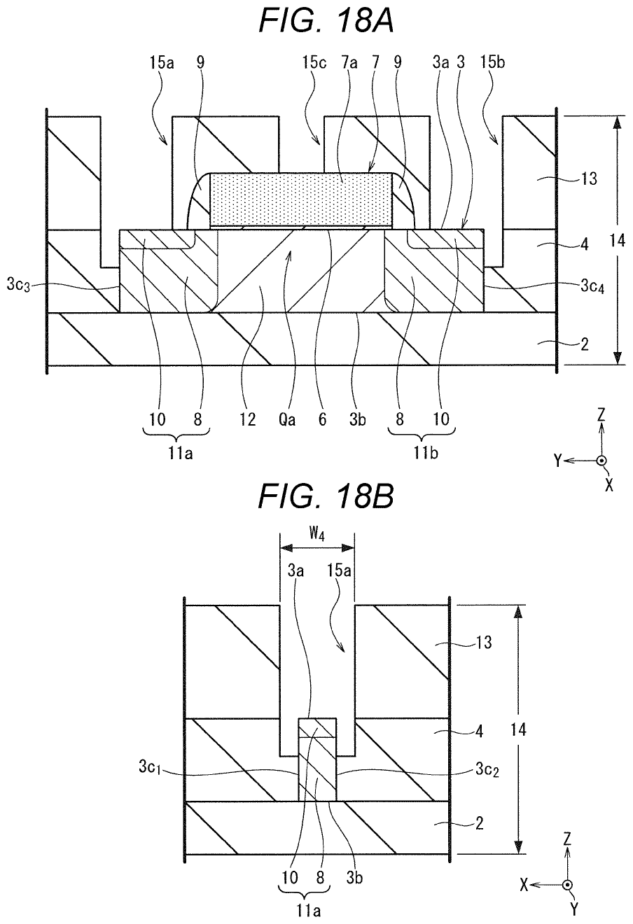

FIG. 17 is a schematic plan view illustrating a step subsequent to FIG. 15, FIG. 18A is a schematic longitudinal cross-sectional view illustrating a longitudinal cross-sectional structure taken along a cutting line a17-a17 in FIG. 17, and FIG. 18B is a schematic longitudinal cross-sectional view illustrating a longitudinal cross-sectional structure taken along a cutting line c17-c17 in FIG. 17.

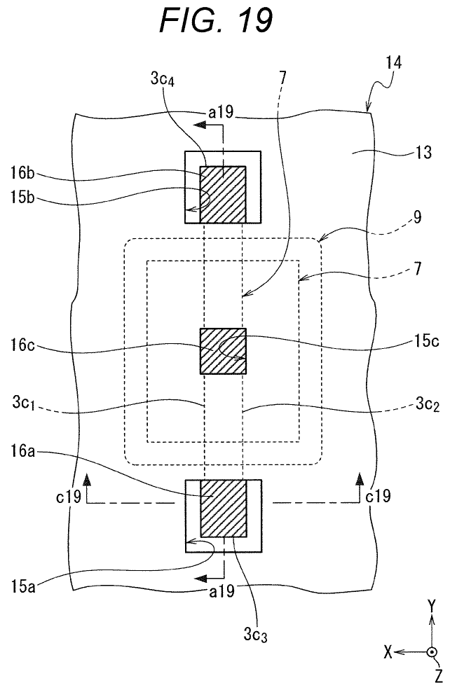

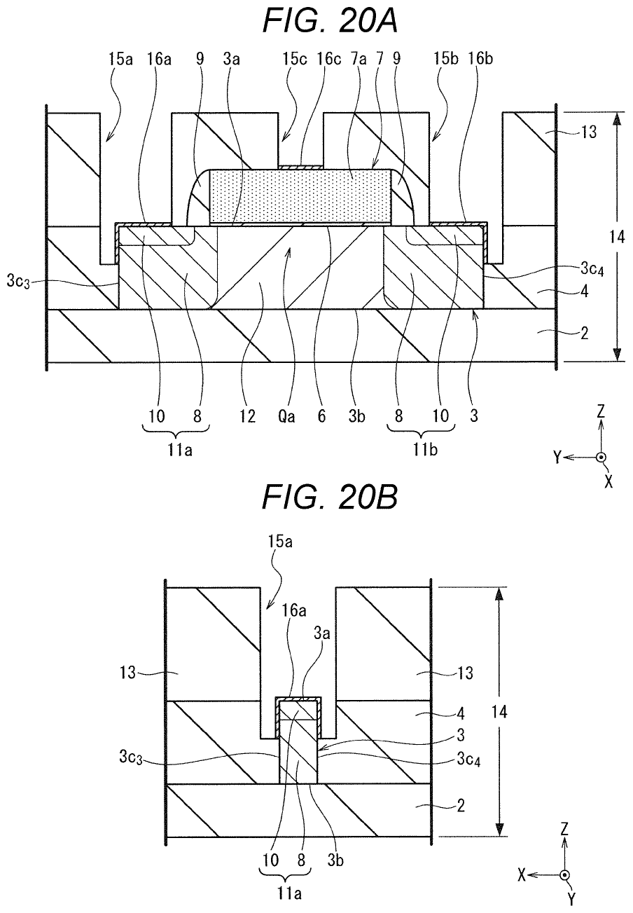

FIG. 19 is a schematic plan view illustrating a step subsequent to FIG. 17, FIG. 20A is a schematic longitudinal cross-sectional view illustrating a longitudinal cross-sectional structure taken along a cutting line a19-a19 in FIG. 19, and FIG. 20B is a schematic longitudinal cross-sectional view taken along a cutting line c19-c19 in FIG. 19.

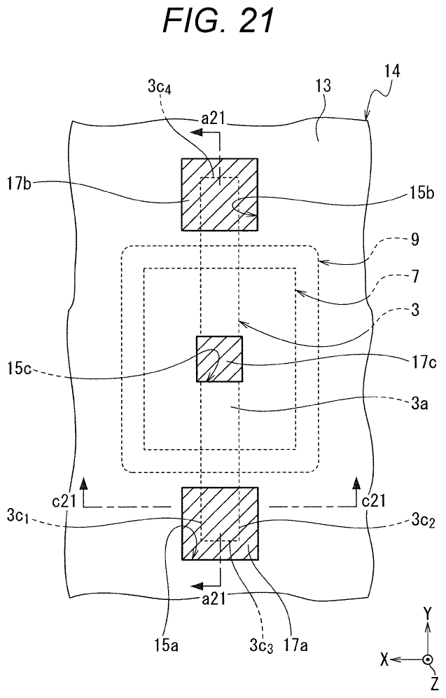

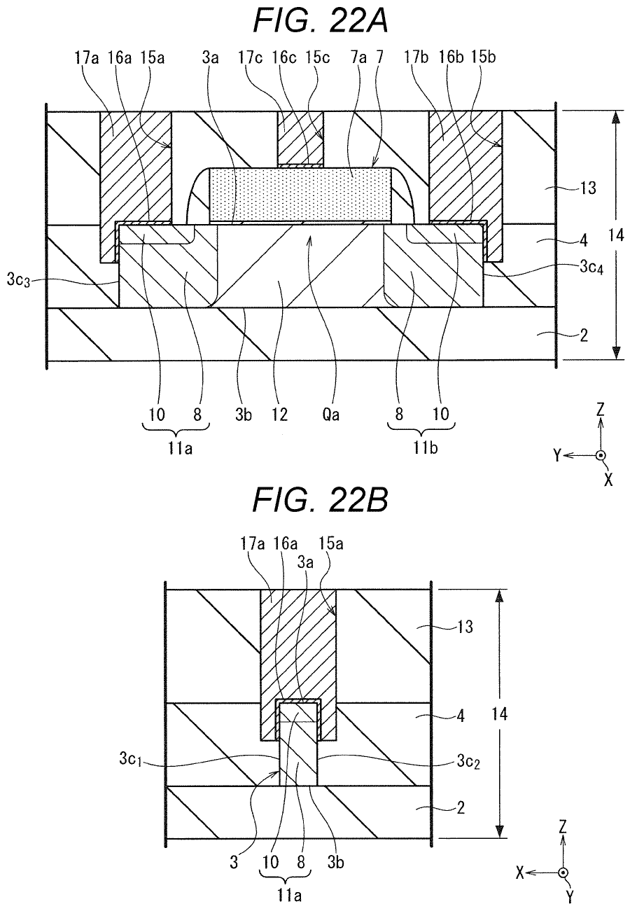

FIG. 21 is a schematic plan view illustrating a step subsequent to FIG. 19, FIG. 22A is a schematic longitudinal cross-sectional view illustrating a longitudinal cross-sectional structure taken along a cutting line a21-a21 in FIG. 21, and FIG. 22B is a schematic longitudinal cross-sectional view illustrating a longitudinal cross-sectional structure taken along a cutting line c21-c21 in FIG. 21.

First, as illustrated in FIGS. 5, 6A, and 6B, the island-shaped semiconductor portion 3 is formed on the first insulating film 2. The semiconductor portion 3 is formed in, for example, a rectangular parallelepiped shape having an upper surface portion 3a, a lower surface portion (bottom surface portion) 3b, and four side surface portions 3c₁, 3c₂, 3c₃, and 3c₄. The semiconductor portion 3 can be formed, for example, by patterning a semiconductor layer provided on the first insulating film 2 into a predetermined shape using a known etching technique or a thinning technique such as a CMP method. Although not limited thereto, the semiconductor portion 3 is constituted by, for example, silicon as a semiconductor material, for example, a single crystal as crystallinity, and for example, i-type (intrinsic type) as a conductivity type. The first insulating film 2 supports the semiconductor portion 3 on the lower surface portion 3b side of the semiconductor portion 3. As the first insulating film 2, for example, a silicon oxide film formed by a chemical vapor deposition (CVD) method is used.

Next, as illustrated in FIGS. 7, 8A, and 8B, the second insulating film 4 and the dug portions 5a and 5b are formed. The second insulating film 4 is formed outside the semiconductor portion 3 so as to surround the semiconductor portion 3. The second insulating film 4 can be formed by forming, for example, a silicon oxide film on the entire surface of the first insulating film 2 including the semiconductor portion 3 using a known film formation method (for example, a CVD method), and then selectively removing the silicon oxide film on the semiconductor portion 3 using, for example, a CMP method.

After the second insulating film 4 is formed, the dug portions 5a and 5b are formed such that the side surface portions 3c₁ and 3c₂ are exposed to the outside each of the two side surface portions 3c₁ and 3c₂ located on opposite sides in the X direction of the semiconductor portion 3. The dug portions 5a and 5b can be formed by selectively etching the second insulating film 4 outside each of the side surface portions 3c₁ and 3c₂ of the semiconductor portion 3 using, for example, a known photolithography technique and dry etching technique. Etching of the second insulating film 4 is performed under a condition that an etching ratio with respect to the semiconductor portion 3 can be obtained. The dug portions 5a and 5b are formed in a shape in which a length in the same direction as the longitudinal direction (Y direction) of the semiconductor portion 3 is shorter than a length in the longitudinal direction of the semiconductor portion 3. In addition, the dug portions 5a and 5b are preferably formed such that the depth in the Z direction is equivalent to or higher than the height of the semiconductor portion 3 in the Z direction.

Next, as illustrated in FIGS. 9, 10A, and 10B, the gate insulating film 6 and the gate electrode 7 are formed. As illustrated in FIGS. 10A and 10B, the gate insulating film 6 is formed over the upper surface portion 3a and the two side surface portions 3c₁ and 3c₂ of the semiconductor portion 3 in the lateral direction (X direction) of the semiconductor portion 3. The gate insulating film 6 can be formed by a thermal oxidation method or a deposition method. In the first embodiment, a silicon oxide film as the gate insulating film 6 is formed by a thermal oxidation method. As a result, the gate insulating film 6 can be selectively formed in the portion of the semiconductor portion 3 exposed from the second insulating film 4.

As illustrated in FIGS. 10A and 10B, the gate electrode 7 is formed so as to face (be adjacent to) the upper surface portion 3a and each of the two side surface portions 3c₁ and 3c₂ of the semiconductor portion 3 with the gate insulating film 6 interposed therebetween. The gate electrode 7 includes a head portion (first portion) 7a provided on the upper surface portion 3a side of the semiconductor portion 3 via the gate insulating film 6, and two leg portions (second portions) 7b₁ and 7b₂ integrated with the head portion 7a and provided outside each of the two side surface portions 3c₁ and 3c₂ located on opposite sides in the lateral direction (X direction) of the semiconductor portion 3 with the gate insulating film 6 interposed therebetween. The head portion 7a protrudes upward from the second insulating film 4. Each of the two leg portions 7b₁ and 7b₂ is separately provided in each of the dug portions 5a and 5b.

The gate electrode 7 can be formed by forming a gate electrode film (electrode material) on the entire surface of the second insulating film 4 including the inside of each of the two dug portions 5a and 5b and the semiconductor portion 3, and then patterning the gate electrode film using a known planarization technique, photolithography technique, dry etching technique, or the like. As the gate electrode film, for example, a polycrystalline silicon film into which an impurity for reducing the resistance value is introduced can be used.

The impurities in the polycrystalline silicon film can be introduced during film formation or after film formation. In a case where a polycrystalline silicon film is embedded inside the dug portions 5a and 5b as in the first embodiment, it is preferable to introduce impurities during film formation from the viewpoint of uniformity of impurity concentration.

Next, as illustrated in FIGS. 11, 12A, and 12B, a pair of extension regions 8 including n-type semiconductor regions is formed on each of the semiconductor portions 3 on both sides of the gate electrode 7 in the gate length direction (Y direction). The extension region 8 can be formed by using the gate electrode 7 and the second insulating film 4 as an impurity introduction mask, ion-implanting, for example, arsenic ions (As⁺) or phosphorus ions (P⁺) as n-type impurities into each of the semiconductor portions 3 on both sides of the gate electrode 7 in the gate length direction (Y direction), and then subjecting the semiconductor portions 3 to a heat treatment for activating the impurities. The pair of n-type extension regions 8 is formed at a depth in contact with the first insulating film 2 on the lower surface portion 3b side of the semiconductor portion 3.

In this step, each of the pair of n-type extension regions 8 is formed on each semiconductor portion 3 on both sides of the gate electrode 7 in the gate length direction (Y direction) so as to be aligned with the gate electrode 7.

Next, as illustrated in FIGS. 13, 14A, and 14B, the sidewall spacer 9 is formed on the sidewall of the head portion 7a of the gate electrode 7 protruding upward from the second insulating film 4. The sidewall spacer 9 can be formed by forming a silicon nitride film having selectivity to, for example, a silicon oxide film as an insulating film on the entire surface of the second insulating film 4 by a CVD method so as to cover the head portion 7a of the gate electrode 7, and then applying anisotropic dry etching such as RIE to the silicon nitride film. The sidewall spacer 9 is formed on the sidewall of the head portion 8a of the gate electrode 7 so as to surround the head portion 7a of the gate electrode 7, and is formed so as to be aligned with the gate electrode 7. Furthermore, the sidewall spacer 9 is formed on the second insulating film 4 and the semiconductor portion 3 so as to cross the semiconductor portion 3.

Next, after the sidewall spacer 9 is formed, as illustrated in FIGS. 13, 14A, and 14B, a pair of n-type contact regions 10 including n-type semiconductor regions is formed on each of the semiconductor portions 3 on both sides of the gate electrode 7 in the gate length direction (Y direction). The pair of n-type contact regions 10 can be formed by using the second insulating film 4, the gate electrode 7, and the sidewall spacer 9 as an impurity introduction mask, ion-implanting, for example, arsenic ions (As⁺) or phosphorus ions (P⁺) as n-type impurities into each of the semiconductor portions 3 on both sides of the gate electrode 7 in the gate length direction (Y direction), and then subjecting the semiconductor portions 3 to a heat treatment for activating the impurities. The pair of n-type contact regions 10 are individually formed in the regions of the pair of extension regions 8. Then, the pair of n-type contact regions 10 is formed on each semiconductor portion 3 on both sides of the gate electrode 7 in the gate length direction (Y direction) so as to be aligned with the sidewall spacer 9.

In this step, a pair of main electrode regions 11a and 11b including the n-type extension region 8 and the n-type contact region 10 is formed in the semiconductor portion 3.

Furthermore, in this step, the channel formation portion 12 is formed in the semiconductor portion 3 between the pair of main electrode regions 11a and 11b.

Then, by this step, the field effect transistor Qa including the gate insulating film 6, the gate electrode 7, the sidewall spacer 9, the pair of main electrode regions 11a and 11b, the channel formation portion 12, and the like is formed in the semiconductor portion 3.

Next, as illustrated in FIGS. 15, 16A, and 16B, a third insulating film 13 that covers the semiconductor portion 3 and the gate electrode 7 is formed on the side of the second insulating film 4 opposite to the first insulating film 2 side. The third insulating film 13 can be formed by forming, for example, a silicon oxide film as an insulating film on the entire surface of the second insulating film 4 including the head portion 7a of the gate electrode 7, and then planarizing the surface of the silicon oxide film by a CMP method or the like.

In this step, the insulating layer 14 including the first insulating film 2, the second insulating film 4, and the third insulating film 13 and including the semiconductor portion 3 and the field effect transistor Qa is formed.

Next, as illustrated in FIGS. 17, 18A, and 18B, each of dug portions 15a and 15b that enters the second insulating film 4 from the surface of the third insulating film 13 of the insulating layer 14 is formed on both end portion sides of the semiconductor portion 3 in the longitudinal direction (Y direction), and a dug portion 15c that reaches the head portion 7a of the gate electrode 7 from the surface of the third insulating film 13 of the insulating layer 14 is formed. Each of the dug portions 15a, 15b, and 15c is formed by selectively etching the insulating layer 14 using a known photolithography technique and an anisotropic dry etching technique.

The dug portion 15a is formed such that the upper surface portion 3a and the three side surface portions 3c₁, 3c₂, and 3c₃ of one semiconductor portion 3 of the two semiconductor portions 3 on both sides in the gate length direction (Y direction) of the gate electrode 7 are exposed. In addition, the dug portion 15b is formed such that the upper surface portion 3a and the three side surface portions 3c₁, 3c₂, and 3c₄ of the other semiconductor portion 3 of the two semiconductor portions 3 on both sides in the gate length direction (Y direction) of the gate electrode 7 are exposed. The width W₄ of each of the dug portions 15a and 15b in the lateral direction (X direction) of the semiconductor portion 3 defines the width W₁ of the contact electrodes 17a and 17b described later.

Next, as illustrated in FIGS. 19, 20A, and 20B, the barrier metal film 16a is formed on the upper surface portion 3a and the three side surface portions 3c₁, 3c₂, and 3c₃ of the semiconductor portion 3 exposed from the dug portion 15a, the barrier metal film 16b is formed on the upper surface portion 3a and the three side surface portions 3c₁, 3c₂, and 3c₄ of the semiconductor portion 3 exposed from the dug portion 15b, and the barrier metal film 16c is formed on the head portion 7a of the gate electrode 7 exposed from the dug portion 15c. The barrier metal films 16a, 16b, and 16c are constituted by, for example, a composite film (Ti/TiN) including a titanium (Ti) film and a titanium nitride (TiN) film. Each of the barrier metal films 16a, 16b, and 16c can be selectively formed by an ALD method.

Next, as illustrated in FIGS. 21, 22A, and 22B, the contact electrodes 17a, 17 b, and 17c are separately formed in the dug portions 15a, 15b, and 15c. Each of the contact electrodes 17a, 17 b, and 17c can be formed by forming a tungsten film, for example, as a high melting point metal film on the entire surface on the insulating layer 14 including the inside of each of the dug portions 15a, 15b, and 15c, and selectively removing the tungsten film on the insulating layer 14 so that the tungsten film separately remains inside each of the dug portions 15a, 15b, and 15c.

In this step, the contact electrode 17a is connected to the upper surface portion 3a and the three side surface portions 3c₁, 3c₂, and 3c₃ of one of the two semiconductor portions 3 on both sides in the gate length direction (Y direction) of the gate electrode 7 via the barrier metal film 16a, and is electrically and mechanically connected to the one main electrode region 11a of the pair of main electrode regions 11a and 11b.

Furthermore, in this step, the contact electrode 17b is also connected to the upper surface portion 3a and the three side surface portions 3c₁, 3c₂, and 3c₄ of the other semiconductor portion 3 of the two semiconductor portions 3 on both sides in the gate length direction (Y direction) of the gate electrode 7 via the barrier metal film 16b, and is electrically and mechanically connected to the other main electrode region 11b of the pair of main electrode regions 11a and 11b.

Furthermore, in this step, the contact electrode 17c is connected to the head portion 7a of the gate electrode 7 via the barrier metal film 16c, and is electrically and mechanically connected to the gate electrode 7.

Next, the wirings 18a, 18b, and 18c electrically and mechanically connected to the contact electrodes 17a, 17 b, and 17c, respectively, are formed in the wiring layer on the insulating layer 14, so that the state illustrated in FIGS. 1 to 4 is obtained.

### <<Main Effects of First Embodiment>>

Next, main effects of the first embodiment will be described.

The semiconductor device 1A according to the first embodiment includes the contact electrodes 17a and 17b provided to overlap the semiconductor portions 3 on both sides in the gate length direction (Y direction) of the gate electrode 7 in plan view. Then, the contact electrode 17a is connected to each of the upper surface portion 3a and the three side surface portions 3c₁, 3c₂, and 3c₃ of the semiconductor portion 3 provided with one main electrode region 11a of the pair of main electrode regions 11a and 11b provided in the semiconductor portion 3 on both sides in the gate length direction (Y direction) of the gate electrode 7. Therefore, as compared with the conventional case where the contact electrode 17a is connected only to the upper surface portion 3a of the semiconductor portion 3, the contact area between the semiconductor portion 3 (one main electrode region 11a) and the contact electrode 17a increases, and the contact resistance between the semiconductor portion 3 (one main electrode region 11a) and the contact electrode 17a can be reduced. Therefore, according to the semiconductor device 1A according to the first embodiment 1, the transconductance (gm) of the field effect transistor Qa can be improved.

Furthermore, similarly, the contact electrode 17b is connected to each of the upper surface portion 3a and the three side surface portions 3c₁, 3c₂, and 3c₄ of the semiconductor portion 3 provided with the other main electrode region 11b of the pair of main electrode regions 11a and 11b provided in the semiconductor portion 5 on both sides in the gate length direction of the gate electrode 7. Therefore, as compared with the conventional case where the contact electrode 17b is connected only to the upper surface portion 3a of the semiconductor portion 3, the contact area between the semiconductor portion 3 (the other main electrode region 11b) and the contact electrode 17b increases, and the contact resistance between the semiconductor portion 3 (the other main electrode region 11b) and the contact electrode 17b can be reduced. Therefore, according to the semiconductor device 1A according to the first embodiment 1, the transconductance (gm) of the field effect transistor Qa can be improved.

In addition, the contact resistance between the semiconductor portion 3 (one main electrode region 11a) and the contact electrode 17a can be reduced, and the contact resistance between the semiconductor portion 3 (the other main electrode region 11b) and the contact electrode 17b can be reduced, so that the transconductance (gm) of the field effect transistor Qa can be further improved.

In addition, even when the width W₂ of the semiconductor portion 3 in the lateral direction (X direction) and the width W₁ (diameter and width of thickness) of each of the contact electrodes 17a and 17b decrease with the miniaturization of the field effect transistor Qa, an increase in contact resistance between the semiconductor portion 3 and the contact electrodes 17a and 17b can be suppressed, so that it is possible to suppress a decrease in transconductance (gm) while miniaturizing the field effect transistor Qa.

Note that, in the first embodiment described above, the contact electrodes 17a and 17b are formed at a depth separated from the first insulating film 2 of the insulating layer 14, but the contact electrodes 17a and 17b may be formed at a depth reaching the first insulating film 2. In this case, the contact resistance between the semiconductor portion 3 and the contact electrodes 17a and 17 b, specifically, the contact resistance between the pair of main electrode regions 11a and 11b and the contact electrodes 17a and 17b can be further reduced.

Furthermore, in the first embodiment described above, the case where each of the two contact electrodes 17a and 17b is connected to the upper surface portion 3a and the three side surface portions (3c₁, 3c₂, and 3c₃ (or 3c₄)) of the semiconductor portion 3 has been described. However, one of the two contact electrodes 17a and 17b may be connected to the upper surface portion 3a and the three side surface portions (3c₁, 3c₂, and 3c₃ (or 3c₄)) of the semiconductor portion 3, and the other may be connected only to the upper surface portion 3a of the semiconductor portion 3.

### Second Embodiment

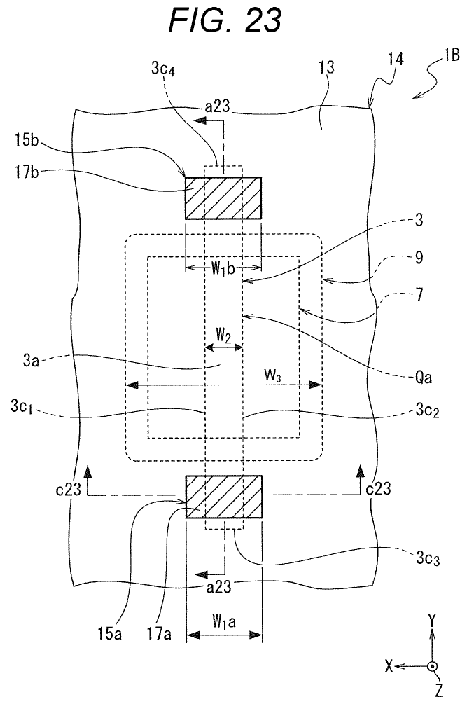

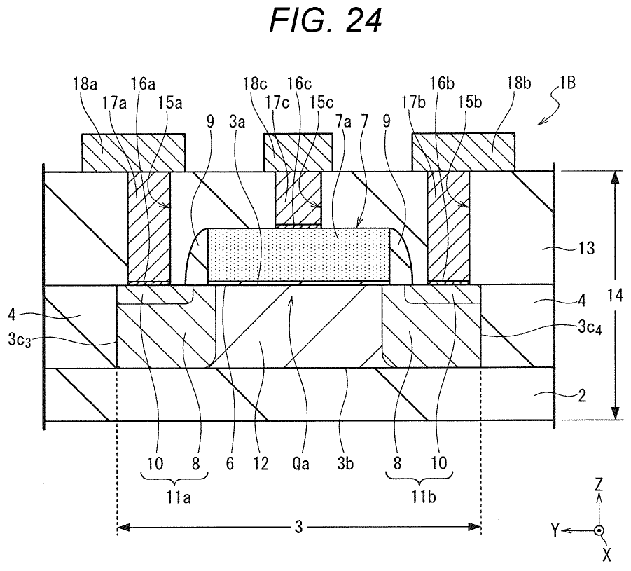

As illustrated in FIGS. 23 to 25, a semiconductor device 1B according to a second embodiment of the present technology basically has a configuration similar to that of the semiconductor device 1A according to the first embodiment described above, and a connection form in which a contact electrode is connected to a side surface portion of a semiconductor portion 3 is different.

That is, as illustrated in FIGS. 1 to 4, the contact electrode 17a of the above-described first embodiment is connected to each of the three side surface portions 3c₁, 3c₂, and 3c₃ of the semiconductor portion 3. Furthermore, the contact electrode 17b is also connected to each of the three side surface portions 3c₁, 3c₂, and 3c₄ of the semiconductor portion 3.

Meanwhile, as illustrated in FIGS. 23 to 25, the contact electrode 17a of the second embodiment is located closer to the gate electrode 7 than one side surface portion 3c₃ of the side surface portions 3c₃ and 3c₄ as two end portions located opposite to each other in the longitudinal direction (Y direction) of the semiconductor portion 3. Then, the contact electrode 17a of the second embodiment is connected to each of the two side surface portions 3c₁ and 3c₂ located on opposite sides in the lateral direction (X direction) of the semiconductor portion 3 among the three side surface portions 3c₁, 3c₂, and 3c₃ of the semiconductor portion 3. That is, the contact electrode 17a of the second embodiment is connected to the upper surface portion 3a of the semiconductor portion 3, and as the side surface portion of the semiconductor portion 3, is connected to each of the two side surface portions 3c₁ and 3c₂ located in the lateral direction (X direction) of the semiconductor portion 3 except for the side surface portion 3c₃ which is one end portion in the longitudinal direction (Y direction) of the semiconductor portion 3.

In addition, also in the contact electrode 17b of the second embodiment, similarly to the contact electrode 17a of the second embodiment, the contact electrode is located closer to the gate electrode 7 than the other side surface portion 3c₄ of the side surface portions 3c₃ and 3c₄ as the two end portions located opposite to each other in the longitudinal direction (Y direction) of the semiconductor portion 3. Then, the contact electrode 17b of the second embodiment is also connected to each of the two side surface portions 3c₁ and 3c₂ located on opposite sides in the lateral direction (X direction) of the semiconductor portion 3 among the three side surface portions 3c₁, 3c₂, and 3c₄ of the semiconductor portion 3. That is, the contact electrode 17b of the second embodiment is also connected to the upper surface portion 3a of the semiconductor portion 3, and as the side surface portion of the semiconductor portion 3, is connected to each of the two side surface portions 3c₁ and 3c₂ located in the lateral direction (X direction) of the semiconductor portion 3 except for the side surface portion 3c₄ which is an end portion in the longitudinal direction (Y direction) of the semiconductor portion 3.

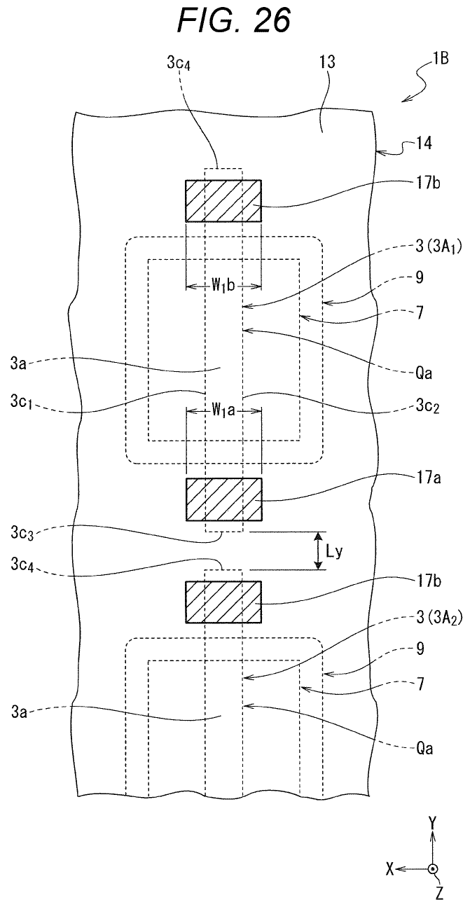

As illustrated in FIG. 26, in the semiconductor device 1B according to the second embodiment, the two semiconductor portions 3 (3A₁ and 3A₂) are arranged in series in the Y direction at predetermined intervals in a direction in which the longitudinal directions (Y directions) of each are the same direction. That is, in the two semiconductor portions 3 (3A₁ and 3A₂), the side surface portion 3c₃ located on one end portion side in the longitudinal direction of the one semiconductor portion 3A₁ and the side surface portion 3c₄ located on the other end portion side in the longitudinal direction of the other semiconductor portion 3A₂ are adjacent to each other and arranged in series in the Y direction. Then, the field effect transistor Qa is provided in each of the two semiconductor portions 3 (3A₁ and 3A₂).

Here, as illustrated in FIG. 26, the contact electrode 17a located on the side surface portion 3c₃ side of the one semiconductor portion 3 (3A₁) is located closer to the gate electrode 7 provided in the one semiconductor portion 3 (3A₁) than the side surface portion 3c₃ in the longitudinal direction of the one semiconductor portion 3 (3A₁). Then, the contact electrode 17b located on the side surface portion 3c₄ side of the other semiconductor portion 3 (3A₂) is located closer to the gate electrode 7 provided in the other semiconductor portion 3 (3A₂) than the side surface portion 304 in the longitudinal direction of the other semiconductor portion 3 (3A₂).

Therefore, according to the semiconductor device 1B according to the second embodiment, as compared with the semiconductor device 1A according to the first embodiment described above, the interval (distance) Ly between the side surface portion 3c₃ of one semiconductor portion 3 (3A₁) and the side surface portion 3c₄ of the other semiconductor portion 3 (3A₂) can be narrowed in plan view, so that the field effect transistor Qa can be arranged more densely. This makes it possible to improve the transconductance (Gm) of the field effect transistor Qa and to achieve high integration of the semiconductor device 1B.

As illustrated in FIGS. 23 to 25, also in the second embodiment, similarly to the above-described first embodiment, the width W₁a of the contact electrode 17a is wider than the width W₂ of the semiconductor portion 3 in the lateral direction (X direction) of the semiconductor portion 3. Then, the width W₁a of the contact electrode 17a is narrower than the width W₃ including the gate electrode 7 and the sidewall spacers 19 provided on both sides of the gate electrode 7.

Furthermore, in the second embodiment, similarly to the first embodiment described above, the width W₁b of the contact electrode 17b is wider than the width W₂ of the semiconductor portion 3 in the lateral direction (X direction) of the semiconductor portion 3. Then, the width W₁b of the contact electrode 17b is narrower than the width W₃ including the gate electrode 7 and the sidewall spacers 19 provided on both sides of the gate electrode 7.

That is, each of the two contact electrodes 17a and 17b is located on the inner side (gate electrode 7 side) of the end portion (side surface portion 3c₃ and side surface portion 3c₄) in the longitudinal direction (Y direction) of the semiconductor portion 3, and each of the widths W₁a and W₁b of the contact electrodes 17a and 17b is narrower than the width W₃ including the gate electrode 7 and the sidewall spacers 19 provided on both sides of the gate electrode 7. Therefore, according to the semiconductor device 1B according to the second embodiment, the transconductance (gm) of the field effect transistor Qa can be improved without increasing the area occupied by the field effect transistor Qa.

Note that, in FIG. 26, illustration of an upper layer than the insulating layer 14 is omitted for convenience of description, similarly to FIG. 1 of the first embodiment described above.

### <<Modification of Second Embodiment>>

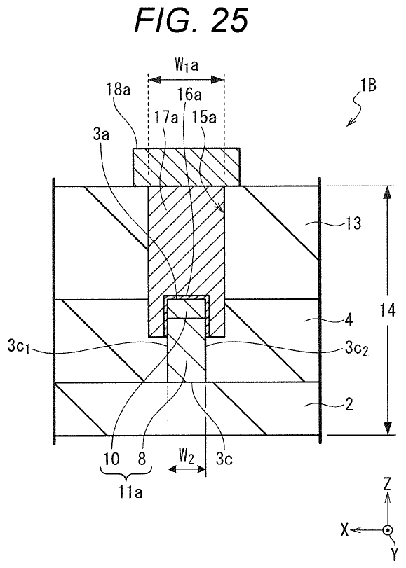

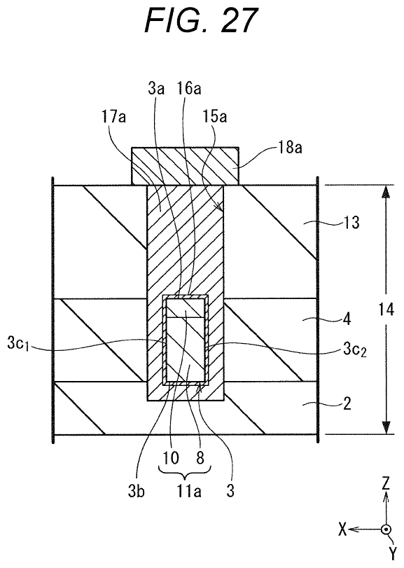

In the second embodiment described above, as illustrated in FIG. 25, the configuration in which each of the contact electrodes 17a and 17b is connected to the upper surface portion 3a and the side surface portions 3c₁ and 3c₂ of the semiconductor portion 3 has been described. However, as illustrated in FIG. 27, the contact electrode 17a may also be connected to the lower surface portion 3b of the semiconductor portion 3.

That is, the contact electrode 17a of this modification is connected to each of the upper surface portion 3a and the two side surface portions 3c₁ and 3c₂ of the semiconductor portion 3, and is also connected to the lower surface portion 3b of the semiconductor portion 3. In addition, the barrier metal film 16a is connected to each of the upper surface portion 3a and the two side surface portions 3c₁ and 3c₂ of the semiconductor portion 3, and is also connected to the lower surface portion 3b of the semiconductor portion 3.

The contact electrode 17a of this modification can be formed by forming the dug portion 15a in the insulating layer 14 so that each of the upper surface portion 3a, the two side surface portions 3c₁ and 3c₂, and the lower surface portion 3b of the semiconductor portion 3 is exposed, then forming the barrier metal film 16a on the surface portion of the semiconductor portion 3 exposed from the dug portion 15a, and then embedding the dug portion 15a with a conductive film so as to wrap around the lower surface portion 3b side of the semiconductor portion 3.

According to the modification of the second embodiment, as compared with the above-described second embodiment, the contact area between the semiconductor portion 3 (one main electrode region 11a) and the contact electrode 17a is increased, and the contact resistance between the semiconductor portion 3 (one main electrode region 11a) and the contact electrode 17a can be further reduced.

Note that, in FIG. 27, the contact electrode 17a is exemplified as an example, but the contact electrode 17b preferably has a configuration similar to that of the contact electrode 17a.

In addition, in FIG. 27, the configuration in which the entire lower surface portion 3b of the semiconductor portion 3 is covered with the contact electrode 17a is exemplified as an example, but the central portion of the lower surface portion 3b in the lateral direction (X direction) of the semiconductor portion 3 may not be selectively covered with the contact electrode.

### Third Embodiment

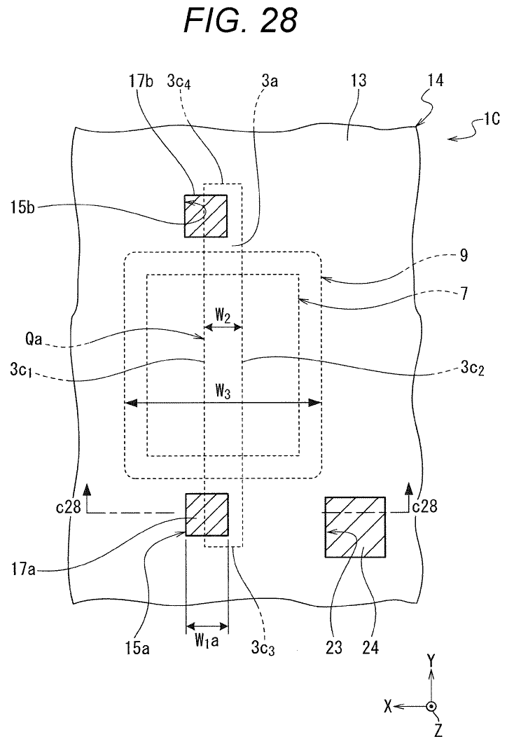

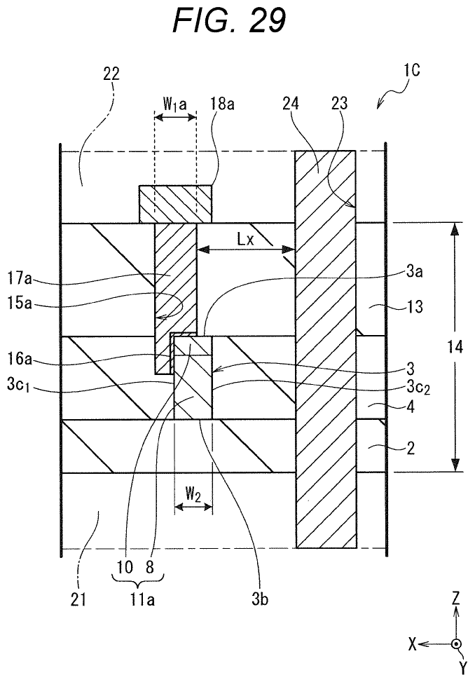

As illustrated in FIGS. 28 and 29, a semiconductor device 1C according to a third embodiment of the present technology basically has a configuration similar to that of the semiconductor device 1B according to the second embodiment described above, and has a different connection form in which a contact electrode is connected to a side surface portion of a semiconductor portion 3.

That is, as illustrated in FIGS. 23 to 25, the contact electrode 17a of the above-described second embodiment is connected to each of the two side surface portions 3c₁ and 3c₂ as a side surface portion of the semiconductor portion 3. Furthermore, the contact electrode 17b is also connected to each of the two side surface portions 3c₁ and 3c₂ as a side surface portion of the semiconductor portion 3.

Meanwhile, as illustrated in FIGS. 28 and 29, each of the contact electrodes 17a and 17b of the third embodiment is connected, as a side surface portion of the semiconductor portion 3, to any one of the two side surface portions 3c₁ and 3c₂ located on opposite sides in the lateral direction (X direction) of the semiconductor portion 3. In FIGS. 28 and 29, the connection form in which each of the contact electrodes 17a and 17b is connected to the side surface portion 301 of the semiconductor portion 3 is exemplified as an example, but each of the contact electrodes 17a and 17b may be connected to the side surface portion 3c₂ opposite to the side surface portion 3c₁ of the semiconductor portion 3.

That is, each of the contact electrodes 17a and 17b of the third embodiment is connected to the upper surface portion 3a of the semiconductor portion 3, and as the side surface portion of the semiconductor portion 3, is selectively connected to one side surface portion 3c₁ located in the lateral direction (X direction) of the semiconductor portion 3 except for the side surface portions 3c₃ and 3c₄ which are the end portions in the longitudinal direction (Y direction) of the semiconductor portion 3 and the other side surface portion 3c₂ located in the lateral direction (X direction) of the semiconductor portion 3.

As illustrated in FIGS. 28 and 29, the semiconductor device 1C according to the third embodiment further includes a through contact electrode 24 that penetrates the insulating layer 14 in the thickness direction of the insulating layer 14 and is provided adjacent to the contact electrode 17a on the outer side in the lateral direction (X direction) of the semiconductor portion 3 in plan view. The through contact electrode 24 is, for example, but not limited to, arranged outside the other side surface portion 3c₂ of the two side surface portions 3c₁ and 3c₂ located opposite to each other in the lateral direction of the semiconductor portion 3.

Then, as illustrated in FIG. 29, the through contact electrode 24 is provided in a dug portion 23 that penetrates the insulating layer 14 in the thickness direction (Z direction) of the insulating layer 14 and extends over a layer 22 provided on the upper surface side of the insulating layer 14 and a layer 21 provided on the lower surface side opposite to the upper surface side of the insulating layer 14.

Here, as illustrated in FIGS. 28 and 29, the contact electrode 17a is selectively connected to one side surface portion 3c₁ on the side opposite to the through contact electrode 24 side of the semiconductor portion 3, of the two side surface portions 3c₁ and 3c₂ located on both sides in the lateral direction (X direction) of the semiconductor portion 3. Therefore, as compared with the case where the contact electrode 17a is connected to each of the two side surface portions 3c₁ and 3c₂ located on both sides in the lateral direction of the semiconductor portion 3 as in the second embodiment described above, the interval (distance) Lx between the contact electrode 17a and the through contact electrode 24 is increased, so that it is possible to reduce the parasitic capacitance using the insulating film between the contact electrode 17a and the through contact electrode 24 as the dielectric film. Therefore, according to the semiconductor device 1C according to the third embodiment, effects similar to those of the second embodiment described above can be obtained, and the parasitic capacitance using the insulating film between the contact electrode 17a and the through contact electrode 24 as the dielectric film can be reduced.

Note that, although not illustrated, even in a case where the through contact electrode 24 is provided adjacent to the contact electrode 17b on the outer side in the lateral direction (X direction) of the semiconductor portion 3 in plan view, the through contact electrode is selectively connected to one side surface portion 3c₁ on the opposite side to the other side surface portion 3c₂ on the through contact electrode 24 side of the semiconductor portion 3 of the two side surface portions 3c₁ and 3c₂ located on both sides in the lateral direction (X direction) of the semiconductor portion 3, whereby the parasitic capacitance using the insulating film between the contact electrode 17b and the through contact electrode 24 as the dielectric film can be reduced.

Note that, in FIG. 28, illustration of an upper layer than the insulating layer 14 is omitted for convenience of description, similarly to FIG. 1 of the first embodiment described above.

### <<Modification of Third Embodiment>>

### <First Modification>

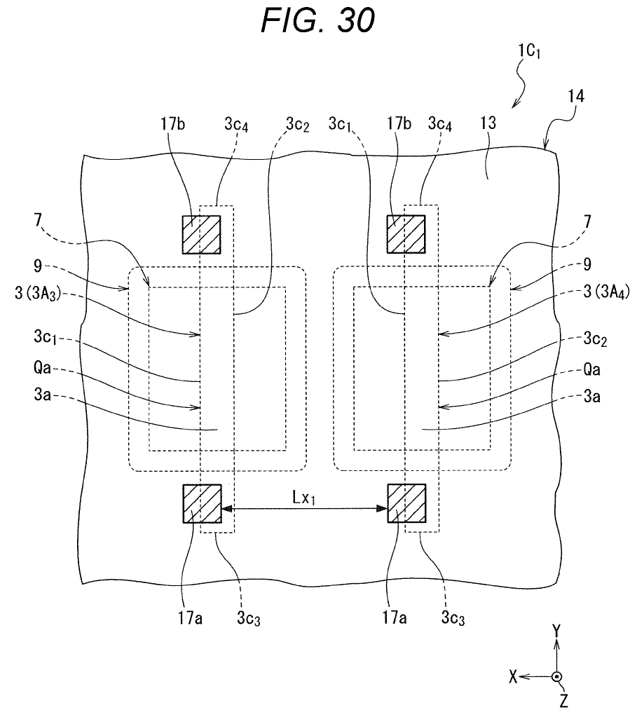

As illustrated in FIG. 30, in a semiconductor device 1C₁ according to a first modification of the third embodiment, two semiconductor portions 3 (3A₃ and 3A₄) are arranged in parallel at a predetermined interval in the X direction in a direction in which the longitudinal directions (Y directions) of each are the same direction. That is, in the two semiconductor portions 3 (3A₃ and 3A₄), the other side surface portion 3c₂ of the two side surface portions 3c₁ and 3c₂ located in the lateral direction of the one semiconductor portion 3 (3A₃) and the one side surface portion 3c₁ of the two side surface portions 3c₁ and 3c₂ located in the lateral direction of the other semiconductor portion 3 (3A₄) are adjacent to each other and arranged in parallel. Then, the field effect transistor Qa is provided in each of the two semiconductor portions 3 (3A₃ and 3A₄).

Here, as illustrated in FIG. 30, in the two semiconductor portions 3 (3A₃ and 3A₄), the other side surface portion 3c₂ located in the lateral direction (X direction) of the one semiconductor portion 3A₃ and the one side surface portion 3c₁ located in the lateral direction (X direction) of the other semiconductor portion 3A₄ are arranged adjacent to each other (facing each other). Then, the contact electrode 17a on the one semiconductor portion 3c₃ side is selectively connected to one side surface portion 301 of the two side surface portions 3c₁ and 3c₂ located on both sides in the lateral direction of the one semiconductor portion 3A₃, and the contact electrode 17a on the other semiconductor portion 3A₄ side is also selectively connected to one side surface portion 3c₁ of the two side surface portions 3c₁ and 3c₂ located on both sides in the lateral direction of the other semiconductor portion 3A₄. Therefore, as compared with the case where the contact electrode 17a is connected to each of the two side surface portions 3c₁ and 3c₂ located on both sides in the lateral direction of the semiconductor portion 3 as in the second embodiment described above, the interval (distance) Lx₁ between the contact electrode 17a on the one semiconductor portion 3A₃ side and the contact electrode 17a on the other semiconductor portion 3A₄ side is increased, so that it is possible to reduce the parasitic capacitance using the insulating film between the contact electrode 17a on the one semiconductor portion 3A₃ side and the contact electrode 17a on the other semiconductor portion 3A₄ side as the dielectric film. Therefore, according to the semiconductor device 1C₁ according to the first modification of the third embodiment, effects similar to those of the above-described second embodiment can be obtained, and the parasitic capacitance using the insulating film between the contact electrode 17a on the one semiconductor portion 3A₃ side and the contact electrode 17a on the other semiconductor portion 3A₄ side as the dielectric film can be reduced.

In addition, as illustrated in FIG. 30, since the interval between the contact electrode 17b on the one semiconductor portion 3A₃ side and the contact electrode 17b on the other semiconductor portion 3A₄ side is also increased, it is possible to reduce the parasitic capacitance using the insulating film between the contact electrode 17a on the one semiconductor portion 3A₃ side and the contact electrode 17b on the other semiconductor portion 3A₄ side as the dielectric film.

Note that, in FIG. 30, illustration of an upper layer than the insulating layer 14 is omitted for convenience of description, similarly to FIG. 1 of the first embodiment described above.

### <Second Modification>

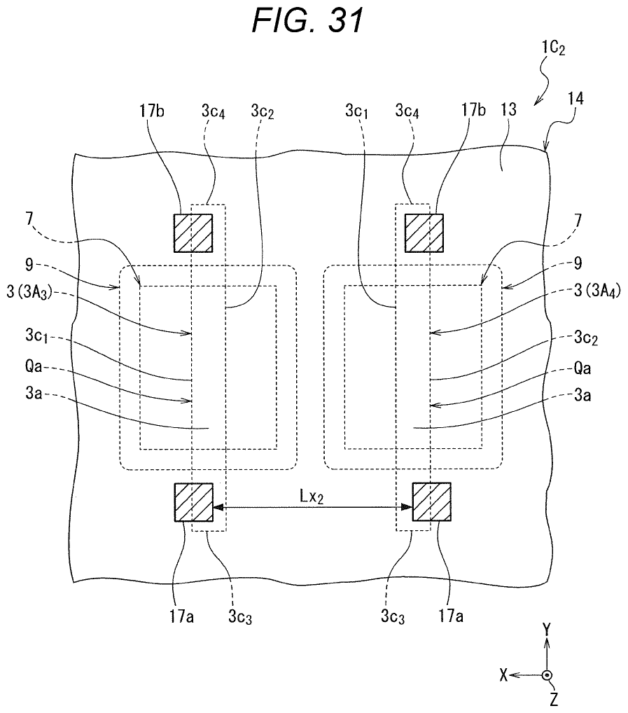

As illustrated in FIG. 31, a semiconductor device 1C₂ according to a second modification of the third embodiment basically has a configuration similar to that of the semiconductor device 1C₁ according to the first modification of the third embodiment described above, and the following configuration is different.

That is, as illustrated in FIG. 31, each of the contact electrodes 17a and 17b on the one semiconductor portion 3 (3A₃) side of the two semiconductor portions 3 (3A₃ and 3A₄) is selectively connected to one side surface portion 3c₁ of the two side surface portions 3c₁ and 3c₂ located on both sides in the lateral direction of the one semiconductor portion 3 (3A₃), similarly to the first modification of the third embodiment described above. Then, each of the contact electrodes 17a and 17b on the other semiconductor portion 3 (3A₄) side of the two semiconductor portions 3 (3A₃ and 3A₄) is different from the first modification of the third embodiment described above, and is selectively connected to the other side surface portion 3c₂ of the two side surface portions 3c₁ and 3c₂ located on both sides in the lateral direction of the other semiconductor portion 3 (3A₄).

Therefore, since the interval (distance) Lx₂ between the contact electrode 17a on the one semiconductor portion 3A₃ side and the contact electrode 17a on the other semiconductor portion 3A₄ side is wider than the interval Lx₁ in the case of the first modification of the third embodiment described above, it is possible to further reduce the parasitic capacitance using the insulating film between the contact electrode 17a on the one semiconductor portion 3A₃ side and the contact electrode 17a on the other semiconductor portion 3A₄ side as the dielectric film.

In addition, as illustrated in FIG. 31, since the interval between the contact electrode 17b on the one semiconductor portion 3A₃ side and the contact electrode 17b on the other semiconductor portion 3A₄ side is also widened, the parasitic capacitance using the insulating film between the contact electrode 17b on the one semiconductor portion 3A₃ side and the contact electrode 17b on the other semiconductor portion 3A₄ side as the dielectric film can be further reduced.

Note that, in FIG. 31, illustration of an upper layer than the insulating layer 14 is omitted for convenience of description, similarly to FIG. 1 of the first embodiment described above.

### <Third Modification>

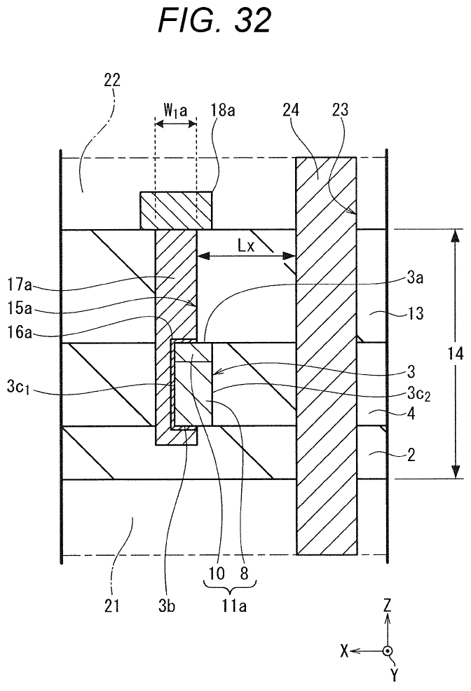

As illustrated in FIG. 32, similarly to the modification of the second embodiment described above, the contact electrode 17a may be connected to the lower surface portion 3b of the semiconductor portion 3.

That is, the contact electrode 17a of a third modification is connected to the upper surface portion 3a of the semiconductor portion 3, is connected to one side surface portion 3c₁ of the two side surface portions 3c₁ and 3c₂, and is also connected to the lower surface portion 3b of the semiconductor portion 3. In addition, the barrier metal film 16a is also connected to the upper surface portion 3a of the semiconductor portion 3, is connected to one side surface portion 3c₁ of the two side surface portions 3c₁ and 3c₂, and is also connected to the lower surface portion 3b of the semiconductor portion 3.

Note that, in FIG. 32, the contact electrode 17a is illustrated as an example, but the contact electrode 17b may also have a configuration similar to that of the contact electrode 17a illustrated in FIG. 32.

### Fourth Embodiment

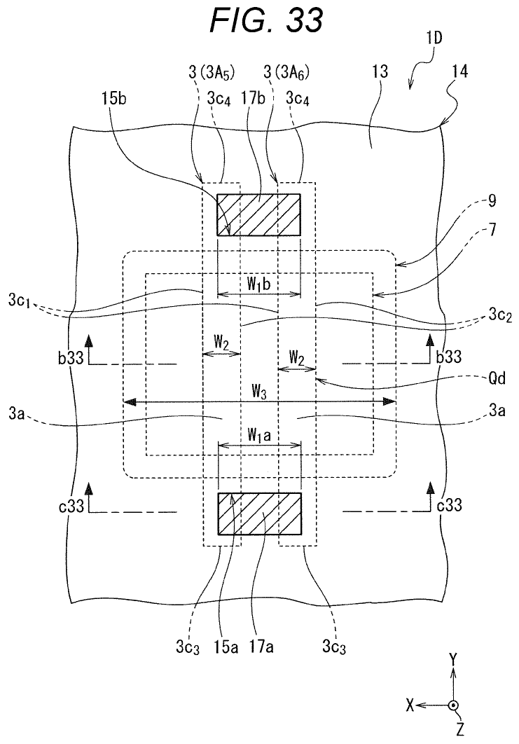

As illustrated in FIGS. 33 to 35, a semiconductor device 1D according to a fourth embodiment of the present technology basically has a configuration similar to that of the semiconductor device 1C according to the above-described third embodiment, and the following configuration is different.

That is, as illustrated in FIGS. 33 to 35, the semiconductor device 1D according to the fourth embodiment of the present technology includes two semiconductor portions 3 (3A₅ and 3A₆) arranged in parallel with the lateral directions aligned with the X direction, and a field effect transistor Qd in which a gate electrode 7 is provided on each of the two semiconductor portions 3 (3A₅ and 3A₆) with a gate insulating film 6 interposed therebetween.

The field effect transistor Qd basically has a configuration similar to that of the field effect transistor Qa described above, and the configuration of the gate electrode 7 is different. Other configurations are substantially similar to those of the field effect transistor Qa described above.

As illustrated in FIGS. 33 to 35, the gate electrode 7 of the field effect transistor Qd includes a head portion 7a provided on the upper surface portion 3a side of each of the two semiconductor portions 3 (3A₅ and 3A₆) with the gate insulating film 6 interposed therebetween and extending in the lateral direction (X direction) over the two semiconductor portions 3 (3A₅ and 3A₆), and three leg portions 7b₁, 7b₂, and 7b₃ integrated with the head portion 7a and provided side by side in the lateral direction of each of the two semiconductor portions 3 (3A₅ and 3A₆).

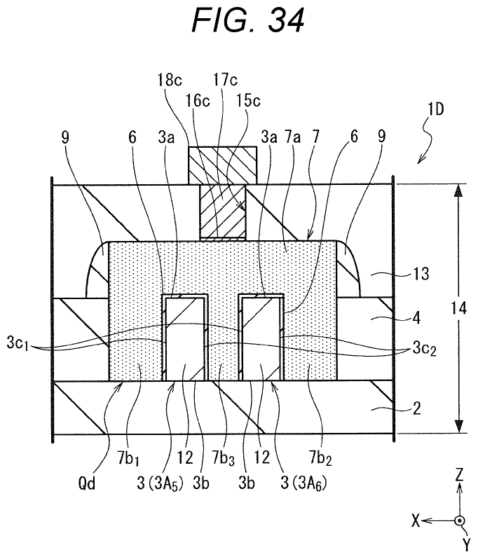

As illustrated in FIG. 34, the leg portion 7b₁ is provided outside one side surface portion 3c₁ of the two side surface portions 3c₁ and 3c₂ located on both sides in the lateral direction of one semiconductor portion 3 (3A₅) of the two semiconductor portions 3 (3A₅ and 3A₆) with the gate insulating film 6 interposed therebetween.

The leg portion 7b₂ is provided outside the other side surface portion 3c₂ of the two side surface portions 3c₁ and 3c₂ located on both sides in the lateral direction of the other semiconductor portion 3 (3A₆) of the two semiconductor portions 3 (3A₅ and 3A₆) with the gate insulating film 6 interposed therebetween.

The leg portion 7b₃ is provided between the two semiconductor portions 3 (3A₅ and 3A₆). Then, in the two semiconductor portions 3 (3A₅ and 3A₆), the leg portion 7b₃ is adjacent to the other side surface portion 3c₂ of the two side surface portions 3c₁ and 3c₂ located on both sides in the lateral direction of the one semiconductor portion 3 (3A₅) with the gate insulating film 6 interposed therebetween, and is adjacent to the one side surface portion 3c₁ of the two side surface portions 3c₁ and 3c₂ located on both sides in the lateral direction of the other semiconductor portion 3 (3A₆) with the gate insulating film 6 interposed therebetween.

Here, the semiconductor device 1D according to the fourth embodiment also includes the contact electrodes 17a and 17b similarly to the semiconductor device 1C according to the third embodiment described above, but each of the contact electrodes 17a and 17b according to the fourth embodiment is connected to a side surface portion of each of the two semiconductor portions 3 (3A₅ and 3A₆).

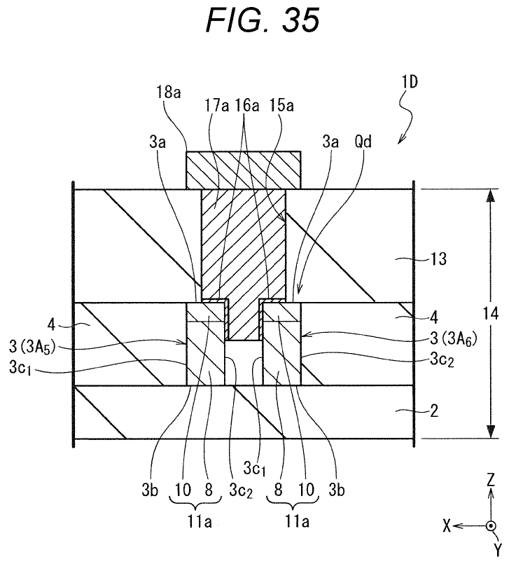

Specifically, as illustrated in FIGS. 33 and 35, in the two semiconductor portions 3 (3A₅ and 3A₆), the contact electrode 17a of the fourth embodiment is selectively connected to the other side surface portion 3c₂ of the two side surface portions 3c₁ and 3c₂ located on both sides in the lateral direction of the one semiconductor portion 3 (3A₅) and the one side surface portion 3c₁ of the two side surface portions 3c₁ and 3c₂ located on both sides in the lateral direction of the other semiconductor portion 3 (3A₆). Then, in the contact electrode 17b of the fourth embodiment, similarly to the contact electrode 17a of the fourth embodiment, in the two semiconductor portions 3 (3A₅ and 3A₆), the other side surface portion 3c₂ located in the lateral direction of the one semiconductor portion 3 (3A₅) and the one side surface portion 3c₁ located in the lateral direction of the other semiconductor portion 3 (3A₆) are selectively connected.

That is, each of the contact electrodes 17a and 17b of the fourth embodiment is connected to the upper surface portion 3a of each of the two semiconductor portions 33 (3A₅ and 3A₆), and as the side surface portion of each of the two semiconductor portions 3 (3A₅ and 3A₆), is selectively connected to the other side surface portion 3c₂ located in the lateral direction of the one semiconductor portion 3 (3A₅) and the one side surface portion 3c₁ located in the lateral direction of the other semiconductor portion 3 (3A₆).

Also in the semiconductor device 1D according to the fourth embodiment, effects similar to those of the semiconductor device 1C according to the third embodiment described above can be obtained.

Note that, in FIG. 33, illustration of an upper layer than the insulating layer 14 is omitted for convenience of description, similarly to FIG. 1 of the first embodiment described above.

### Fifth Embodiment

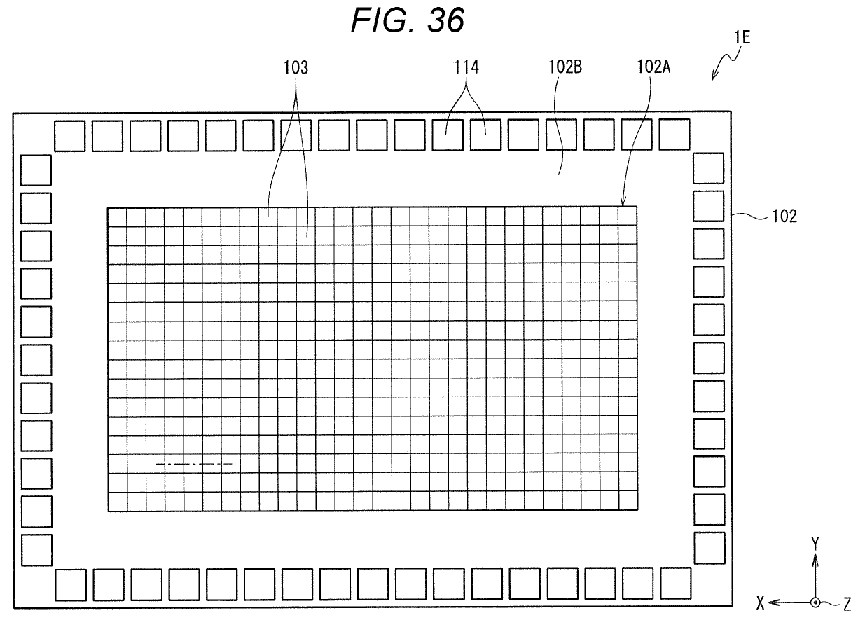

In a fifth embodiment, an example in which the present technology is applied to a solid-state imaging device called a back-illuminated complementary metal oxide semiconductor (CMOS) image sensor as a light detection device included in a semiconductor device will be described with reference to FIGS. 36 to 39.

### <<Overall Configuration of Solid-State Imaging Device>>

First, an overall configuration of a solid-state imaging device 1E will be described.

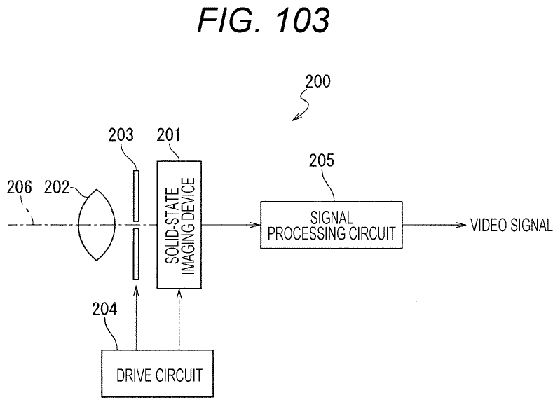

As illustrated in FIG. 36, the solid-state imaging device 1E according to the fifth embodiment of the present technology mainly includes a semiconductor chip 102 having a two-dimensional planar shape of a square in plan view. That is, the solid-state imaging device 1E is mounted on the semiconductor chip 102, and the semiconductor chip 102 can be regarded as the solid-state imaging device 1E. As illustrated in FIG. 103, the solid-state imaging device 1E (201) takes in image light (incident light 206) from a subject via an optical lens 202, converts the light amount of the incident light 206 formed on the imaging surface into an electrical signal in units of pixels, and outputs the electrical signal as a pixel signal (image signal).

As illustrated in FIG. 36, the semiconductor chip 102 on which the solid-state imaging device 1E is mounted includes a rectangular pixel array unit 102A provided in a central portion in a two-dimensional plane including an X direction and a Y direction orthogonal to each other, and a peripheral portion 102B provided outside the pixel array unit 102A so as to surround the pixel array unit 102A. The semiconductor chip 102 is formed by fragmenting a semiconductor wafer including a semiconductor layer 130 described later for each chip formation region in a manufacturing process. Therefore, the configuration of the solid-state imaging device 1E described below is substantially similar even in a wafer state before the semiconductor wafer is divided into small pieces. That is, the present technology can be applied in a state of a semiconductor chip and a state of a semiconductor wafer.

The pixel array unit 102A is, for example, a light receiving surface that receives light condensed by the optical lens (optical system) 202 illustrated in FIG. 103. Then, in the pixel array unit 102A, a plurality of pixels 103 is arranged in a matrix on a two-dimensional plane including the X direction and the Y direction. In other words, the pixels 103 are repeatedly arranged in the X direction and the Y direction orthogonal to each other in the two-dimensional plane.

As illustrated in FIG. 36, a plurality of bonding pads 114 is arranged in the peripheral portion 102B. Each of the plurality of bonding pads 114 is arranged along each of four sides in the two-dimensional plane of the semiconductor chip 102, for example. Each of the plurality of bonding pads 114 functions as an input/output terminal that electrically connects the semiconductor chip 102 and an external device.

### <Logic Circuit>

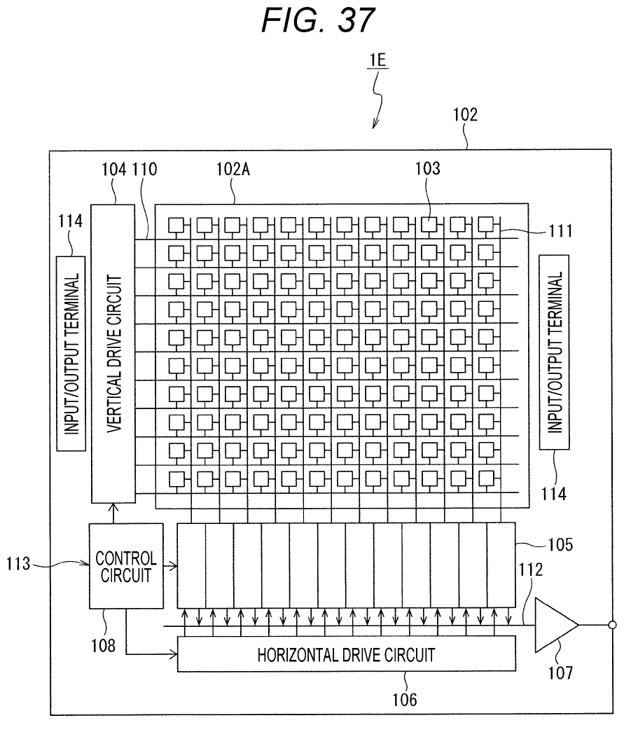

The semiconductor chip 102 includes a logic circuit 113 illustrated in FIG. 37. As illustrated in FIG. 37, the logic circuit 113 includes a vertical drive circuit 104, a column signal processing circuit 105, a horizontal drive circuit 106, an output circuit 107, a control circuit 108, and the like. The logic circuit 113 includes, for example, a complementary MOS (CMOS) circuit including an n-channel conductivity type metal oxide semiconductor field effect transistor (MOSFET) and a p-channel conductivity type MOSFET as field effect transistors.

The vertical drive circuit 104 includes, for example, a shift register. The vertical drive circuit 104 sequentially selects a desired pixel drive line 110, supplies a pulse for driving the pixel 103 to the selected pixel drive line 110, and drives each pixel 103 row by row. That is, the vertical drive circuit 104 selectively scans each pixel 103 of the pixel array unit 102A sequentially in the vertical direction in units of rows, and supplies the pixel signal from the pixel 103 based on the signal charge generated according to the amount of received light by the photoelectric conversion unit (photoelectric conversion element) of each pixel 103 to the column signal processing circuit 105 through the vertical signal line 111.

The column signal processing circuit 105 is arranged, for example, for each column of the pixels 103, and performs signal processing such as noise removal for each pixel column on the signals output from the pixels 103 of one row. For example, the column signal processing circuit 105 performs signal processing such as correlated double sampling (CDS) for removing pixel-specific fixed pattern noise and analog digital (AD) conversion.

The horizontal drive circuit 106 includes, for example, a shift register. The horizontal drive circuit 106 sequentially outputs the horizontal scanning pulse to the column signal processing circuit 105 to sequentially select each of the column signal processing circuits 105, and causes each of the column signal processing circuits 105 to output the pixel signal subjected to the signal processing to the horizontal signal line 112.

The output circuit 107 performs signal processing on the pixel signals sequentially supplied from each of the column signal processing circuits 105 through the horizontal signal line 112, and outputs the pixel signals. As the signal processing, for example, buffering, black level adjustment, column variation correction, various digital signal processing, and the like can be used.

The control circuit 108 generates a clock signal or a control signal serving as a reference of operations of the vertical drive circuit 104, the column signal processing circuit 105, the horizontal drive circuit 106, and the like on the basis of the vertical synchronization signal, the horizontal synchronization signal, and the master clock signal. Then, the control circuit 108 outputs the generated clock signal and control signal to the vertical drive circuit 104, the column signal processing circuit 105, the horizontal drive circuit 106, and the like.

### <Circuit Configuration of Pixel>

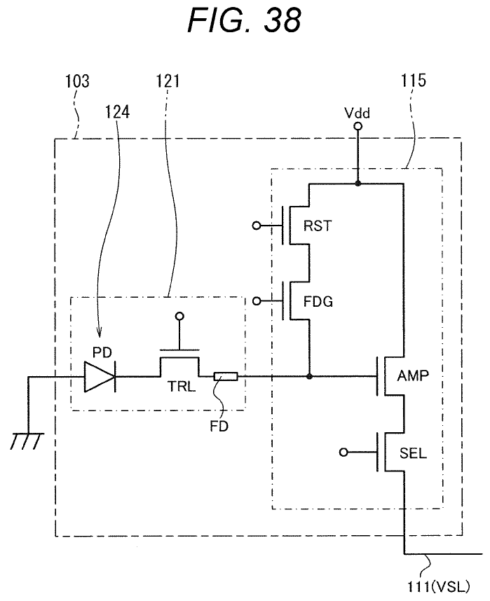

Each pixel 103 of the plurality of pixels 103 illustrated in FIGS. 36 and 37 includes a photoelectric conversion region 121 and a pixel circuit (readout circuit) 115 illustrated in FIG. 38. The photoelectric conversion region 121 includes a photoelectric conversion unit 124, a transfer transistor TR, and a charge holding region (floating diffusion) FD. The pixel circuit 115 is electrically connected to the charge holding region FD of the photoelectric conversion region 121. In the fifth embodiment, as an example, one pixel circuit 115 is allocated to one pixel 103, but the circuit configuration is not limited thereto, and one pixel circuit 115 may be shared by a plurality of pixels 103. For example, a circuit configuration may be employed in which one pixel circuit 115 is shared by four pixels 103 (one pixel block) arranged in 2×2, two pixels being arranged in each of the X direction and the Y direction.

The photoelectric conversion unit 124 illustrated in FIG. 38 includes, for example, a pn junction type photodiode (PD), and generates a signal charge according to the amount of received light. In the photoelectric conversion unit 124, a cathode side is electrically connected to a source region of the transfer transistor TR, and an anode side is electrically connected to a reference potential line (for example, ground).

The transfer transistor TR illustrated in FIG. 38 transfers the signal charge photoelectrically converted by the photoelectric conversion unit 124 to the charge holding region FD. The source region of the transfer transistor TR is electrically connected to the cathode side of the photoelectric conversion unit 124, and the drain region of the transfer transistor TR is electrically connected to the charge holding region FD. Then, the gate electrode of the transfer transistor TR is electrically connected to the transfer transistor drive line of the pixel drive line 110 (see FIG. 37).

The charge holding region FD illustrated in FIG. 38 temporarily holds (accumulates) the signal charge transferred from the photoelectric conversion unit 124 via the transfer transistor TR.

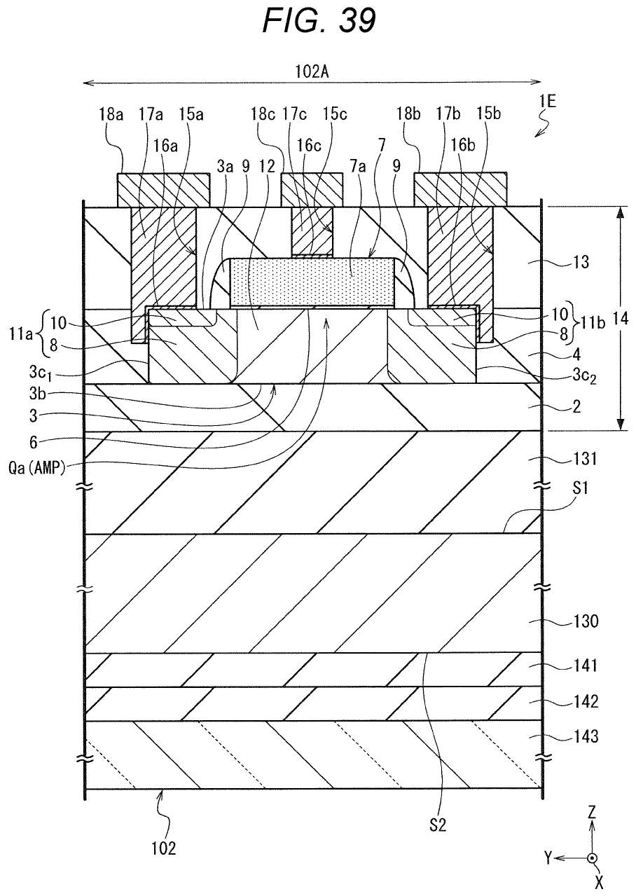

The photoelectric conversion unit 124, the transfer transistor TR, and the photoelectric conversion region 121 including the charge holding region FD are mounted on the semiconductor layer 130 (see FIG. 39) as a second semiconductor layer to be described later.

The pixel circuit 115 illustrated in FIG. 38 reads the signal charges held in the charge holding region FD, converts the read signal charges into a pixel signal, and outputs the pixel signal. In other words, the pixel circuit 115 converts the signal charge photoelectrically converted by the photoelectric conversion unit 124 into a pixel signal based on the signal charge and outputs the pixel signal. The pixel circuit 115 includes, but is not limited to, an amplification transistor AMP, a selection transistor SEL, a reset transistor RST, and a switching transistor FDG, for example, as pixel transistors. Each of these pixel transistors (AMP, SEL, RST, and FDG) and the above-described transfer transistor TR is configured by, for example, a MOSFET as a field effect transistor. Furthermore, these transistors may be MISFETs.

Among the pixel transistors included in the pixel circuit 115, each of the selection transistor SEL, the reset transistor RST, and the switching transistor FDG functions as a switching element, and the amplification transistor AMP functions as an amplification element. That is, the pixel circuit 115 includes field effect transistors for different applications.

Note that the selection transistor SEL and the switching transistor FDG may be omitted as necessary.

As illustrated in FIG. 38, in the amplification transistor AMP, the source region is electrically connected to the drain region of the selection transistor SEL, and the drain region is electrically connected to the power supply line Vdd and the drain region of the reset transistor RST. Then, the gate electrode of the amplification transistor AMP is electrically connected to the charge holding region FD and the source region of the switching transistor FDG.

A source of the selection transistor SEL is electrically connected to the vertical signal line 111 (VSL), and a drain region thereof is electrically connected to a source region of the amplification transistor AMP. Then, the gate electrode of the selection transistor SEL is electrically connected to a selection transistor drive line of the pixel drive line 110 (see FIG. 37).

The reset transistor RST has a source region electrically connected to the drain region of the switching transistor FDG, and a drain region electrically connected to the power supply line Vdd and the drain region of the amplification transistor AMP. Then, the gate electrode of the reset transistor RST is electrically connected to the reset transistor drive line among the pixel drive lines 110 (see FIG. 37).

The switching transistor FDG has a source region electrically connected to the charge holding region FD and the gate electrode of the amplification transistor AMP, and a drain region electrically connected to the power supply line Vdd and the drain region of the amplification transistor AMP. Then, the gate electrode of the switching transistor FDG is electrically connected to the switching transistor drive line of the pixel drive line 110 (see FIG. 37).

Note that, in a case where the selection transistor SEL is omitted, the source region of the amplification transistor AMP is electrically connected to the vertical signal line 111 (VSL). Furthermore, in a case where the switching transistor FDG is omitted, the source region of the reset transistor RST is electrically connected to the gate electrode of the amplification transistor AMP and the charge holding region FD.

When the transfer transistor TR is turned on, the transfer transistor TR transfers the signal charge generated by the photoelectric conversion unit 124 to the charge holding region FD.

When the reset transistor RST is turned on, the reset transistor RST resets the potential (signal charge) of the charge holding region FD to the potential of the power supply line Vdd. The selection transistor SEL controls an output timing of the pixel signal from the pixel circuit 115.

The amplification transistor AMP generates a signal of a voltage corresponding to the level of the signal charge held in the charge holding region FD as a pixel signal. The amplification transistor AMP constitutes a source follower type amplifier, and outputs a pixel signal having a voltage corresponding to the level of the signal charge generated by the photoelectric conversion unit 124. When the selection transistor SEL is turned on, the amplification transistor AMP amplifies the potential of the charge holding region FD and outputs a voltage corresponding to the potential to the column signal processing circuit 105 via the vertical signal line 111 (VSL).

The switching transistor FDG controls charge retention by the charge holding region FD, and adjusts the multiplication factor of the voltage according to the potential amplified by the amplification transistor AMP.

During the operation of the solid-state imaging device 1E according to the fifth embodiment, the signal charge generated in the photoelectric conversion unit 124 of the pixel 103 is held (accumulated) in the charge holding region FD via the transfer transistor TR of the pixel 103. Then, the signal charge held in the charge holding region FD is read by the pixel circuit 115 and applied to the gate electrode of the amplification transistor AMP of the pixel circuit 115. A horizontal line selection control signal is supplied from the vertical shift register to the gate electrode of the selection transistor SEL of the pixel circuit 115. Then, by setting the selection control signal to the high (H) level, the selection transistor SEL is conducted, and the current corresponding to the potential of the charge holding region FD, amplified by the amplification transistor AMP, flows through the vertical signal line 111. Furthermore, by setting the reset control signal applied to the gate electrode of the reset transistor RST of the pixel circuit 115 to the high (H) level, the reset transistor RST is conducted, and the signal charge accumulated in the charge holding region FD is reset.

### <<Longitudinal Cross-Sectional Structure of Solid-State Imaging Device>>

Next, a longitudinal cross-sectional structure of the semiconductor chip 102 (solid-state imaging device 1E) will be described with reference to FIG. 39. FIG. 39 is a schematic longitudinal cross-sectional view illustrating a longitudinal cross-sectional structure in the pixel array unit of FIG. 36, and is upside down with respect to FIG. 36 in order to make the drawing easy to see.

### <Semiconductor Chip>

As illustrated in FIG. 39, the semiconductor chip 102 includes a semiconductor layer 130 having a first surface S1 and a second surface S2 located on opposite sides in the thickness direction (Z direction), and an insulating layer 131 provided on the first surface S1 side of the semiconductor layer 130.

In addition, the semiconductor chip 102 includes, on the second surface S2 side of the semiconductor layer 130, a planarization layer 141, a color filter layer 142, a lens layer 143, and the like sequentially laminated from the second surface S2 side.

In addition, the semiconductor chip 102 includes an insulating layer 14 provided on the side of the insulating layer 131 opposite to the semiconductor layer 130 side. The insulating layer 14 of the fifth embodiment has a configuration similar to that of the insulating layer 14 illustrated in FIGS. 2 to 4 of the first embodiment described above as an example, and includes an island-shaped semiconductor portion 3 and a field effect transistor Qa in which a gate electrode 7 is provided in the semiconductor portion 3 with a gate insulating film 6 interposed therebetween.

Furthermore, the semiconductor chip 102 further includes contact electrodes 17a and 17b provided on the insulating layer 14 so as to overlap the island-shaped semiconductor portion 3 in plan view. The contact electrodes 17a and 17b of the fifth embodiment have a configuration similar to that of the contact electrodes 17a and 17b illustrated in FIGS. 2 to 4 of the first embodiment described above as an example.

The semiconductor layer 130 is constituted by, for example, monocrystalline silicon.

The planarization layer 141 is constituted by, for example, a silicon oxide film. Then, the planarization layer 141 covers the entire second surface S2 side of the semiconductor layer 130 in the pixel array unit 102A such that the second surface S2 (light incident surface) side of the semiconductor layer 130 is a flat surface without unevenness.

In the color filter layer 142, color filters such as red (R), green (G), and blue (B) are provided for each pixel 103, and color-separate incident light incident from the light incident surface side of the semiconductor chip 102.

In the lens layer 143, a microlens that condenses the irradiation light and efficiently causes the condensed light to enter the photoelectric conversion region 121 is provided for each pixel 103.

The semiconductor layer 130 is arranged to overlap the semiconductor portion 5. That is, the semiconductor chip 102 has a two-step structure in which the semiconductor layer 130 and the semiconductor portion 3 are laminated in each thickness direction (Z direction).

In the fifth embodiment, each of the photoelectric conversion unit 124, the transfer transistor TR, and the charge holding region FD illustrated in FIG. 38 is provided in the semiconductor layer 130 illustrated in FIG. 39 although not illustrated in detail.

Meanwhile, each of the pixel transistors (AMP, SEL, RST, and FDG) included in the pixel circuit 115 of FIG. 38 includes a field effect transistor Qa illustrated in FIG. 39. Then, in FIG. 39, an amplification transistor AMP including a field effect transistor Qa is illustrated as an example.

### <<Main Effects of Fifth Embodiment>>

In the solid-state imaging device 1E according to the fifth embodiment, each of the pixel transistors (AMP, SEL, RST, and FDG) included in the pixel circuit 115 includes a field effect transistor Qa provided in the semiconductor portion 3. Then, of the contact electrodes 17a and 17b provided on both end portion sides in the longitudinal direction of the semiconductor portion 3 so as to overlap with the semiconductor portion 3, the contact electrode 17a is connected to the upper surface portion 3a of the semiconductor portion 3 and is connected to each of the three side surface portions 3c₁, 3c₂, and 3c₃ as the side surface portion of the semiconductor portion 3, similarly to the first embodiment described above. In addition, the contact electrode 17b provided on both end portion sides in the longitudinal direction of the semiconductor portion 3 so as to overlap the semiconductor portion 3 is also connected to the upper surface portion 3a of the semiconductor portion 3 and connected to each of the three side surface portions 3c₁, 3c₂, and 3c₄ as the side surface portion of the semiconductor portion 3, similarly to the first embodiment described above.

Therefore, according to the solid-state imaging device 1E according to the fifth embodiment, it is possible to improve the transconductance (gm) of each of the pixel transistors (AMP, SEL, RST, and FDG) included in the pixel circuit 115, similarly to the above-described first embodiment.

In addition, even when the width W₂ in the lateral direction (Y direction) of the semiconductor portion 3 and the width W₁ (diameter and width of thickness) of each of the contact electrodes 17a and 17b decrease as the pixel transistors (AMP, SEL, RST, and FDG) included in the pixel circuit 115 are miniaturized, an increase in contact resistance between the semiconductor portion 3 and the contact electrodes 17a and 17b can be suppressed, so that it is possible to suppress a decrease in transconductance (gm) while miniaturizing the pixel transistors (AMP, SEL, RST, and FDG).

Here, in the amplification transistor AMP, it is important to suppress deterioration of noise resistance such as 1/f noise or RTS noise as compared with a pixel transistor (SEL, RST, and FDG) functioning as a switching element. Therefore, the effectiveness is particularly high in a case where the present technology is applied to the connection between the semiconductor portion 3 provided with the amplification transistor AMP included in the pixel circuit 115 and the contact electrode.

Note that, in the fifth embodiment, the case where the connection form of the first embodiment described above is applied as the connection form for connecting the contact electrodes 17a and 17b to the semiconductor portion 3 has been described, but it is a matter of course that the connection forms in the other embodiments and modifications described above can also be applied to the fifth embodiment.

Furthermore, at least one of the pixel transistors (AMP, SEL, RST, or FDG) included in the pixel circuit 115 may be configured by the field effect transistor Qa provided in the semiconductor portion 3.

### Sixth Embodiment

In a sixth embodiment, a semiconductor device having a contact electrode formed in the same layer as a gate electrode of a field effect transistor will be described.

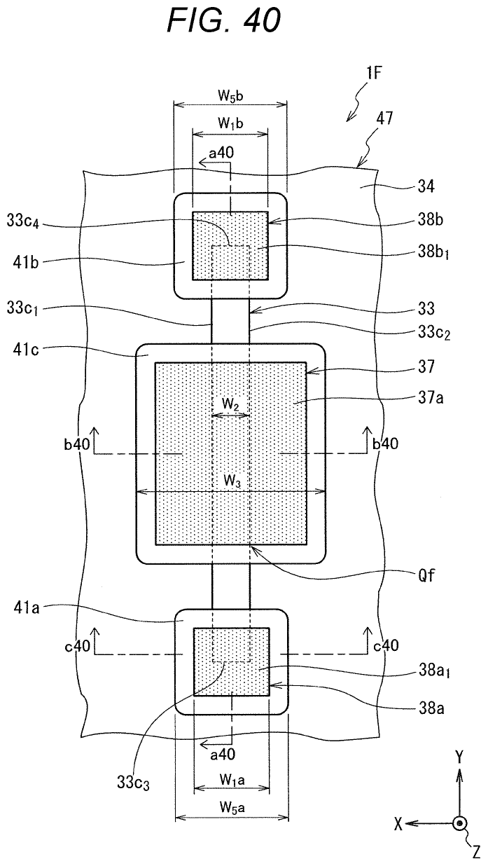

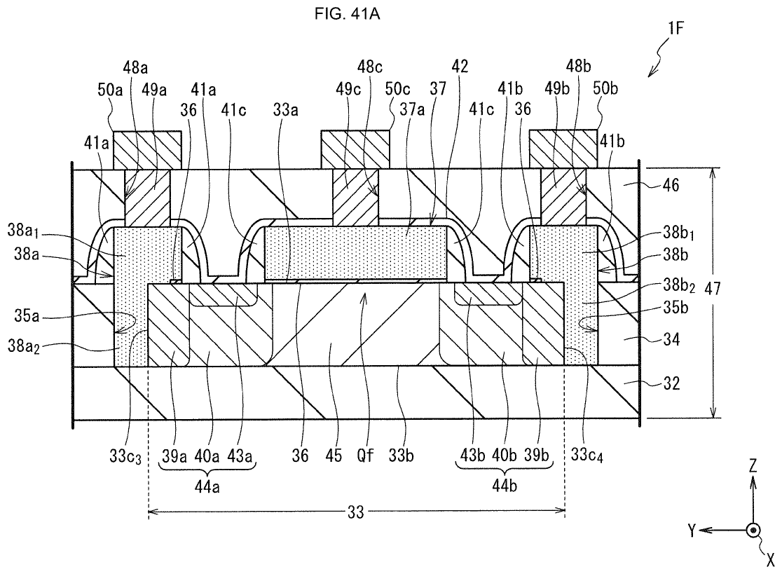

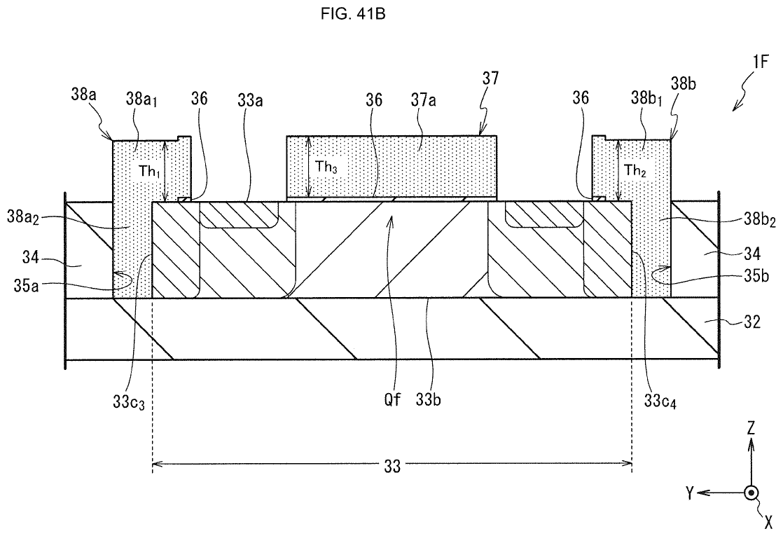

First, an overall configuration of a semiconductor device 1F will be described with reference to FIGS. 40, 41, 41A, 42, and 43. In FIG. 40, for convenience of description, illustration of an upper layer (buffer insulating film 42, third insulating film 46, contact electrodes 49a, 49b, and 49c, wirings 50a, 50b, and 50c, and the like) than the sidewall spacers 41a, 41b, and 41c illustrated in FIGS. 41, 42, and 43 is omitted.

As illustrated in FIGS. 40 to 43, the semiconductor device 1F according to the sixth embodiment of the present technology includes an island-shaped semiconductor portion 33 and a field effect transistor Qf in which a channel formation portion (channel region) 45 is provided in the island-shaped semiconductor portion 33.

In addition, as illustrated in FIGS. 40 to 43, the semiconductor device 1F according to the sixth embodiment of the present technology further includes an insulating layer 47 including the semiconductor portion 33 and the field effect transistor Qf, and contact electrodes 38a and 38b provided on the insulating layer 47 so as to overlap the island-shaped semiconductor portion 33 in plan view.

In addition, as illustrated in FIGS. 41 to 43, the semiconductor device 1F according to the sixth embodiment of the present technology further includes contact electrodes 49a and 49b provided in the insulating layer 47 so as to overlap the contact electrodes 38a and 38b, respectively.

Here, in the sixth embodiment, the contact electrodes 38a and 38b correspond to a specific example of the “contact electrode” or a “first contact electrode” of the present technology, and the contact electrodes 49a and 49b correspond to a specific example of the “second contact electrode” of the present technology.

### <Semiconductor Portion>

As illustrated in FIGS. 40 to 43, the semiconductor portion 33 has, for example, a rectangular parallelepiped shape having an upper surface portion 33a, a lower surface portion (bottom surface portion) 33b, and four side surface portions 33c₁, 33c₂, 33c₃, and 33c₄. Then, as an example, the semiconductor portion 33 extends in the Y direction, the thickness direction is the Z direction, the longitudinal direction is the Y direction, and the lateral direction is the X direction. The upper surface portion 33a and the lower surface portion 33b are located on opposite sides in the thickness direction (Z direction) of the semiconductor portion 33. Among the four side surface portions 33c₁, 33c₂, 33c₃, and 33c₄, the two side surface portions 33c₁ and 33c₂ are located on opposite sides in the X direction, and the remaining two side surface portions 33c₃ and 33c₄ are located on opposite sides in the Y direction.

Here, in the sixth embodiment, the semiconductor portion 33 corresponds to a specific example of the “semiconductor portion” of the present technology. Then, the four side surface portions 33c₁, 33c₂, 33c₃, and 33c₄ of the semiconductor portion 33 correspond to a specific example of the “side surface portion of the semiconductor portion” of the present technology. Then, the four side surface portions 33c₁, 33c₂, 33c₃, and 33c₄ may be referred to as a first side surface portion 33c₁, a second side surface portion 33c₂, a third side surface portion 33c₃, and a fourth side surface portion 33c₄, respectively.

Furthermore, in the sixth embodiment, the lateral direction of the semiconductor portion 33 corresponds to a specific example of the “first direction of the semiconductor portion” of the present technology, and the longitudinal direction of the semiconductor portion 33 corresponds to a specific example of the “second direction of the semiconductor portion” of the present technology. Then, the side surface portions 33c₃ and 33c₄ located on the end portion side in the longitudinal direction (second direction) of the semiconductor portion 33 correspond to a specific example of the “end portion in the second direction intersecting the first direction of the semiconductor portion” of the present technology.

Although not limited thereto, similarly to the semiconductor portion 3 described above, the semiconductor portion 33 is constituted by, for example, silicon (Si) as a semiconductor material, for example, a single crystal as crystallinity, and for example, i-type (intrinsic type) as a conductivity type. That is, the semiconductor portion 33 is constituted by i-type monocrystalline silicon. In addition to Si, germanium (Ge), silicon germanium (SiGe), gallium arsenide (GaAs), indium phosphide (InP), or the like can also be used as the material of the semiconductor portion 33.

### <Insulating Layer>

As illustrated in FIGS. 40 to 43, the insulating layer 47 has a multilayer structure including, but not limited to, a first insulating film (base insulating film) 32 provided on the lower surface portion 33b side opposite to the upper surface portion 33a of the semiconductor portion 33 so as to be in contact with the lower surface portion 33b, a second insulating film (surrounding insulating film) 34 provided on the first insulating film 32 so as to surround the semiconductor portion 33, and a third insulating film (covering insulating film) 46 provided on the second insulating film 34 so as to cover the semiconductor portion 33 and the field effect transistor Qf. Then, the insulating layer 47 of the sixth embodiment further includes, but is not limited to, a buffer insulating film 42. Each of the first insulating film 32, the second insulating film 34, the third insulating film 46, and the buffer insulating film 42 is constituted by, for example, a silicon oxide (SiO₂) film. That is, the semiconductor device 1F of the first embodiment has a silicon on insulator (SOI) structure in which the semiconductor portion 33 of silicon (Si) is provided on the first insulating film 32. In addition, the insulating layer 47 includes the semiconductor portion 33 and the field effect transistor Qf.

### <Contact Electrode>

As illustrated in FIGS. 41 and 43, the contact electrode 38a is provided on one side surface portion 33c₃ side of the two side surface portions 33c₃ and 33c₄ located in the longitudinal direction (Y direction) of the semiconductor portion 33 so as to overlap the semiconductor portion 33 in plan view. The contact electrode 38a includes a head portion 38a₁ protruding upward from the second insulating film 34 included in the insulating layer 47 and covered with the buffer insulating film 42 and the third insulating film 46 included in the insulating layer 47, and a leg portion 38a₂ integrated with the head portion 38a₁ and provided in the dug portion 35a between the second insulating film 34 and the semiconductor portion 33.

As illustrated in FIG. 41, the contact electrode 38b is provided on the other side surface portion 33c₄ side of the two side surface portions 33c₃ and 33c₄ located in the longitudinal direction (Y direction) of the semiconductor portion 33 so as to overlap the semiconductor portion 33 in plan view. The contact electrode 38b includes a head portion 38b₁ protruding upward from the second insulating film 34 included in the insulating layer 47 and covered with the buffer insulating film 42 and the third insulating film 46 included in the insulating layer 47, and a leg portion 38b₂ integrated with the head portion 38b₁ and provided in the dug portion 35b between the second insulating film 34 and the semiconductor portion 33.

### <Field Effect Transistor>

The field effect transistor Qf is not limited thereto, but is configured to have, for example, an n-channel conductivity type. Then, the field effect transistor Qf includes a MOSFET using a silicon oxide (SiO₂) film as a gate insulating film. The field effect transistor Of may be of a p-channel conductivity type. In addition, a MISFET may be used in which a gate insulating film is a silicon nitride film or a laminated film (composite film) such as a silicon nitride (Si₃N₄) film and a silicon oxide film.

As illustrated in FIGS. 41 to 43, the field effect transistor Qf includes the channel formation portion 45 provided in the semiconductor portion 33, and a gate electrode 37 provided over the upper surface portion 33a and the two side surface portions 33c₃ and 33c₄ of the semiconductor portion 33 with a gate insulating film 36 interposed in the channel formation portion 45 of the semiconductor portion 33 in the lateral direction (X direction) of the semiconductor portion 33.

Furthermore, the field effect transistor Of further includes a pair of main electrode regions 44a and 44b provided outside the semiconductor portion 33 to be separated from each other with the channel formation portion 45 interposed therebetween in the channel length direction (gate length direction) of the channel formation portion 45. In other words, the field effect transistor Of includes a pair of main electrode regions 44a and 44b provided in the semiconductor portion 33 on both sides in the gate length direction of the gate electrode 37. The pair of main electrode regions 44a and 44b functions as a source region and a drain region.

Here, for convenience of description, one main electrode region 44a of the pair of main electrode regions 44a and 44b may be referred to as a source region 44a, and the other main electrode region 44b may be referred to as a drain region 44b.

Furthermore, the distance between the pair of main electrode regions 44a and 44b is the channel length (L) of the channel formation portion 45 (the gate length (Lg) of the gate electrode 7), and the direction of the channel length is referred to as a channel length direction (gate length direction). Then, the direction of the channel width (W) (gate width (Wg)) of the channel formation portion 45 is referred to as a channel width direction (gate width direction). Then, in the sixth embodiment, as an example, since the pair of main electrode regions 44a and 44b is separated in the Y direction with the channel formation portion 45 interposed therebetween, the channel length direction is the Y direction.

In the field effect transistor Qf, a channel (inversion layer) electrically connecting a source region (one main electrode region) 44a and a drain region (the other main electrode region) 44b is formed (induced) in the channel formation portion 45 by a voltage applied to the gate electrode 37, and a current (drain current) flows from the drain region 44b side to the source region 45a side through the channel formation portion 45.

### <Gate Electrode>

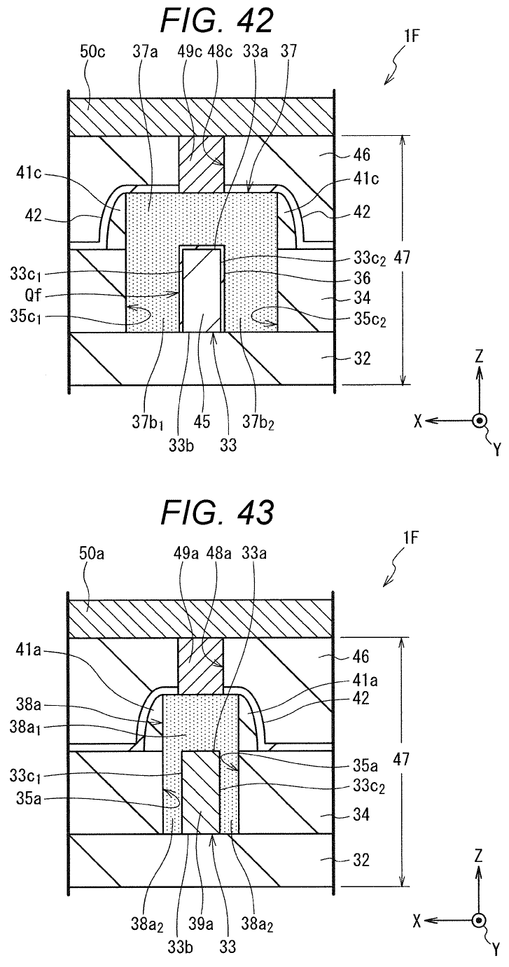

As illustrated in FIGS. 41 and 42, the gate electrode 37 includes, but is not limited to, for example, a head portion (first portion) 37a provided on the upper surface portion 33a side of the semiconductor portion 33 with the gate insulating film 36 interposed therebetween, and two leg portions (second portions) 37b₁ and 37b₂ integrated with the head portion 37a and provided outside each of the two side surface portions 33c₁ and 33c₂ located on opposite sides in the lateral direction (X direction) of the semiconductor portion 33 with the gate insulating film 36 interposed therebetween. That is, the gate electrode 37 is provided over the upper surface portion 33a and the two side surface portions 33c₁ and 33c₂ of the semiconductor portion 33, and has a C-shaped cross-sectional shape orthogonal to the longitudinal direction (Y direction) of the semiconductor portion 33. The gate electrode 37 is constituted by, for example, a polycrystalline silicon film into which an impurity for reducing the resistance value is introduced.

Here, the semiconductor portion 33 is preferably sandwiched between the leg portions of the gate electrode 37 from both sides in the lateral direction (X direction) of the semiconductor portion 33. Therefore, the leg portion of the gate electrode 37 is usually “n+1” when the number of semiconductor portions 33 is “n”. In the sixth embodiment, since the gate electrode 37 is provided in one semiconductor portion 33, the gate electrode 37 has two leg portions 37b₁ and 37b₂.

As illustrated in FIGS. 41 and 42, the head portion 37a of the gate electrode 37 protrudes upward from the second insulating film 34 included in the insulating layer 47, and is further covered with the buffer insulating film 42 and the third insulating film 46 included in the insulating layer 47. Then, the two leg portions 37b₁ and 37b₂ of the gate electrode 37 are separately provided in the dug portions 35c₁ and 35c₂ between the second insulating film 34 and the semiconductor portion 33.

### <Gate Insulating Film>

The gate insulating film 36 is provided between the semiconductor portion 33 and the gate electrode 37 over the upper surface portion 33a and the two side surface portions 33c₁ and 33c₂ of the semiconductor portion 33. The gate insulating film 36 is constituted by, for example, a silicon oxide film.

### <Sidewall Spacer>

As illustrated in FIGS. 40 to 43, the sidewall spacer 41a is provided on the sidewall of the head portion 38a₁ of the contact electrode 38a so as to surround the periphery of the head portion 38a₁. Furthermore, the sidewall spacer 41b is provided on the sidewall of the head portion 38b₁ of the contact electrode 38b so as to surround the periphery of the head portion 38b₁. Then, the sidewall spacer 41c is provided on the sidewall of the head portion 37a of the gate electrode 37 so as to surround the periphery of the head portion 37a.

The sidewall spacer 41a extends on the second insulating film 34 of the insulating layer 47 and on the semiconductor portion 33, and is formed so as to be aligned with the head portion 38a₁ of the contact electrode 38a (see FIGS. 40, 41, and 43).

The sidewall spacer 41b extends on the second insulating film 34 of the insulating layer 47 and on the semiconductor portion 33, and is formed so as to be aligned with the head portion 38b₁ of the contact electrode 38b (see FIGS. 40 and 41).

The sidewall spacer 41c extends on the second insulating film 34 of the insulating layer 47 and on the semiconductor portion 33, and is formed so as to be aligned with the head portion 37a of the gate electrode 37 (see FIGS. 40, 41, and 42).

Each of the sidewall spacers 41a, 41b, and 41c can be formed, for example, by forming an insulating film (spacer material) on the second insulating film 34 by a CVD method so as to cover the head portions 37a, 38a₁, and 38b₁ of the gate electrode 37 and the contact electrodes 38a and 38b, and then applying anisotropic dry etching such as reactive ion etching (RIE) to the insulating film. That is, the sidewall spacers 41a, 41b, and 41c of the sixth embodiment are formed in the same layer.

Here, “the sidewall spacers 41a, 41b, and 41c are formed in the same layer” means “the sidewall spacers 41a, 41b, and 41c are formed by the same step and the same material”.

The sidewall spacers 41a, 41b, and 41c are constituted by a material having a selectivity ratio with respect to the second insulating film 34, the semiconductor layer 33, the gate electrode 37, and the contact electrodes 38a and 38b. In the sixth embodiment, the sidewall spacers 41a, 41b, and 41c are constituted by, for example, a silicon nitride film having selectivity for each of the silicon oxide film of the insulating layer 47, the monocrystalline silicon of the semiconductor portion 3, and the polycrystalline silicon of the gate electrode 37 and the contact electrodes 38a and 38b. The sidewall spacers 41a, 41b, and 41c secure distances between the gate electrode 7 and the contact electrodes 38a and 38b, and n-type semiconductor regions 43a and 43b (see FIG. 41) included in a pair of main electrode regions 44a and 44b described later, respectively.

### <Buffer Insulating Film>

As illustrated in FIGS. 41 to 43, the buffer insulating film 42 included in the insulating layer 47 covers the head portion 37a of the gate electrode 37 and the head portion 38a₁ and 38b₁ of each of the two contact electrodes 38a and 38b, and covers each of the sidewall spacers 41a, 41b, and 41c. The buffer insulating film 42 is used as a buffer film at the time of ion implantation of impurities in a step of forming n-type semiconductor regions 43a and 43b to be described later, and is constituted by, for example, a silicon oxide film.

### <Main Electrode Region>

As illustrated in FIG. 41, one main electrode region 44a of the pair of main electrode regions 44a and 44b is provided on one side surface portion 33c₃ side of the two side surface portions 33c₃ and 33c₄ located in the longitudinal direction (Y direction) of the semiconductor portion 33. Then, the one main electrode region 44a includes an n-type semiconductor region 39a, an n-type semiconductor region 40a having an impurity concentration lower than that of the n-type semiconductor region 39a, and an n-type semiconductor region 43a having an impurity concentration higher than that of the n-type semiconductor region 39a.

As illustrated in FIGS. 41 and 43, the n-type semiconductor region 39a has a three-dimensional structure extending from the upper surface portion 33a to the lower surface portion 33b along the three side surface portions 33c₁, 33c₂, and 33c₃ of the semiconductor portion 33. The n-type semiconductor region 39a can be formed by diffusing impurities from the contact electrode 38a into the semiconductor portion 33.

As illustrated in FIG. 41, the n-type semiconductor region 40a is provided in contact with the n-type semiconductor region 39a in the semiconductor portion 33 between the contact electrode 38a and the gate electrode 37 in plan view. Then, the n-type semiconductor region 40a is formed so as to be aligned with the head portion 37a of the gate electrode 37, and extends from the upper surface portion 33a to the lower surface portion 33b of the semiconductor portion 33. The n-type semiconductor region 40a functions as an extension region.

As illustrated in FIG. 41, the n-type semiconductor region 43a is provided on the upper surface portion 33a side of the semiconductor portion 33 and in a surface layer portion of the n-type semiconductor region 40a so as to be in contact with the n-type semiconductor region 40a and the n-type semiconductor region 39a. Then, the n-type semiconductor region 43a is formed so as to be aligned with the sidewall spacer 41a of the sidewall of the head portion 38a₁ of the contact electrode 38a and the sidewall spacer 41c of the sidewall of the head portion 37a of the gate electrode 37.

In the sixth embodiment, each of the n-type semiconductor region 39a and the n-type semiconductor region 40a is configured to have a depth in contact with the first insulating film 32 included in the insulating layer 47, for example, although not limited thereto.

As illustrated in FIG. 41, the other main electrode region 44b of the pair of main electrode regions 44a and 44b is provided on the other side surface portion 33c₄ side of the two side surface portions 33c₃ and 33c₄ located in the longitudinal direction (Y direction) of the semiconductor portion 33. Then, the other main electrode region 44b includes an n-type semiconductor region 39b, an n-type semiconductor region 40b having an impurity concentration lower than that of the n-type semiconductor region 39b, and an n-type semiconductor region 43b having an impurity concentration higher than that of the n-type semiconductor region 39b.

Although not illustrated in detail, the n-type semiconductor region 39b has a three-dimensional structure extending from the upper surface portion 33a to the lower surface portion 33b along the three side surface portions 33c₁, 33c₂, and 33c₄ of the semiconductor portion 33 similarly to the n-type semiconductor region 39a. The n-type semiconductor region 39b can be formed by diffusing impurities from the contact electrode 38b into the semiconductor portion 33.

As illustrated in FIG. 41, the n-type semiconductor region 40b is provided in contact with the n-type semiconductor region 39b in the semiconductor portion 33 between the contact electrode 38b and the gate electrode 37 in plan view. Then, the n-type semiconductor region 40b is formed so as to be aligned with the head portion 37a of the gate electrode 37, and extends from the upper surface portion 33a to the lower surface portion 33b of the semiconductor portion 33. The n-type semiconductor region 40b functions as an extension region.

As illustrated in FIG. 41, the n-type semiconductor region 43b is provided on the upper surface portion 33a of the semiconductor portion 33 and in a surface layer portion of the n-type semiconductor region 40b so as to be in contact with the n-type semiconductor region 40b and the n-type semiconductor region 39b. Then, the n-type semiconductor region 43b is formed so as to be aligned with the sidewall spacer 41b of the sidewall of the head portion 38b₁ of the contact electrode 38b and the sidewall spacer 41c of the sidewall of the head portion 37a of the gate electrode 37.

In the sixth embodiment, each of the n-type semiconductor region 39b and the n-type semiconductor region 40b is configured to have a depth in contact with the first insulating film 32 included in the semiconductor layer 47, for example, although not limited thereto.

As illustrated in FIGS. 40 to 43, the field effect transistor Qf of the sixth embodiment is configured as a so-called fin type in which the gate electrode 37 is provided in the island-shaped semiconductor portion 33 as a fin portion with the gate insulating film 36 interposed therebetween, similarly to the field effect transistor Qa described above.

In the fin-type field effect transistor Qf, the length between the pair of main electrode regions 44a and 44b is the channel length L (≈ gate length Lg), and in the region where the gate electrode 37 and the semiconductor portion 33 three-dimensionally overlap, a value obtained by multiplying the length (the length around the semiconductor portion 3) including the width W₂ in the lateral direction on the upper surface portion 33a side of the semiconductor portion 33 and the heights of the side surface portions 3b₁ and 3b₂ of the semiconductor portion 33 by the number of semiconductor portions 33 is the channel width W (≈ gate width).

Therefore, in the fin-type field effect transistor Qf, since the channel width W is increased by increasing the width W₁ of the semiconductor portion 33 in the lateral direction (Y direction) and increasing the height of the semiconductor portion 33 in the thickness direction (Z direction), the effective channel area (channel length L×channel width W) can be increased. Then, the fin-type field effect transistor Qf can increase the channel area (channel length L×channel width W) by increasing the number of semiconductor portions 33. In the sixth embodiment, a case where the field effect transistor Qf is provided in one semiconductor portion 33 has been described, but there may be a plurality of semiconductor portions 3.

Examples of the field effect transistor Qf include an enhancement type (normally-off type) in which a drain current flows by applying a gate voltage equal to or higher than a threshold voltage to the gate electrode 37, and a depression type (normally-off type) in which a drain current flows without applying a voltage to the gate electrode 37. In the sixth embodiment, although not limited thereto, for example, an enhancement type is used. In the case of the enhancement type, in the field effect transistor Qf, a channel (inversion layer) electrically connecting the pair of main electrode regions 44a and 44b is formed (induced) in the channel formation portion 45 by a voltage applied to the gate electrode 37, and a current (drain current) flows from the drain region side (for example, the main electrode region 44b side) to the source region side (for example, the main electrode region 44a side) through the channel of the channel formation portion 45.

### <Contact Electrode and Wiring>

As illustrated in FIGS. 41 and 42, the gate electrode 37 is electrically connected to the wiring 50c provided in the wiring layer on the insulating layer 47 via the contact electrode 49c provided in the dug portion 48c of the insulating layer 47 (specifically, the third insulating film 46). In addition, as illustrated in FIGS. 41 and 43, the contact electrode 38a is electrically connected to the wiring 50a provided in the wiring layer on the insulating layer 47 via the contact electrode 49a provided in the dug portion 48a of the insulating layer 47 (specifically, the third insulating film 46). In addition, as illustrated in FIG. 41, the contact electrode 38b is electrically connected to the wiring 50b provided in the wiring layer on the insulating layer 47 via the contact electrode 49b provided in the dug portion 48b of the insulating layer 47 (specifically, the third insulating film 46).

As illustrated in FIG. 41, the contact electrode 49a is provided to overlap with the contact electrode 38a in plan view, and is electrically and mechanically connected to the contact electrode 38a. Similarly, the contact electrode 49b is provided to overlap the contact electrode 38b in plan view, and is electrically and mechanically connected to the contact electrode 38b. In addition, the contact electrode 49c is provided to overlap the gate electrode 37 in plan view, and is electrically and mechanically connected to the gate electrode 37.

As a material of the contact electrodes 49a, 49b, and 49c, for example, tungsten (W) of a high melting point metal can be used. As the material of the wirings 50a, 50b, and 50c, for example, a metal material such as aluminum (Al) or copper (Cu), an alloy material mainly containing Al or Cu, or the like can be used.

### <Connection Between Contact Electrode and Semiconductor Portion>

As illustrated in FIGS. 41 and 43, each of the contact electrodes 38a and 38b is connected to the upper surface portion 33a and the side surface portion of the semiconductor portion 33.

Specifically, as illustrated in FIGS. 41 and 43, in the contact electrode 38a, on one end portion side (side surface portion 33c₃ side) in the longitudinal direction of the semiconductor portion 33, the head portion 38a₁ is connected to the upper surface portion 33a of the semiconductor portion 33, and the leg portion 38a₂ is connected to the three side surface portions 33c₁, 33c₂, and 33c₃ of the semiconductor portion 33. Then, the contact electrode 38a is electrically and mechanically connected to one main electrode region 44a provided on one end portion side (side surface portion 33c₃ side) in the longitudinal direction of the semiconductor portion 33, of the pair of main electrode regions 44a and 44b.

Furthermore, although not illustrated in detail, similarly to the contact electrode 38a, also in the contact electrode 38b, on the other end portion side (side surface portion 33c₄ side) in the longitudinal direction of the semiconductor portion 33, the head portion 38b₁ is connected to the upper surface portion 33a of the semiconductor portion 33, and the leg portion 38b₂ is connected to the three side surface portions 33c₁, 33c₂, and 33c₄ of the semiconductor portion 33. Then, the contact electrode 38b is electrically and mechanically connected to the other main electrode region 44b provided on the other end portion side (side surface portion 33c₄ side) in the longitudinal direction of the semiconductor portion 33, of the pair of main electrode regions 44a and 44b.

### <Material of Contact Electrode>

Each of the contact electrodes 38a and 38b illustrated in FIGS. 40, 41, and 43 is constituted by a polycrystalline semiconductor material. In the sixth embodiment, although not limited thereto, each of the contact electrodes 38a and 38b is constituted by, for example, silicon (Si) as a semiconductor material, for example, a single crystal as crystallinity, for example, an n-type (intrinsic type) as a conductivity type. That is, each of the contact electrodes 38a and 38b is constituted by n-type polycrystalline silicon as a semiconductor material. Then, each of the contact electrodes 38a and 38b is formed in the same layer as the gate electrode 37.

Here, “each of the contact electrodes 38a and 38b is formed in the same layer as the gate electrode 37” means that “each of the contact electrodes 38a and 38b is formed by the same step and the same material as the gate electrode 37”. That is, each of the contact electrodes 38a and 38b is formed together with the gate electrode 37 in the step of patterning the gate material to form the gate electrode 37.

Note that, as described above, the semiconductor portion 33 is constituted by i-type monocrystalline silicon. Furthermore, as described above, the gate electrode 37 is constituted by polycrystalline silicon.

### <Thickness of Contact Electrode and Gate Electrode>

As illustrated in FIG. 41A, in the contact electrode 38a, the thickness Th₁ at the portion overlapping the semiconductor portion 33 in plan view (the head portion 38a₁) is substantially the same as the thickness Th₃ at the portion overlapping the semiconductor portion 33 of the gate electrode 37 in plan view (the head portion 37a). Furthermore, in the contact electrode 38b, the thickness Th₂ at the portion overlapping the semiconductor portion 33 in plan view (the head portion 38b₁) is substantially the same as the thickness Th₃ at the portion overlapping the semiconductor portion 33 of the gate electrode 37 in plan view (the head portion 37a). That is, the thicknesses Th₁, Th₂, and Th₃ of the contact electrodes 38a and 38b and the gate electrode 37 are substantially the same at respective portions (head portion 38a₁, head portion 38b₁, head portion 37a) overlapping the gate electrode 37 in plan view.

In this way, by forming the contact electrodes 38a and 38b in the same layer as the gate electrode 37, the thicknesses Th₁ and Th₂ at the respective portions (the head portions 38a₁ and 38b₁) where the contact electrodes 38a and 38b overlap the semiconductor portion 33 in a plan view and the thickness Th₃ at the portion (the head portion 37a) where the gate electrode 37 overlaps the semiconductor portion 33 in a plan view can be equalized.

### <Width of Contact Electrode+Sidewall Spacer>

As illustrated in FIG. 40, in the lateral direction (X direction) of the semiconductor portion 33, the width W₁a of the contact electrode 38a is wider than the width W₂ of the semiconductor portion 3. Then, the width W₅a including the head portion 38a₁ of the contact electrode 38a and the sidewall spacers 41a respectively provided on both sides of the head portion 38a₁ of the contact electrode 38a (width of head portion 38a₁ of contact electrode 38a+width of sidewall spacer 41a×2) is narrower than the width W₃ including the head portion 37a of the gate electrode 37 and the sidewall spacers 41c respectively provided on both sides of the gate electrode 37 (width of head portion 38a₁ of gate electrode 38a+width of sidewall spacer 41c×2).

Similarly, in the lateral direction (X direction) of the semiconductor portion 33, the width W₁b of the contact electrode 38b is also wider than the width W₂ of the semiconductor portion 3. Then, the width W₅b including the head portion 38b₁ of the contact electrode 38b and the sidewall spacers 41b respectively provided on both sides of the head portion 38b₁ of the contact electrode 38b (width of head portion 38a₁ of contact electrode 38a+width of sidewall spacer 41a×2) is also narrower than the width W₃ including the head portion 37a of the gate electrode 37 and the sidewall spacers 41c respectively provided on both sides of the gate electrode 37 (width of head portion 38a₁ of gate electrode 38a+width of sidewall spacer 41c×2).

### <Oxide>

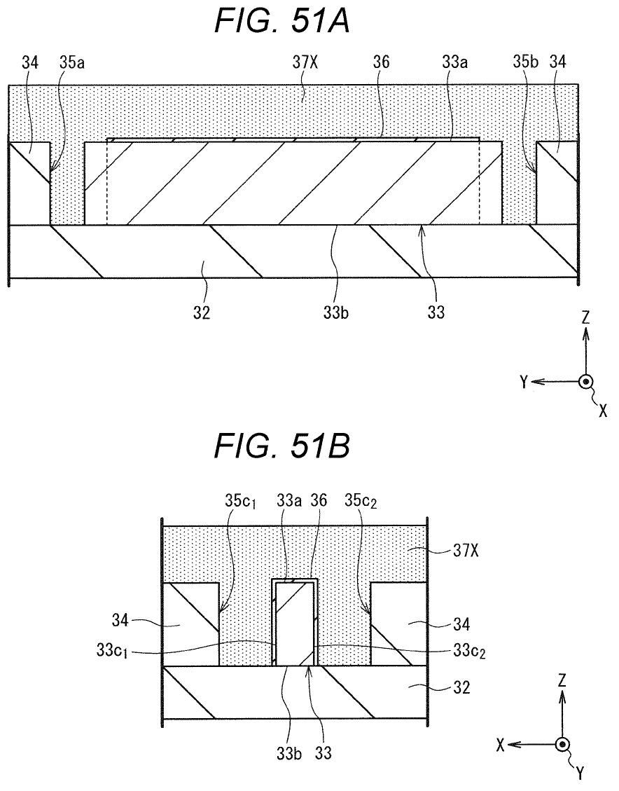

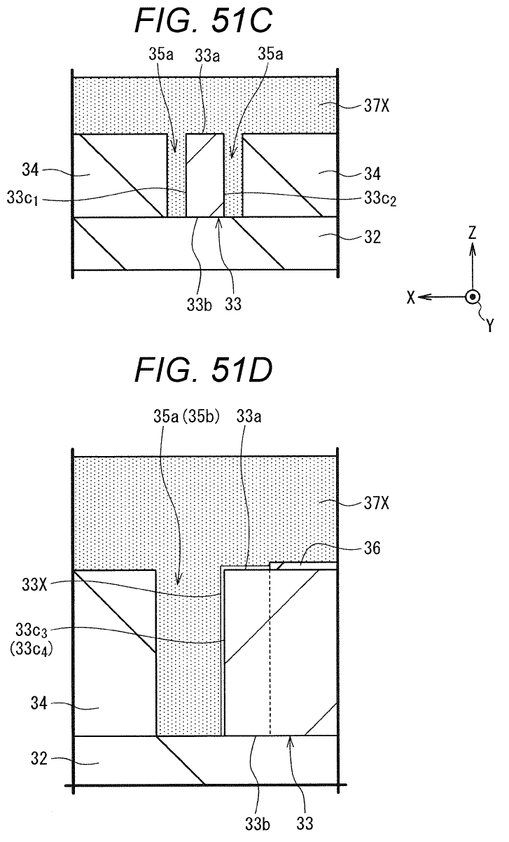

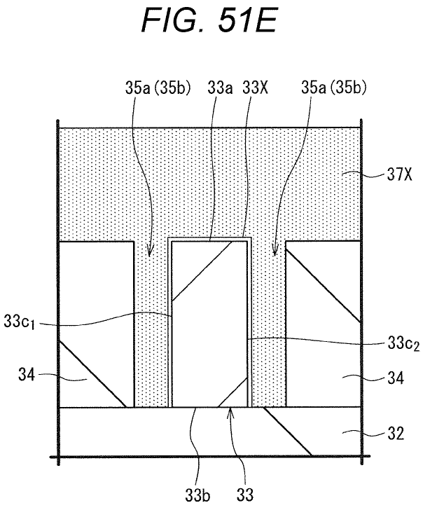

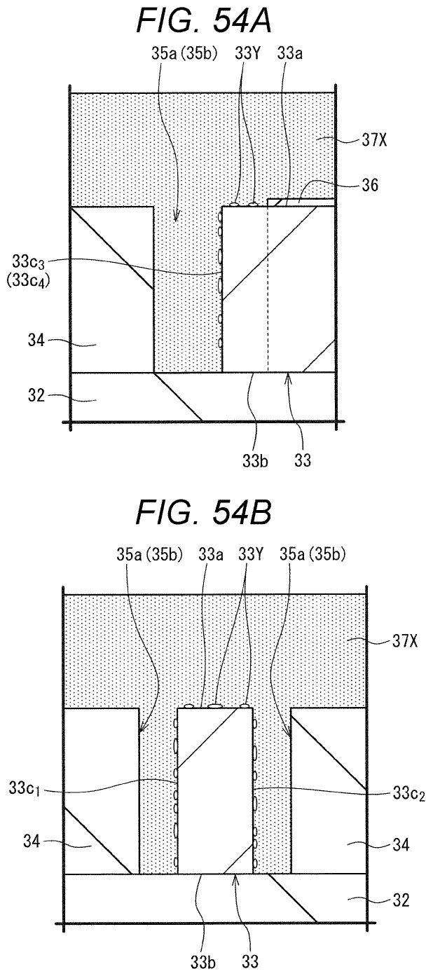

Here, although not illustrated in FIG. 43, a plurality of oxides 33Y as granular (spherical) insulators illustrated in FIGS. 54A and 54B is interspersed at the interface portion between the semiconductor portion 33 and the contact electrodes 38a and 38b. Although the oxide 33Y will be described in detail later, the natural oxide film 33X illustrated in FIGS. 51D and 51E is changed by fluidization of heat treatment. The natural oxide film 33X constituted by silicon oxide (SiO₂) containing a large amount of impurities has a low melting point, and is fluidized by heat treatment. As described above, by changing the natural oxide film 33X to the granular (spherical) oxide 33Y, the contact characteristics between the semiconductor portion 33 and the contact electrodes 38a and 38b can be further improved.

### <Other Configurations>

As illustrated in FIG. 41, the gate insulating film 36 is provided between the gate electrode 37 side of the contact electrode 38a and the semiconductor portion 33. Furthermore, the gate insulating film 36 is also provided between the gate electrode 37 side of the contact electrode 38b and the semiconductor portion 33. Although not illustrated in detail, the gate insulating film 36 between the contact electrodes 38a and 38b and the semiconductor portion 33 extends over the upper surface portion 33a and the two side surface portions 33c₁ and 33c₂ of the semiconductor portion 33, similarly to the gate insulating film 36 between the gate electrode 37 and the semiconductor portion 33 illustrated in FIG. 42.

Then, the gate insulating film 36 is provided on the two side surface portions 33c₁ and 33c₂ of the semiconductor portion 33 between the contact electrodes 38a and 38b and the gate electrode 37, but is not provided on the upper surface portion 33a, although it is not limited thereto.

### <<Method for Manufacturing Semiconductor Device>>

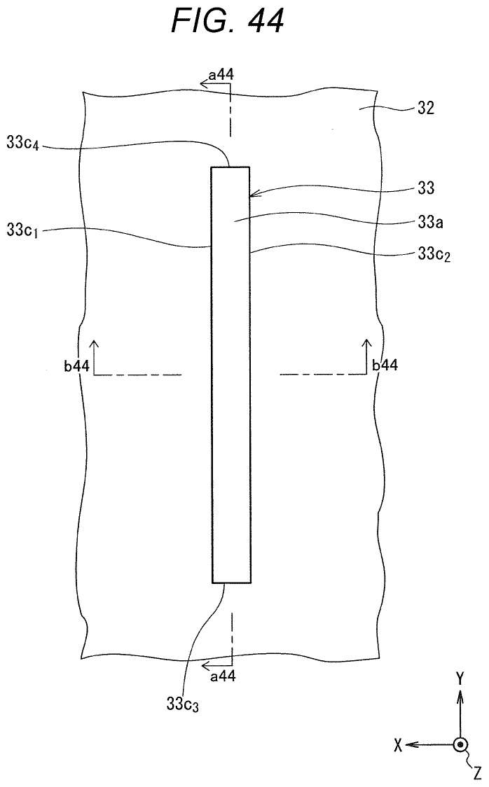

Next, a method for manufacturing the semiconductor device 1F will be described with reference to FIGS. 44 to 68.

In the sixth embodiment, the formation of the field effect transistor Of and the formation of the contact electrodes 38a and 38b included in the method for manufacturing the semiconductor device will be specifically described.

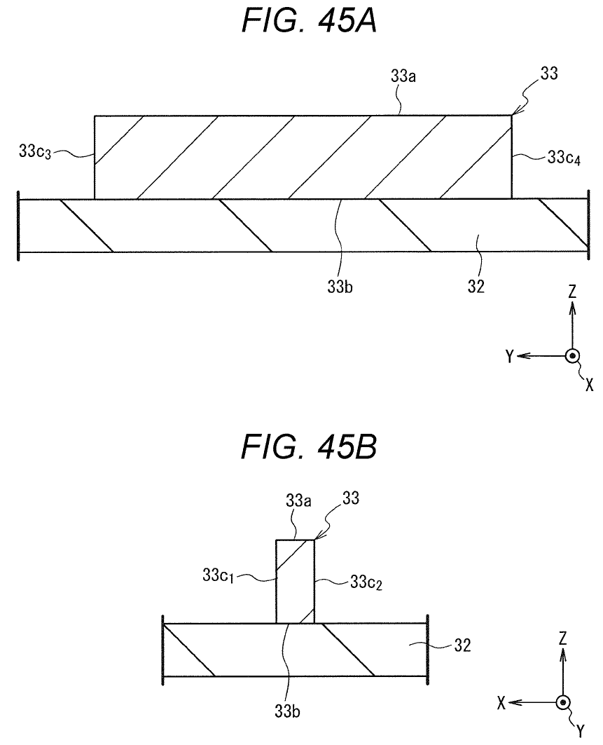

First, as illustrated in FIG. 44 (schematic plan view), FIG. 45A (schematic longitudinal cross-sectional view taken along a cutting line a44-a44 in FIG. 44), and FIG. 45B (schematic longitudinal cross-sectional view taken along a cutting line b44-b44 in FIG. 44), the island-shaped semiconductor portion 33 is formed on the first insulating film 32. The semiconductor portion 33 is formed in, for example, a rectangular parallelepiped shape having an upper surface portion 33a, a lower surface portion (bottom surface portion) 33b, and four side surface portions 33c₁, 33c₂, 33c₃, and 33c₄. The semiconductor portion 33 can be formed, for example, by patterning a semiconductor layer provided on the first insulating film 32 into a predetermined shape using a known photolithography technique, etching technique, or the like. Although not limited thereto, the semiconductor portion 33 is constituted by, for example, silicon as a semiconductor material, for example, a single crystal as crystallinity, and for example, i-type (intrinsic type) as a conductivity type. The first insulating film 32 supports the semiconductor portion 33 on the lower surface portion 33b side of the semiconductor portion 33. As the first insulating film 32, for example, a silicon oxide film formed by a chemical vapor deposition (CVD) method is used.

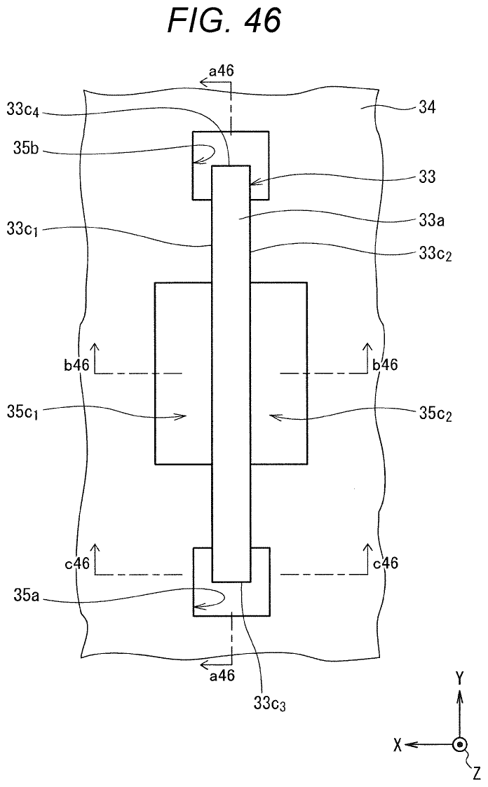

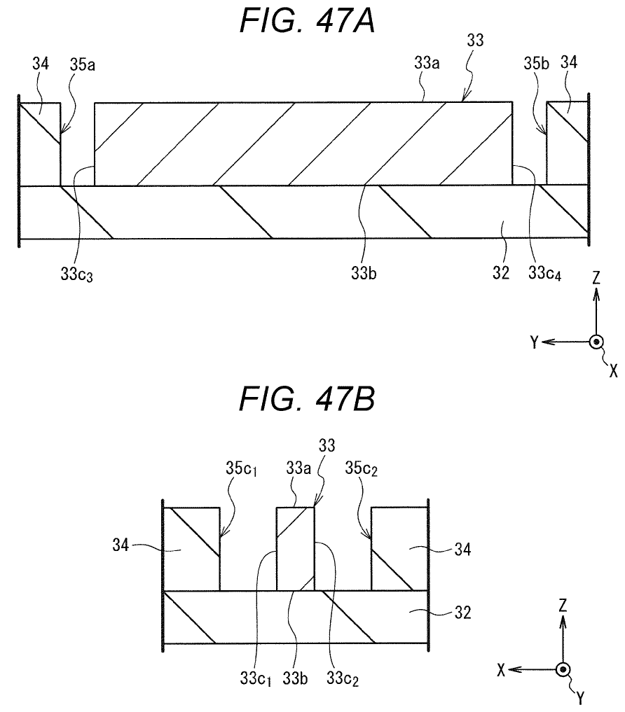

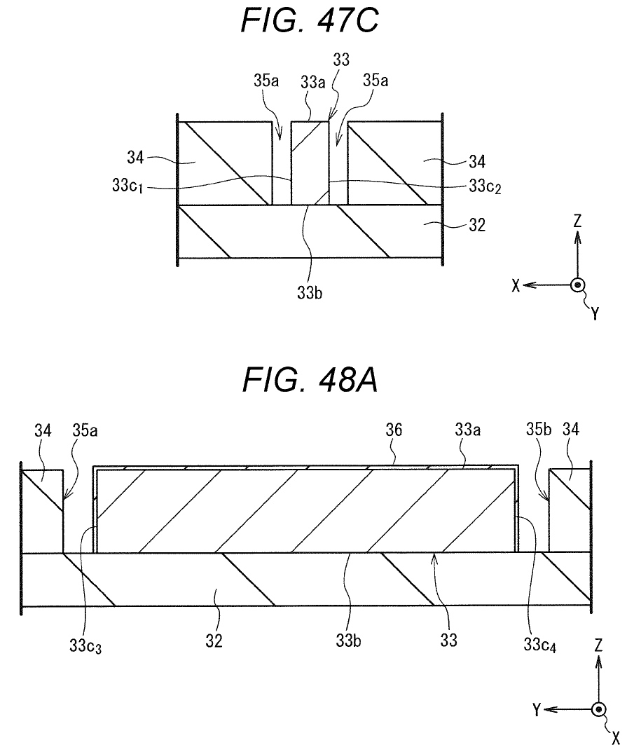

Next, as illustrated in FIG. 46 (schematic plan view), FIG. 47A ((schematic longitudinal cross-sectional view illustrating a longitudinal cross-sectional structure taken along a cutting line a46-a46 in FIG. 46), FIG. 47B (schematic longitudinal cross-sectional view illustrating a longitudinal cross-sectional structure taken along a cutting line b46-b46 in FIG. 46), and FIG. 47C (schematic longitudinal cross-sectional view illustrating a longitudinal cross-sectional structure taken along a cutting line c46-c46 in FIG. 46), a second insulating film 34 and dug portions 35a, 35b, 35c₁, and 35c₂ are formed in the second insulating film 34. The second insulating film 34 is formed outside the semiconductor portion 33 so as to surround the semiconductor portion 33. The second insulating film 34 can be formed by forming, for example, a silicon oxide film on the entire surface of the first insulating film 32 including the semiconductor portion 33 using a known film formation method (for example, a CVD method), and then selectively removing the surface layer portion side of the silicon oxide film using, for example, a CMP method so that the upper surface portion 33a of the semiconductor portion 33 is exposed to reduce the film thickness.

Each of the dug portions 35a, 35b, 35c₁, and 35c₂ can be formed by selectively etching the second insulating film 34 using a known photolithography technique and dry etching technique.

Specifically, the dug portion 35a is formed such that three side surface portions 33c₁, 33c₂, and 33c₃ of the semiconductor portion 33 are exposed on one side surface portion 33c₃ side of the two side surface portions 33c₃ and 33c₄ located on opposite sides in the longitudinal direction (Y direction) of the semiconductor portion 33.

In addition, the dug portion 35b is formed such that the three side surface portions 33c₁, 33c₂, and 33c₄ of the semiconductor portion 33 are exposed on the side of the other side surface portion 33c₄ of the two side surface portions 33c₃ and 33c₄ located on opposite sides in the longitudinal direction (Y direction) of the semiconductor portion 33.

In addition, the dug portions 35c₁ and 35c₂ are formed such that the side surface portions 33c₁ and 33c₂ are exposed to the outside each of the two side surface portions 33c₁ and 33c₂ located on opposite sides at the central portion in the longitudinal direction (Y direction) of the semiconductor portion 33.

Etching of the second insulating film 34 is performed under a condition that an etching ratio with respect to the semiconductor portion 33 can be obtained. The dug portions 35a and 35b are preferably formed such that the depth in the same direction as the thickness direction (Z direction) of the semiconductor portion 33 is equivalent to or higher than the height in the thickness direction of the semiconductor portion 33. In other words, the dug portions 35a and 35b are preferably formed at a depth reaching the first insulating film 32.

In this step, the three side surface portions 33c₁, 33c₂/and 33c₃ of the semiconductor portion 33 are exposed in the dug portion 35a, the three side surface portions 33c₁, 33c₂, and 33c₄ of the semiconductor portion 33 are exposed in the dug portion 35b, the side surface portion 33c₁ of the semiconductor portion 33 is exposed in the dug portion 35c₁, and the side surface portion 33c₂ of the semiconductor portion 33 is exposed in the dug portion 35c₂. The upper surface portion 33a of the semiconductor portion 33 is exposed from one end portion side to the other end portion side in the longitudinal direction (Y direction) of the semiconductor portion 33.

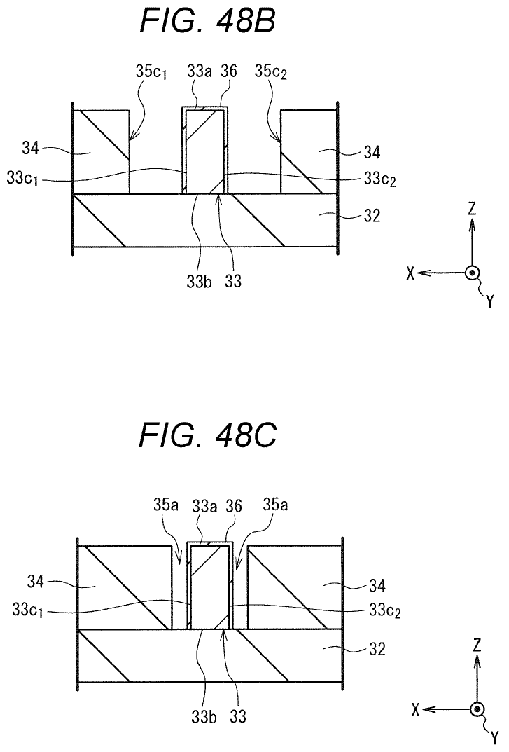

Next, as illustrated in FIG. 48A (schematic longitudinal cross-sectional view illustrating a longitudinal cross-sectional structure at the same position as a cutting line a46-a46 in FIG. 46), FIG. 48B (schematic longitudinal cross-sectional view illustrating a longitudinal cross-sectional structure at the same position as a cutting line b46-b46 in FIG. 46), and FIG. 48C (schematic longitudinal cross-sectional view illustrating a longitudinal cross-sectional structure at the same position as a cutting line c46-c46 in FIG. 46), a gate insulating film 36 is formed on the semiconductor portion 33. The gate insulating film 36 is formed over the upper surface portion 33a and the two side surface portions 33c₁ and 33c₂ of the semiconductor portion 33 in the lateral direction (X direction) of the semiconductor portion 33. The gate insulating film 36 can be formed by a thermal oxidation method or a deposition method. In the sixth embodiment, a silicon oxide film as the gate insulating film 36 is formed by a thermal oxidation method. As a result, the gate insulating film 36 can be selectively formed in the portion of the semiconductor portion 33 exposed from the second insulating film 34.

Note that, in this step, as illustrated in FIG. 48A, the gate insulating film 36 is also formed on each of the two side surface portions 33c₃ and 33c₄ in the longitudinal direction (Y direction) of the semiconductor portion 33.

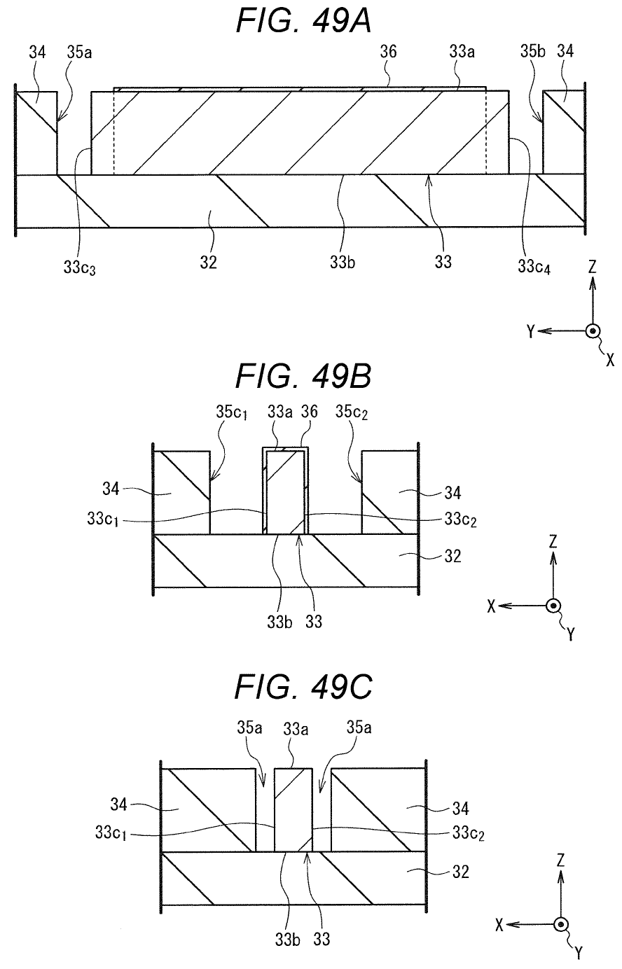

Next, as illustrated in FIG. 49A (schematic longitudinal cross-sectional view illustrating a longitudinal cross-sectional structure at the same position as a cutting line a46-a46 in FIG. 46), FIG. 49B (schematic longitudinal cross-sectional view illustrating a longitudinal cross-sectional structure at the same position as a cutting line b46-b46 in FIG. 46), and FIG. 49C (schematic longitudinal cross-sectional view illustrating a longitudinal cross-sectional structure at the same position as a cutting line c46-c46 in FIG. 46), the gate insulating film 36 is patterned to selectively remove the gate insulating film 36 on one end portion side (dug portion 35a side) and the other end portion side (dug portion 35b side) in the longitudinal direction (Y direction) of the semiconductor portion 33, selectively expose the upper surface portion 33a and the three side surface portions 33c₁, 33c₂, and 33c₃ on one end portion side in the longitudinal direction of the semiconductor portion 33, and selectively expose the upper surface portion 33a and the three side surface portions 33c₁, 33c₂, and 33c₄ on the other end portion side in the longitudinal direction of the semiconductor portion 33. Patterning of the gate insulating film 36 can be performed using a known photolithography technique, dry etching technique, or the like.

In this step, the gate insulating film 36 has a strip shape in which an end portion in the same direction as the longitudinal direction of the semiconductor portion 33 is located inside an end portion in the longitudinal direction of the semiconductor portion 33 in plan view at the central portion in the longitudinal direction (Y direction) of the semiconductor portion 33 and extends over the upper surface portion 33a and the two side surface portions 33c₁ and 33c₂ of the semiconductor portion 33.

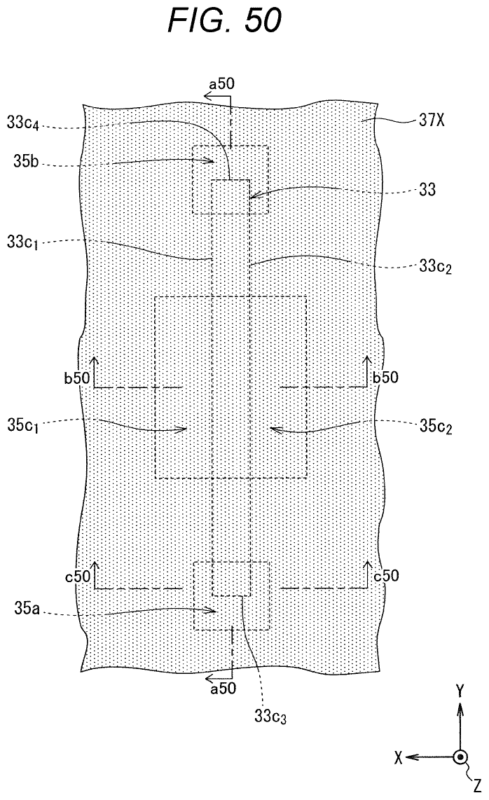

Next, as illustrated in FIG. 50 (schematic plan view), FIG. 51A (schematic longitudinal cross-sectional view taken along a cutting line a50-a50 in FIG. 50), FIG. 51B (schematic longitudinal cross-sectional view illustrating a longitudinal cross-sectional structure taken along a cutting line b50-b50 in FIG. 50), and FIG. 51C (schematic longitudinal cross-sectional view illustrating a longitudinal cross-sectional structure taken along a cutting line c50-c50 in FIG. 50), for example, a polycrystalline silicon film (non-doped polysilicon film) 37X into which an impurity for reducing a resistance value is not introduced is formed as an electrode formation material. The polycrystalline silicon film 37X is formed on the entire surface including the semiconductor portion 33 and the second insulating film 34 by, for example, the CVD method so as to fill the inside of each of the four dug portions 35a, 35b, 35c₁, and 35c₂.

Here, due to movement between steps after the gate insulating film 36 of the semiconductor portion 33 is selectively removed, and the like, as illustrated in FIG. 51D (schematic cross-sectional view in which a part (one end side of the semiconductor portion) of FIG. 51A is enlarged) and FIG. 51E (schematic cross-sectional view in which a part of FIG. 51C is enlarged), an extremely thin natural oxide film 33X is formed in a gate insulating film removal region (upper surface portion 33a and side surface portions 33c₁ to 33c₄) of the semiconductor portion 33. Therefore, as illustrated in FIGS. 51D and 51E, in the gate insulating film removal region on one end portion side in the longitudinal direction (Y direction) of the semiconductor portion 33, an extremely thin natural oxide film 33X having a film thickness of, for example, about 2 nm remains at the interface portion between the polycrystalline silicon film 37X and the upper surface portion 33a and the three side surface portions 33c₁, 33c₂, and 33c₃ on one end portion side in the longitudinal direction of the semiconductor portion 33.

Furthermore, in the gate insulating film removal region on the other end portion side in the longitudinal direction (Y direction) of the semiconductor portion 33, the natural oxide film 33X remains at the interface portion between the polycrystalline silicon film 37X and the upper surface portion 33a and the three side surface portions 33c₁, 33c₂, and 33c₄ on the other end portion side in the longitudinal direction of the semiconductor portion 33.

These natural oxide films 33X spread in a planar shape (film shape) over the upper surface portion 33a of the semiconductor portion 33 and the three side surface portions 33c₁, 33c₂, and 33c₃ (or 33c₄).

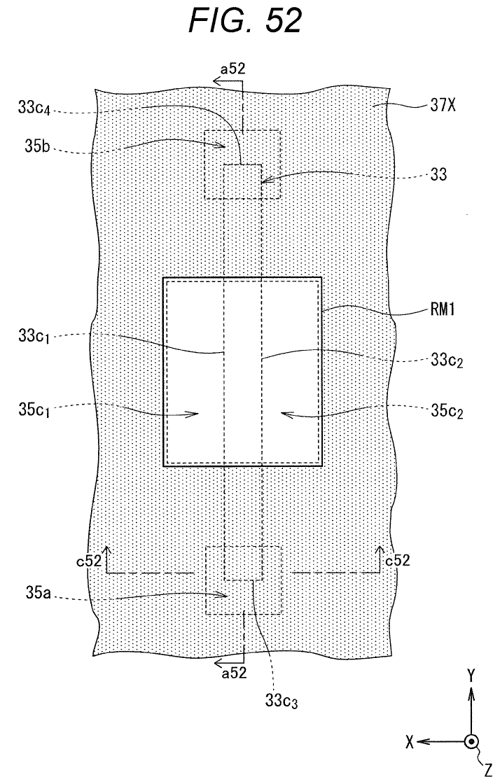

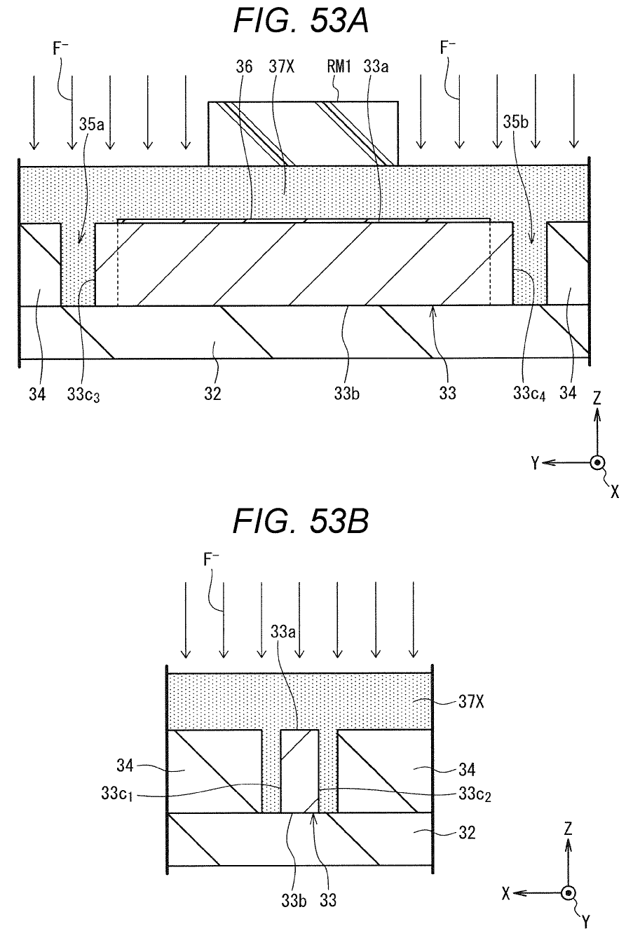

Next, as illustrated in FIG. 52 (schematic plan view), FIG. 53A (schematic longitudinal cross-sectional view taken along a cutting line a52-a52 in FIG. 52), and FIG. 53B (schematic longitudinal cross-sectional view illustrating a longitudinal cross-sectional structure taken along a cutting line c52-c52 in FIG. 52), a mask RM1 as an impurity introduction mask selectively covering a gate electrode formation region of the polycrystalline silicon film 37X is formed. Then, as illustrated in FIGS. 53A and 53B, the mask RM1 is used as an impurity introduction mask, and for example, fluorine ions (F⁻) are implanted as impurities into the polycrystalline silicon film 37X outside the mask RM1. The mask RM1 can be formed by a known photolithography technique.

This implantation of fluorine ions is to facilitate granulation (spheroidization) of the natural oxide film 33X described above by heat treatment. This implantation of fluorine ions is performed, for example, under conditions where the dose amount is about 8×10¹⁵/cm² and the acceleration energy is about 15 keV.

Next, after the mask RM1 is removed, heat treatment is performed to activate fluorine ions (F⁻) implanted in the polycrystalline silicon film 37X.

In this step, fluorine ions (F⁻) diffuse into the polycrystalline silicon film 37X, and fluorine ions (F⁻) also diffuse into the natural oxide film 33X illustrated in FIGS. 51D and 51E. Then, the natural oxide film 33X containing fluorine ions (F⁻) is fluidized by heat treatment, and as illustrated in FIGS. 54A and 54B, it is changed to a granular (spherical) oxide 33Y at an interface portion between the semiconductor portion 33 (the upper surface portion 33a and the side surface portions 33c₁, 33c₂, 33c₃, and 33c₄) and the polycrystalline silicon film 37X.

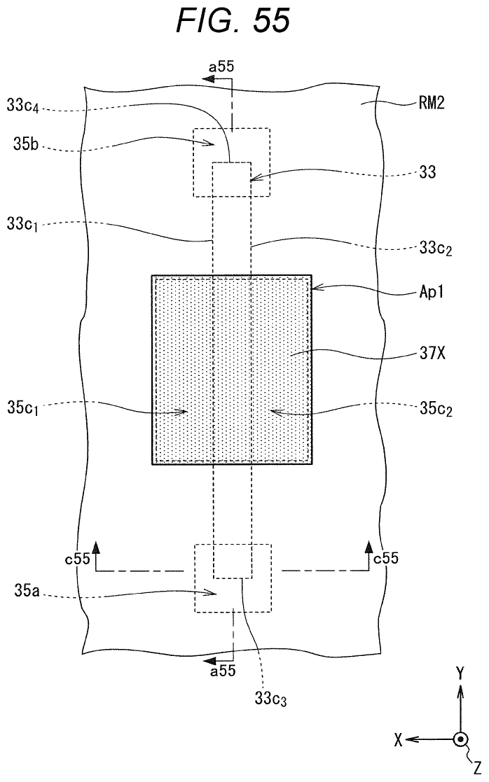

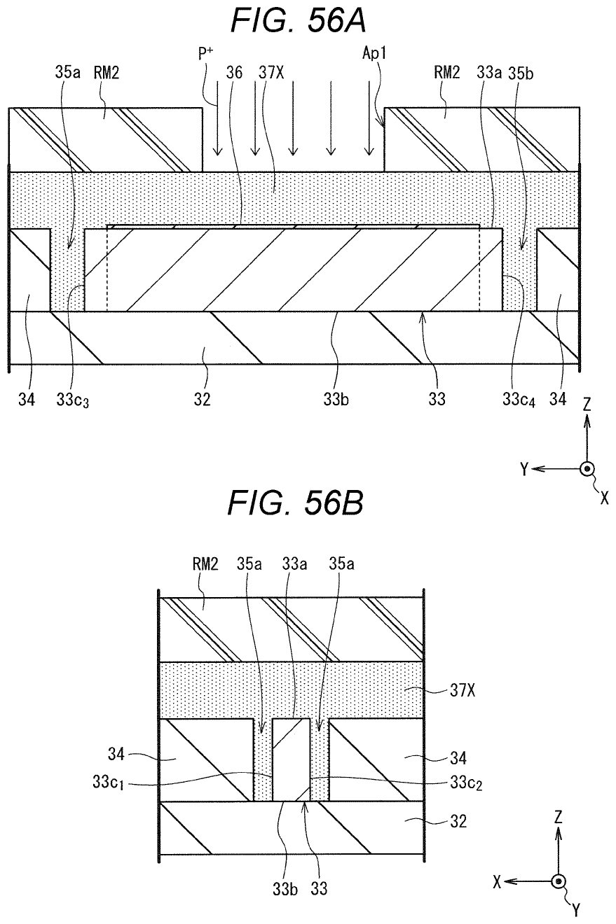

Next, as illustrated in FIG. 55 (schematic plan view), FIG. 56A (schematic longitudinal cross-sectional view illustrating a longitudinal cross-sectional structure taken along a cutting line a55-a55 in FIG. 55), and FIG. 56B (schematic longitudinal cross-sectional view illustrating a longitudinal cross-sectional structure taken along a cutting line c55-c55 in FIG. 55), a mask RM2 as an impurity introduction mask having an opening Ap1 in a gate electrode formation region of the polycrystalline silicon film 37X is formed on the polycrystalline silicon film 37X. Then, as illustrated in FIG. 56A, using the mask RM2 as an impurity introduction mask, for example, phosphorus ions (P⁺) are selectively implanted as n-type impurities into the gate electrode formation region of the polycrystalline silicon film 37X through the opening Ap1 of the mask RM2. The mask RM2 can be formed by a known photolithography technique.

This implantation of phosphorus ions (P⁺) is for reducing the resistance value of the gate electrode formation region of the polycrystalline silicon film 37X. The implantation of phosphorus ions (P⁺) is performed, for example, under conditions where the dose amount is about 5×10¹⁵/cm² and the acceleration energy is about 5 keV. Arsenic ions (As⁺) may be used as the n-type impurity.

Through this step, phosphorus ions (P⁺) are selectively introduced into the gate electrode formation region of the polycrystalline silicon film 37X.

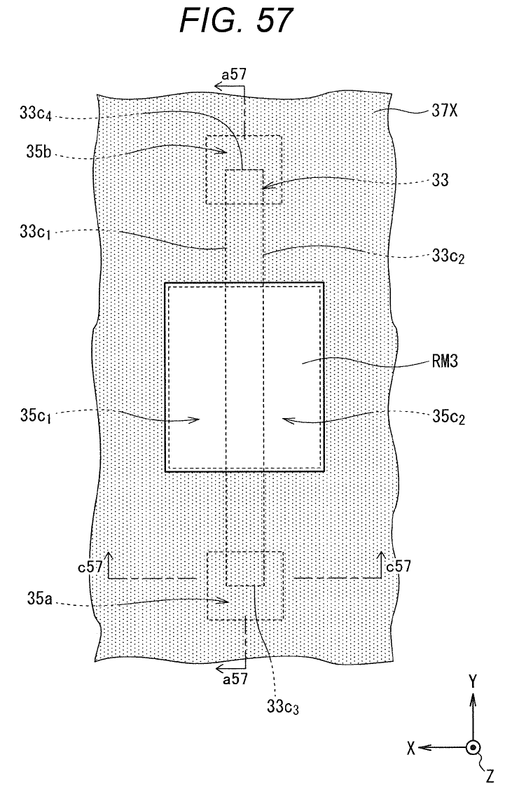

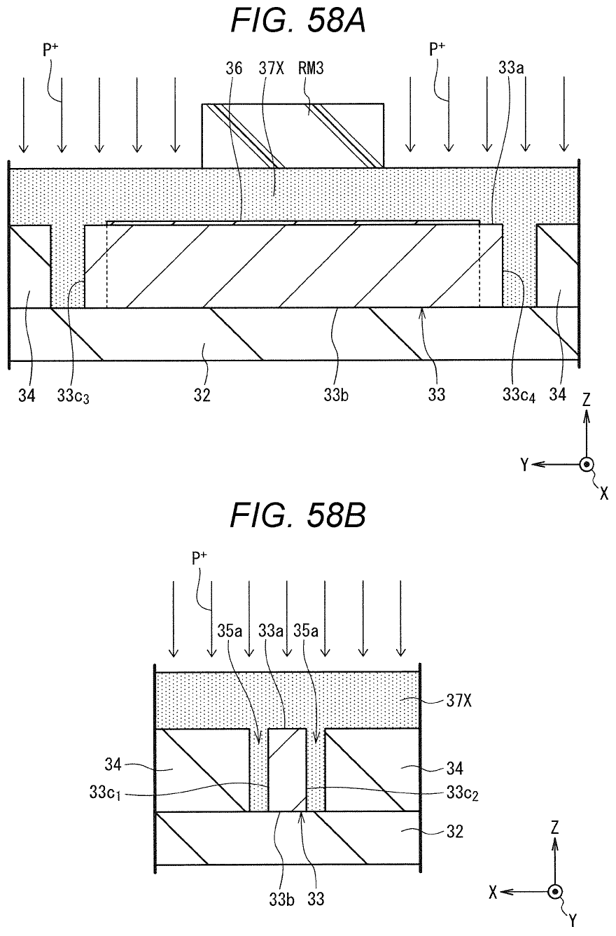

Next, after the mask RM2 is removed, as illustrated in FIG. 57 (schematic plan view), FIG. 58A (schematic longitudinal cross-sectional view illustrating a longitudinal cross-sectional structure taken along a cutting line a57-a57 in FIG. 57), and FIG. 58B (schematic longitudinal cross-sectional view illustrating a longitudinal cross-sectional structure taken along a cutting line c58-c58 in FIG. 58), a mask RM3 is formed as an impurity introduction mask that selectively covers the gate electrode formation region of the polycrystalline silicon film 37X. Then, as illustrated in FIGS. 57, 58A, and 58B, the mask RM3 is used as an impurity introduction mask, and for example, phosphorus ions are implanted as n-type impurities into the polycrystalline silicon film 37X outside the mask RM3. The mask RM3 can be formed by a known photolithography technique.

This implantation of phosphorus ions (P⁺) is for reducing the resistance value of the contact electrode formation region of the polycrystalline silicon film 37X, and for forming n-type semiconductor regions 39a and 39b described later on both end portion sides in the longitudinal direction (Y direction) of the semiconductor portion 33. The implantation of the phosphorus ions (P⁺) is performed at a concentration higher than the phosphorus ions (P⁺) in the ion implantation step illustrated in FIG. 56 described above. For example, the measurement is performed under conditions where the dose amount is about 1×10¹⁶/cm² and the acceleration energy is about 1 keV. Arsenic ions (As⁺) may be used as the n-type impurity.

Through this step, phosphorus ions (P⁺) are introduced into the contact electrode formation region of the polycrystalline silicon film 37X.

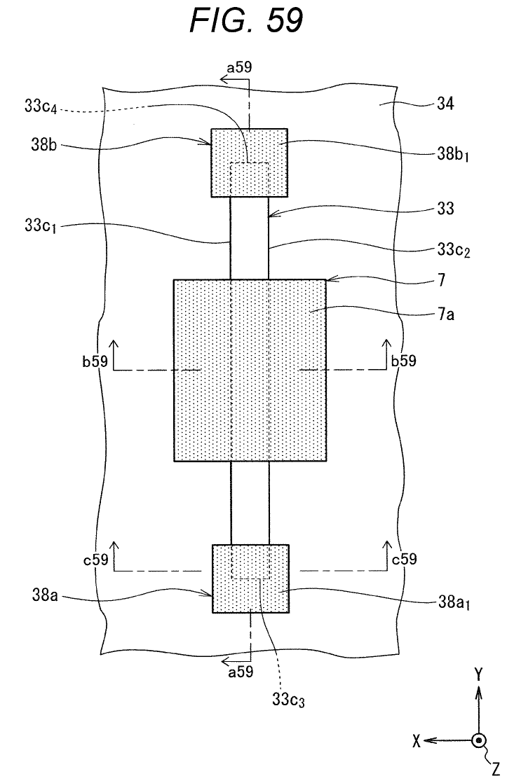

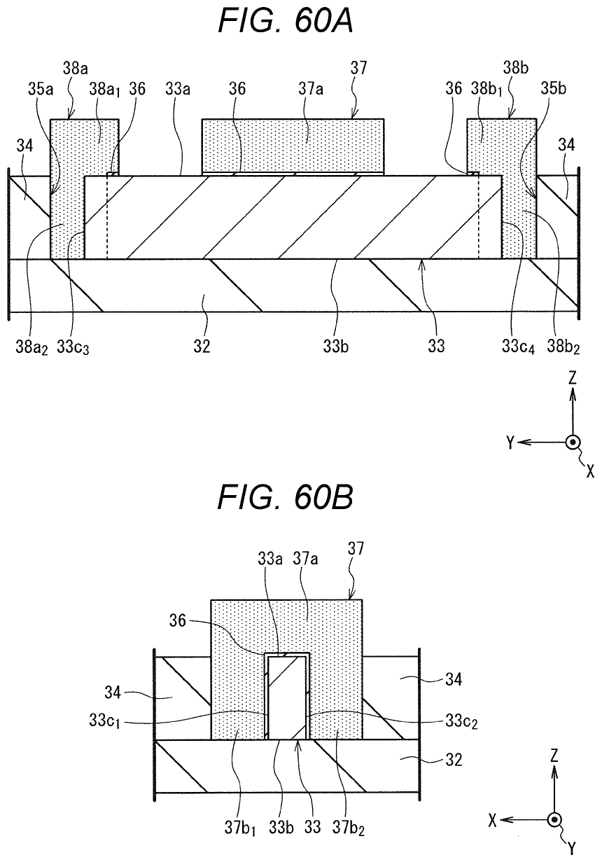

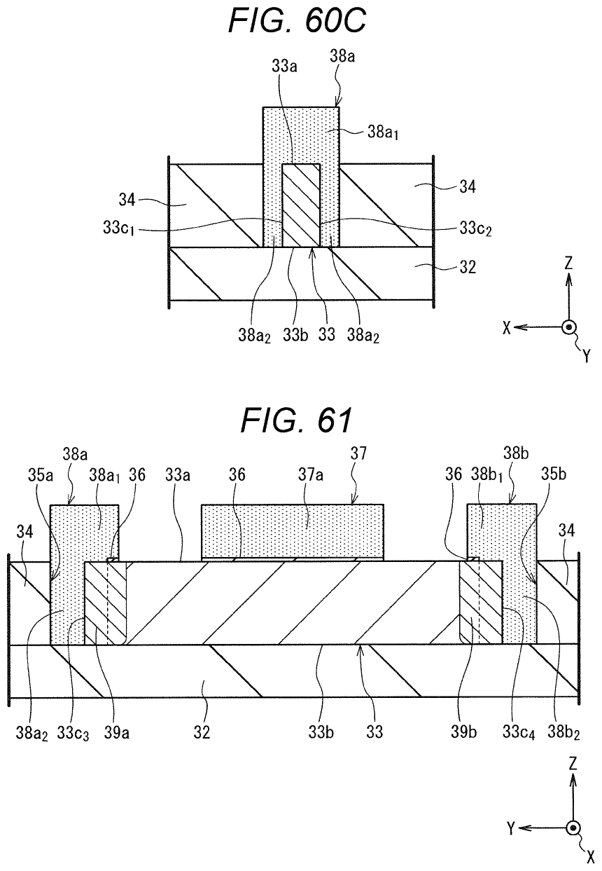

Next, the polycrystalline silicon film 37X is patterned to form the gate electrode 37 and the contact electrodes 38a and 38b as illustrated in FIG. 59 (schematic plan view), FIG. 60A (schematic longitudinal cross-sectional view illustrating a longitudinal cross-sectional structure taken along a cutting line a59-a59 cut line in FIG. 59), FIG. 60B (schematic longitudinal cross-sectional view illustrating a longitudinal cross-sectional structure taken along a cutting line b59-b59 cut line in FIG. 59), and FIG. 60C (schematic longitudinal cross-sectional view illustrating a longitudinal cross-sectional structure taken along a cutting line c59-c59 cut line in FIG. 59). That is, the contact electrodes 38a and 38b are constituted by the same layer (the same step and the same material) as the gate electrode 37. The patterning of the polycrystalline silicon film 37X can be performed using a known photolithography technique, dry etching technique, and the like.

In this step, the gate electrode 37 is formed so as to face the upper surface portion 33a of the semiconductor portion 33 and each of the two side surface portions 33c₁ and 33c₂ with the gate insulating film 36 interposed therebetween. Specifically, the gate electrode 37 includes a head portion (first portion) 37a provided on the upper surface portion 33a side of the semiconductor portion 33 with the gate insulating film 36 interposed therebetween, and two leg portions (second portions) 37b₁ and 37b₂ integrated with the head portion 37a and provided outside each of the two side surface portions 3c₁ and 3c₂ located on opposite sides in the lateral direction (X direction) of the semiconductor portion 33 with the gate insulating film 36 interposed therebetween. The head portion 37a protrudes upward from the second insulating film 34. Each of the two leg portions 37b₁ and 37b₂ is separately provided in each of the dug portions 35a and 35b.

In addition, in this step, the contact electrode 38a is formed to overlap the semiconductor portion 33 in plan view on one side surface portion 33c₃ side of the two side surface portions 33c₃ and 33c₄ located in the longitudinal direction (Y direction) of the semiconductor portion 33. Then, the contact electrode 38a includes a head portion 38a₁ protruding upward from the second insulating film 34, and a leg portion 38a₂ integrated with the head portion 38a₁ and provided in a dug portion 35a between the second insulating film 34 and the semiconductor portion 33. Then, in the contact electrode 38a, on one end portion side (side surface portion 33c₃ side) in the longitudinal direction of the semiconductor portion 33, the head portion 38a₁ is connected to the upper surface portion 33a of the semiconductor portion 33, and the leg portion 38a₂ is connected to the three side surface portions 33c₁, 33c₂, and 33c₃ of the semiconductor portion 33.

Furthermore, in this step, the contact electrode 38b is formed to overlap the semiconductor portion 33 in plan view on the side of the other side surface portion 33c₄ of the two side surface portions 33c₃ and 33c₄ located in the longitudinal direction (Y direction) of the semiconductor portion 33. Then, the contact electrode 38b includes a head portion 38b₁ protruding upward from the second insulating film 34, and a leg portion 38b₂ integrated with the head portion 38b₁ and provided in the dug portion 35b between the second insulating film 34 and the semiconductor portion 33. Then, in the contact electrode 38b, on the other end portion side (side surface portion 33c₄ side) in the longitudinal direction of the semiconductor portion 33, the head portion 38b₁ is connected to the upper surface portion 33a of the semiconductor portion 33, and the leg portion 38b₂ is connected to the three side surface portions 33c₁, 33c₂, and 33c₄ of the semiconductor portion 33.

Further, in this step, the gate insulating film 36 selectively remains (is interposed) between the gate electrode 37 side of the contact electrode 38a and the semiconductor portion 33 over the upper surface portion 33a and the two side surface portions 33c₁ and 33c₂ of the semiconductor portion 33, and the gate insulating film 36 selectively remains (is interposed) between the gate electrode 37 side of the contact electrode 38b and the semiconductor portion 33 over the upper surface portion 33a and the two side surface portions 33c₁ and 33c₂ of the semiconductor portion 33.

Furthermore, in this step, the gate insulating film 36 on the upper surface portion 33a of the semiconductor portion 33 between the gate electrode 37 and the contact electrode 38a and the gate insulating film 36 on the upper surface portion 33a of the semiconductor portion 33 between the gate electrode 37 and the contact electrode 38b are selectively removed by over-etching during patterning of the polycrystalline silicon film 37X. The gate insulating film 36 between the gate electrode 37 and the contact electrodes 38a and 38b may remain in a case where the film thickness is large.

Next, after the mask RM3 is removed, a heat treatment is performed to activate the impurity (phosphorus ion (P⁺)) implanted into the gate electrode 37 to electrically conduct the gate electrode 37 (reduce the resistance value of the gate electrode 37), and activate the impurity (phosphorus ion (P⁺)) implanted into each of the contact electrodes 38a and 38b to electrically conduct the contact electrodes 38a and 38b (reduce the resistance value of each of the contact electrodes 38a and 38b).

In this step, the impurity (phosphorus ion (P⁺)) of each of the contact electrodes 38a and 38b are diffused (leaked) to both end portions in the longitudinal direction (Y direction) of the semiconductor portion 33, and as illustrated in FIG. 61 (schematic longitudinal cross-sectional view illustrating a longitudinal cross-sectional structure at the same position as a cutting line a59-a59 in FIG. 59), the n-type semiconductor region 39a is formed on one end portion side (side surface portion 33c₃ side) in the longitudinal direction (Y direction) of the semiconductor portion 33, and the n-type semiconductor region 39b is formed on the other end portion side (side surface portion 33c₄ side).

The n-type semiconductor region 39a is formed from the upper surface portion 33a to the lower surface portion 33b along the three side surface portions 33c₁, 33c₂, and 33c₃ of the semiconductor portion 33. Furthermore, the n-type semiconductor region 39b is formed from the upper surface portion 33a to the lower surface portion 33b along the three side surface portions 33c₁, 33c₂, and 33c₄ of the semiconductor portion 33.

Also in the heat treatment in this step, a phenomenon in which the natural oxide film 33X (see FIGS. 51D and 51E) is fluidized and changed into the granular oxide 33Y (see FIGS. 54A and 54B) can be caused.

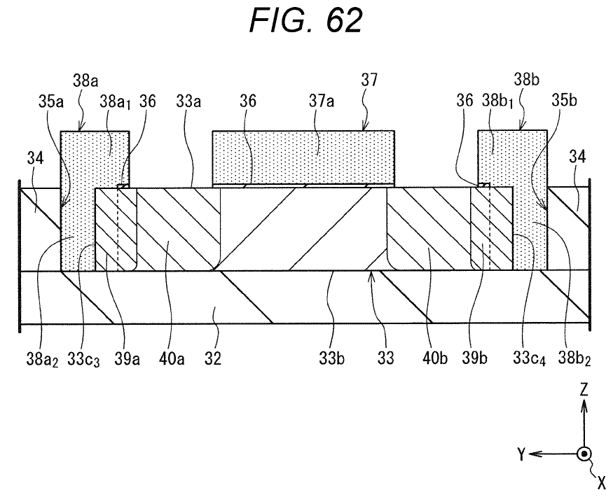

Next, as illustrated in FIG. 62 (schematic longitudinal cross-sectional view illustrating a longitudinal cross-sectional structure at the same position as a cutting line a59-a59 in FIG. 59), a pair of n-type semiconductor regions 40a and 40b having an impurity concentration lower than that of the n-type semiconductor regions 39a and 39b is formed in each of the semiconductor portions 33 on both sides in the gate length direction (Y direction) of the gate electrode 37. Each of the pair of n-type semiconductor regions 40a and 40b functions as an extension region.

Each of the pair of n-type semiconductor regions 40a and 40b can be formed by using the gate electrode 37, the contact electrodes 38a and 38b, and the second insulating film 34 as an impurity introduction mask, implanting, for example, arsenic ions (As⁺) as n-type impurities into each of the semiconductor portions 33 on both sides in the gate length direction (Y direction) of the gate electrode 37, and then subjecting the semiconductor portions to a heat treatment for activating the impurities.

The implantation of arsenic ions (As⁺) is performed, for example, under conditions where the dose amount is about 3×10¹⁴/cm² and the acceleration energy is about 80 keV. Phosphorus ions (P⁺) may be used as the n-type impurity.

In this step, each of the pair of n-type semiconductor regions 40a and 40b is formed on each of the semiconductor portions 33 on both sides of the gate electrode 37 in the gate length direction (Y direction) so as to be aligned with the head portion 37a of the gate electrode 37.

In addition, one n-type semiconductor region 40a of the pair of n-type semiconductor regions 40a and 40b is formed in the semiconductor portion 33 in contact with the n-type semiconductor region 39a, and the other n-type semiconductor region 40b is formed in the semiconductor portion 33 in contact with the n-type semiconductor region 39b.

Furthermore, in the heat treatment in this step, a phenomenon in which the natural oxide film 33X (see FIGS. 51D and 51E) is fluidized and changed into the granular oxide 33Y (see FIGS. 54A and 54B) can be caused.

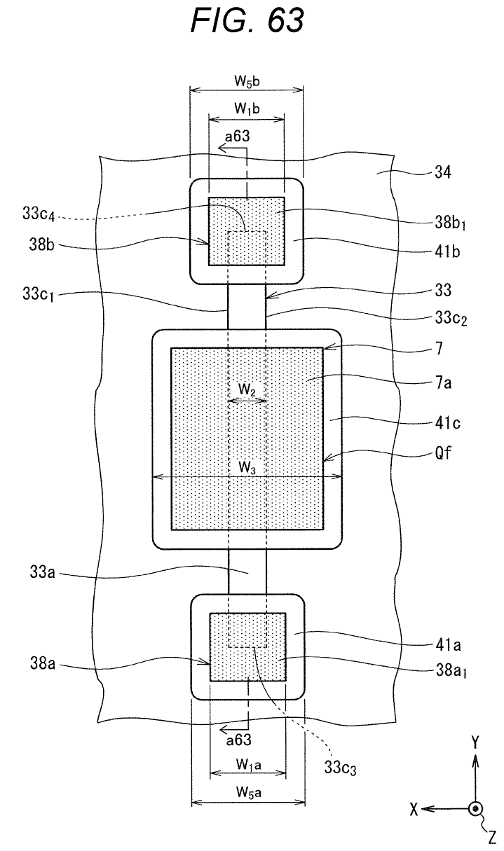

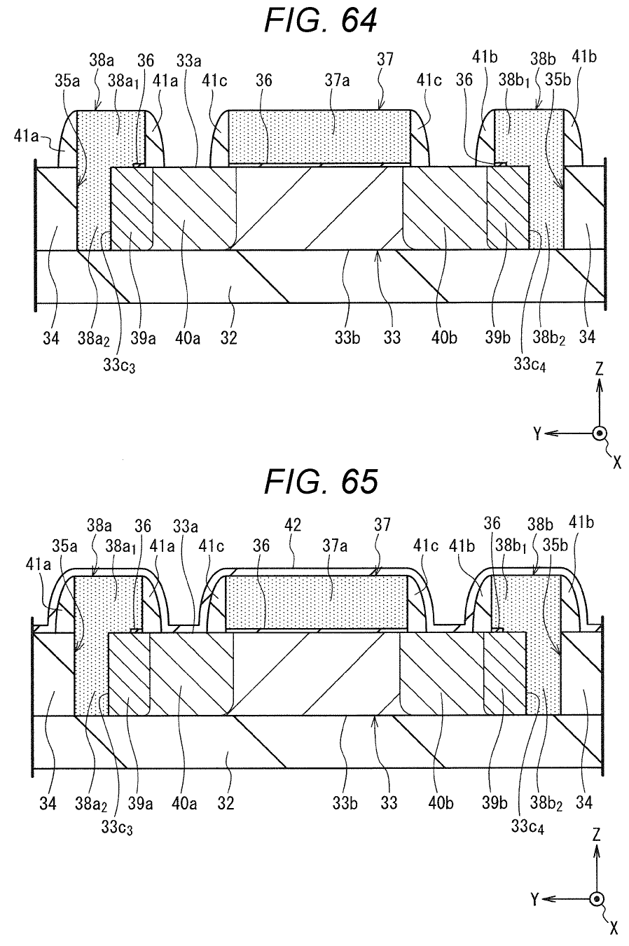

Next, as illustrated in FIG. 63 (schematic plan view) and FIG. 64 (schematic longitudinal cross-sectional view illustrating a longitudinal cross-sectional structure taken along a cutting line a63-a63 in FIG. 63), the sidewall spacers 41c are formed on the sidewalls of the head portions 37a of the gate electrodes 37 protruding upward from the second insulating film 34, and the sidewall spacers 41a and 41b are formed on the sidewalls of the respective head portions 38a₁ and 38b₁ of the contact electrodes 38a and 38b protruding upward from the second insulating film 34.

Each of the sidewall spacers 41a, 41b, and 41c can be formed by forming a silicon nitride film having selectivity to, for example, a silicon oxide film as an insulating film on the entire surface of the second insulating film 34 by a CVD method so as to cover the head portions 38a₁ and 38b₁ of the contact electrodes 38a and 38b and the head portion 37a of the gate electrode 37, and then applying anisotropic dry etching such as RIE to the silicon nitride film.

The sidewall spacer 41a is formed so as to surround the head portion 38a₁ of the contact electrode 38a, and is formed so as to be aligned with the head portion 38a₁ of the contact electrode 38a. The sidewall spacer 41b is formed so as to surround the head portion 38b₁ of the contact electrode 38b, and is formed so as to be aligned with the head portion 38b₁ of the contact electrode 38b. The sidewall spacer 41c is formed so as to surround the head portion 37a of the gate electrode 37, and is formed so as to be aligned with the head portion 37a of the gate electrode 37.

Each of the sidewall spacers 41a, 41b, and 41c is formed on the second insulating film 34 and the semiconductor portion 33 so as to cross the semiconductor portion 33.

Next, as illustrated in FIG. 65 (schematic longitudinal cross-sectional view illustrating a longitudinal cross-sectional structure at the same position as a cutting line a63-a63 in FIG. 63), a buffer insulating film 42 is formed. The buffer insulating film 42 is formed so as to cover each of the head portion 37a of the gate electrode 37, the head portion 38a₁ and 38b₁ of each of the two contact electrodes 38a and 38b, and the sidewall spacers 41a, 41b, and 41c, and to cover the semiconductor portion 33 between the head portion 37a of the gate electrode 37 and the contact electrodes 38a and 38b. The buffer insulating film 42 is used as a buffer film at the time of ion implantation of impurities in a step of forming n-type semiconductor regions 43a and 43b to be described later. As the buffer insulating film 42, for example, a silicon oxide film can be used.

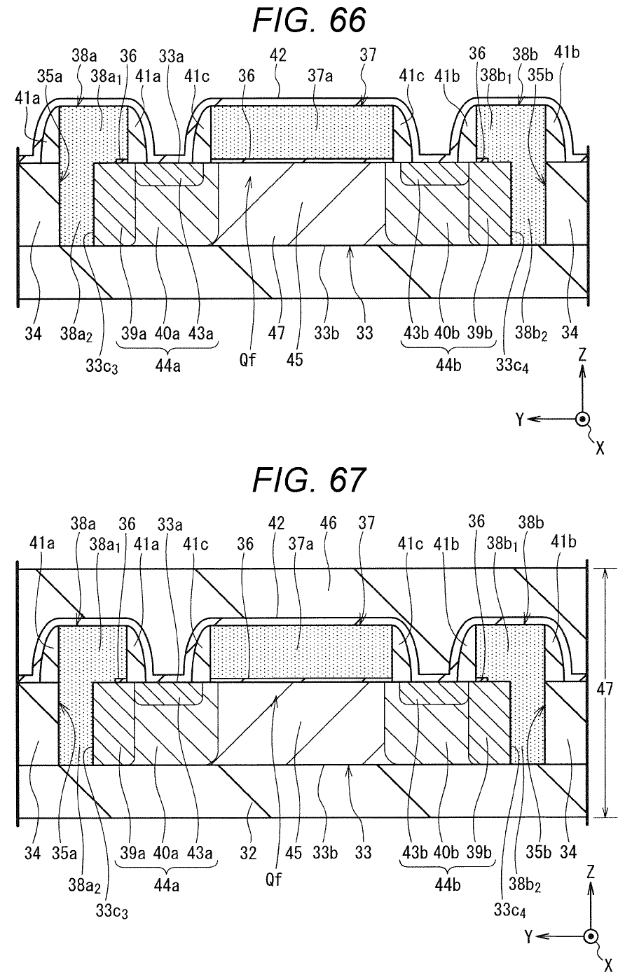

Next, as illustrated in FIG. 66 (schematic longitudinal cross-sectional view illustrating a longitudinal cross-sectional structure at the same position as a cutting line a63-a63 in FIG. 63), a pair of n-type semiconductor regions 43a and 43b having a higher impurity concentration than the n-type semiconductor regions 39a and 39b is formed in each of the semiconductor portions 33 on both sides in the gate length direction (Y direction) of the gate electrode 37.

Each of the pair of n-type semiconductor regions 43a and 43b can be formed by using the gate electrode 37, the contact electrodes 38a and 38b, the sidewall spacers 41a, 41b, and 41c, and the second insulating film 34 as an impurity introduction mask, implanting, for example, phosphorus ions (P⁺) as an n-type impurity through the buffer insulating film 42 into the semiconductor portion 33 between the sidewall spacer 41c of the sidewall of the gate electrode 37 and the sidewall spacer 41a of the sidewall of the contact electrode 38a and the semiconductor portion 33 between the sidewall spacer 41c of the sidewall of the gate electrode 37 and the sidewall spacer 41b of the contact electrode 38b, respectively, and then subjecting the semiconductor portion to a heat treatment for activating the impurity.

The implantation of phosphorus ions (P⁺) is performed, for example, under conditions where the dose amount is about 8×10¹⁵/cm² and the acceleration energy is about 10 keV. Arsenic ions (As⁺) may be used as the n-type impurity.

In this step, since phosphorus ions (P⁺) are implanted into the semiconductor portion 33 through the buffer insulating film 42, damage to the semiconductor portion 33 due to ion implantation can be suppressed.

Furthermore, in this step, the n-type semiconductor region 43a is formed so as to be aligned with the sidewall spacer 41c of the sidewall of the gate electrode 37 and the sidewall spacer 41a of the sidewall of the contact electrode 38a. Furthermore, the n-type semiconductor region 43b is formed so as to be aligned with the sidewall spacer 41c of the sidewall of the gate electrode 37 and the sidewall spacer 41b of the sidewall of the contact electrode 38b.

Furthermore, in this step, the main electrode region 44a including the n-type semiconductor region 39a, the n-type semiconductor region 40a, and the n-type semiconductor region 43a is formed, and the main electrode region 44b including the n-type semiconductor region 39b, the n-type semiconductor region 40b, and the n-type semiconductor region 43b is formed.

Furthermore, in this step, the channel formation portion 45 is formed in the semiconductor portion 3 between the pair of main electrode regions 44a and 44b.

Furthermore, in this step, the field effect transistor Of including the gate insulating film 36, the gate electrode 37, the pair of main electrode regions 44a and 44b, the channel formation portion 45, and the like is formed in the semiconductor portion 33.

Furthermore, in the heat treatment in this step, a phenomenon in which the natural oxide film 33X (see FIGS. 51D and 51E) is fluidized and changed into the granular oxide 33Y (see FIGS. 54A and 54B) can be caused.

Next, as illustrated in FIG. 67 (schematic longitudinal cross-sectional view illustrating a longitudinal cross-sectional structure at the same position as a cutting line a63-a63 in FIG. 63), a third insulating film 46 is formed on the entire surface of the buffer insulating film 42 so as to cover the gate electrode 37 and the contact electrodes 38a and 38b. The third insulating film 46 can be formed by forming, for example, a silicon oxide film as an insulating film on the entire surface of the buffer insulating film 42 including the gate electrode 37 and the head portions 37a, 38a₁, and 38b₁ of the contact electrodes 38a and 38b, and then planarizing the surface of the silicon oxide film by a CMP method or the like.

In this step, the insulating layer 47 including the first insulating film 32, the second insulating film 34, the buffer insulating film 42, and the third insulating film 46 and including the semiconductor portion 33 and the field effect transistor Of is formed.

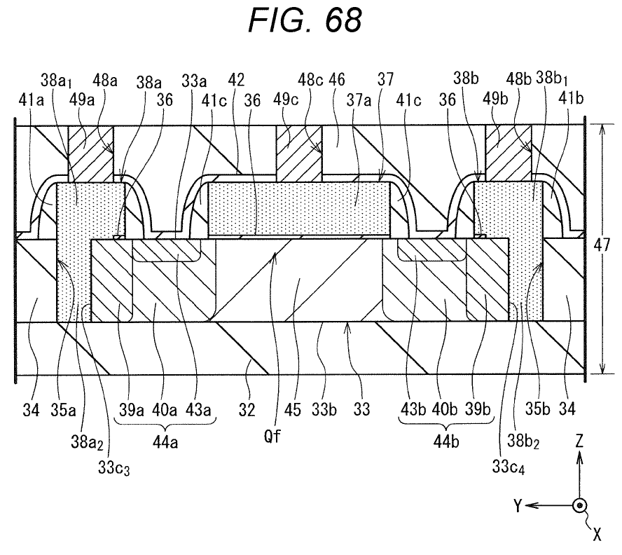

Next, as illustrated in FIG. 68 (schematic longitudinal cross-sectional view illustrating a longitudinal cross-sectional structure at the same position as a cutting line a63-a63 in FIG. 63), dug portions 48a and 48b individually reaching the respective head portions 38a₁ and 38b₁ of the contact electrodes 38a and 38b from the surface of the insulating layer 47 (the surface of the third insulating film 46), and a dug portion 48c reaching the head portion 37a of the gate electrode 37 from the surface of the insulating layer 47 (the surface of the third insulating film 46) are formed.

Then, thereafter, as illustrated in FIG. 68, the contact electrodes 49a, 49b, and 49c are separately formed in the dug portions 48a, 48b, and 48c, respectively.

Each of the dug portions 48a, 48b, and 48c can be formed by etching the insulating layer 14 using a known photolithography technique and an anisotropic dry etching technique.

Each of the contact electrodes 49a, 49b, and 49c can be formed by forming a tungsten film, for example, as a high melting point metal film on the entire surface on the insulating layer 47 including the inside of each of the dug portions 48a, 48b, and 48c, and then selectively removing the tungsten film on the insulating layer 47 such that the tungsten film individually remains inside each of the dug portions 48a, 48b, and 48c.

In this step, the contact electrode 49a is electrically and mechanically connected to the contact electrode 38a, and is electrically connected to the one main electrode region 44a of the field effect transistor Of via the contact electrode 38a. Furthermore, the contact electrode 49b is electrically and mechanically connected to the contact electrode 38b, and is electrically connected to the other main electrode region 44b of the field effect transistor Of via the contact electrode 38b. Then, the contact electrode 49c is electrically and mechanically connected to the gate electrode 37 of the field effect transistor Qf.

Next, wirings 50a, 50b, and 50c separately electrically and mechanically connected to the contact electrodes 49a, 49b, and 49c are formed in the wiring layer on the insulating layer 47, so that the state illustrated in FIGS. 40 to 43 is obtained.

Note that, in a case where the gate insulating film 36 remains on the upper surface portion 33a of the semiconductor portion 33 between the sidewall spacer 41c of the sidewall of the gate electrode 37 and the sidewall spacer 41a of the sidewall of the contact electrode 38a, and on the upper surface portion 33a of the semiconductor portion 33 between the sidewall spacer 41c of the sidewall of the gate electrode 37 and the sidewall spacer 41b of the sidewall of the contact electrode 38b, the buffer insulating film 42 may be omitted. In this case, the insulating layer 47 does not include the buffer insulating film 42.

Furthermore, in the manufacturing method of the sixth embodiment, fluorine ions (F⁻) are implanted into the polycrystalline silicon film 37X in order to promote the change from the natural oxide film 33X to the granular oxide 33Y, but the implantation of fluorine ions (F⁻) may be omitted in a case where the introduction of impurities to such an extent that the natural oxide film 33X is fluidized by the heat treatment is secured.

Furthermore, in the manufacturing method according to the sixth embodiment, the heat treatment for activating the impurities in the n-type semiconductor regions 40a and 40b and the heat treatment for activating the impurities in the n-type semiconductor regions 43a and 43b are performed in separate steps. However, the heat treatment for activating the impurities in the n-type semiconductor regions 40a and 40b may be performed in the same step as the heat treatment for activating the impurities in the n-type semiconductor regions 43a and 43b.

### <<Main Effects of Sixth Embodiment>>

As described above, the semiconductor device 1F according to the sixth embodiment includes the contact electrodes 38a and 38b provided to overlap the semiconductor portions 33 on both sides in the gate length direction (Y direction) of the gate electrode 37 in plan view. Then, the contact electrode 38a is connected to each of the upper surface portion 33a of the semiconductor portion 33 and the three side surface portions 33c₁, 33c₂, and 33c₃ on one end portion side in the longitudinal direction (Y direction) of the semiconductor portion 33. Similarly, the contact electrode 38b is also connected to each of the upper surface portion 33a of the semiconductor portion 33 and the three side surface portions 33c₁, 33c₂, and 33c₄ on the other end portion side in the longitudinal direction (Y direction) of the semiconductor portion 33.

Therefore, according to the semiconductor device 1F of the sixth embodiment, the transconductance (gm) of the field effect transistor Qf can be improved, similarly to the first embodiment described above.

In addition, even when the width W₂ of the semiconductor portion 33 in the lateral direction (XY direction) and the widths W₁a and W₁b (diameter and width of thickness) of the contact electrodes 38a and 38b decrease with the miniaturization of the field effect transistor Qf, an increase in contact resistance between the semiconductor portion 33 and the contact electrodes 38a and 38b can be suppressed, so that it is possible to suppress a decrease in transconductance (gm) while miniaturizing the field effect transistor Qf.

In addition, the widths W₁a and W₁b of the contact electrodes 38a and 38b can be made wider than the width W₂ of the semiconductor portion 33, and the difficulty of connecting the contact electrodes 38a and 38b to the contact electrodes 49a and 49b can be reduced. Therefore, even if the width W₂ of the semiconductor portion 33 is narrowed due to miniaturization, the semiconductor portion 33 and the contact electrodes 49a and 49b can be easily electrically connected. As a result, even if the semiconductor portion 33 is miniaturized, a connection failure between the semiconductor portion 33 and the upper layer wirings 50a and 50b due to mask misalignment can be suppressed, and the manufacturing yield of the semiconductor device 1F can be improved.

In addition, since the contact electrodes 38a and 38b are formed in the same layer as the gate electrode 37 in the semiconductor device 1F according to the sixth embodiment, the contact electrodes 38a and 38b can be provided at low cost as compared with a case where the contact electrodes 38a and 38b are formed in a layer different from the gate electrode 37. Therefore, according to the semiconductor device 1F of the sixth embodiment, it is possible to reduce the cost and improve the transconductance (gm) of the field effect transistor Qf.

In addition, since the contact electrodes 38a and 38b are formed in the same layer as the gate electrode 37, the thicknesses Th₁ and Th₂ of the respective portions (head portion 38a₁, head portion 38b₁) of the contact electrodes 38a and 38b overlapping the semiconductor portion 33 in plan view and the thickness Th₃ of the portion (head portion 37a) of the gate electrode 37 overlapping the semiconductor portion 33 in plan view can be made substantially the same.

As a result, since the thickness of the insulating layer 47 on the contact electrodes 38a and 38b and the thickness of the insulating layer 47 on the gate electrode 37 are substantially the same, it is possible to reduce the over-etching time when the dug portion is formed in the insulating layer 47 corresponding to the contact electrodes 38a and 38b and the gate electrode 37, and it is possible to suppress variations in the widths (diameter and thickness) of the dug portions 48a, 48b, and 48c due to the over-etching.

In addition, in the method for manufacturing the semiconductor device 1F according to the sixth embodiment, the natural oxide film 33X formed on the semiconductor portion 33 is fluidized by heat treatment and converted into the granular (spherical) oxide 33Y, so that the contact characteristics between the semiconductor portion 33 and the contact electrodes 38a and 38b can be further improved.

In addition, in the method for manufacturing the semiconductor device 1F according to the sixth embodiment, the semiconductor portion 33 on which the gate insulating film 36 is formed except for both end portion sides in the longitudinal direction (Y direction) is covered with the polycrystalline silicon film 37X, and thereafter, the polycrystalline silicon film 33X is patterned to form the gate electrode 37 and the contact electrodes 38a and 38b, so that the gate insulating film 36 can remain on the gate electrode 37 side between the contact electrodes 38a and 38b and the semiconductor portion 33.

### <<Modification of Sixth Embodiment>>

In the above-described sixth embodiment, as the side surface connection form in which the contact electrodes 38a and 38b are connected to the side surface portion of the semiconductor portion 33, the side surface connection form in which the contact electrodes 38a and 38b are connected to the three side surface portions 33c₁, 33c₂, and 33c₃ (or 33c₄) of the semiconductor portion 33 has been described. However, the present technology is not limited to the side surface connection form of the sixth embodiment described above.

That is, as the side surface connection form, each of the contact electrodes 38a and 38b is only required to be connected to at least one of the three side surface portions 33c₁, 33c₂, or 33c₃ (or 33c₄) of the semiconductor portion 33.

In addition, each of the contact electrodes 38a and 38b is only required to be connected to at least one of the two side surface portions 33c₁ or 33c₂ in the lateral direction (X direction) of the semiconductor portion 33.

In addition, each of the contact electrodes 38a and 38b is only required to be connected to at least one of the two side surface portions in the lateral direction of the semiconductor portion 33.

### <First Modification>

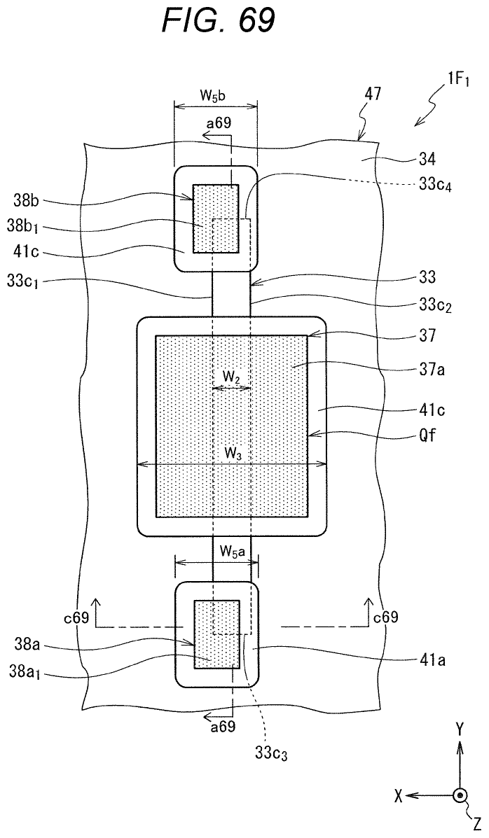

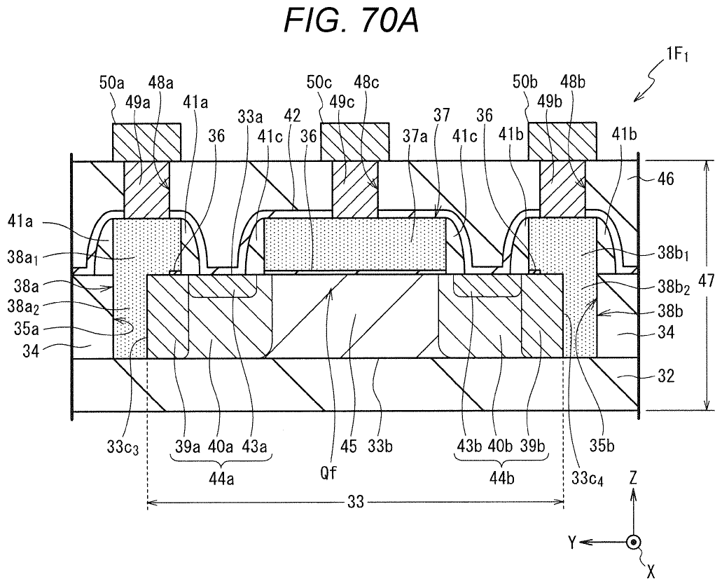

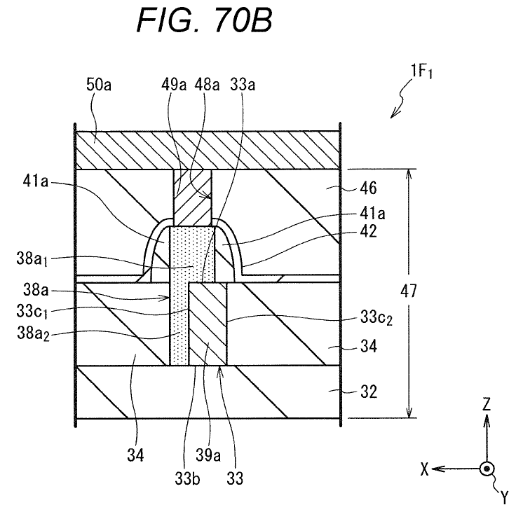

For example, as the side surface connection form, as illustrated in FIGS. 69, 70A, and 70B, the contact electrodes 38a and 38b may be connected to any one of the two side surface portions 33c₁ and 33c₂ located in the lateral direction (X direction) of the semiconductor portion 33, and may be connected to the side surface portion 33c₃ (or the side surface portion 33c₄) located in the longitudinal direction (Y direction) of the semiconductor portion 33. In this case, the contact electrodes 38a and 38b are connected to the upper surface portion 33a of the semiconductor portion 33, and are connected to two side surface portions of the three side surface portions 33c₁, 33c₂/and 33c₃ (or 33c₄) of the semiconductor portion 33.

In FIGS. 69, 70A, and 70B, as an example, the configuration in which the contact electrodes 38a and 38b are connected to one side surface portion 33c₃ of the two side surface portions 33c₁ and 33c₂ located in the lateral direction of the semiconductor portion 33 is exemplified, but it is a matter of course that the contact electrodes 38a and 38b may be connected to the other side surface portion 33c₂.

Also in the semiconductor device 1F₁ according to the first modification of the sixth embodiment, effects similar to those of the semiconductor device 1F according to the sixth embodiment described above can be obtained.

Furthermore, although not illustrated in FIG. 69, in the first modification of the sixth embodiment, in a case where the through contact electrode 24 illustrated in FIGS. 28 and 29 is provided adjacent to the contact electrode 38a on the outer side of the other side surface portion 33c₂ of the two side surface portions 33c₁ and 33c₂ (the side surface portions 3c₁ and 3c₂ in the third embodiment) in the lateral direction (X direction) of the semiconductor portion 33 in plan view, similarly to the above-described third embodiment, since the contact electrode 38a (the contact electrode 17a in the third embodiment) is selectively connected to the one side surface portion 33c₁ on the opposite side to the other side surface portion 33c₂ on the through contact electrode 24 side of the semiconductor portion 33 among the two side surface portions 33c₁ and 33c₂ located in the lateral direction of the semiconductor portion 33, the interval (distance) Lx between the contact electrode 38a and the through electrode 24 is increased as compared with the above-described sixth embodiment, and thus, it is possible to reduce the parasitic capacitance in which the insulating film between the contact electrode 38a and the through contact electrode 24 is a dielectric film, similarly to the above-described third embodiment.

Note that, similarly to the third embodiment described above, even in a case where the through contact electrode 24 illustrated in FIGS. 28 and 29 is provided adjacent to the contact electrode 38b (17b in the third embodiment) on the outer side in the lateral direction (X direction) of the semiconductor portion 33 in plan view, the through contact electrode is selectively connected to one side surface portions 33c₁ on the opposite side to the other side surface portion 3c₂ on the through contact electrode 24 side of the semiconductor portion 33 among the two side surface portions 3c₁ and 3c₂ located on both sides in the lateral direction (X direction) of the semiconductor portion 33, so that it is possible to reduce the parasitic capacitance with the insulating film between the contact electrode 38b and the through contact electrode 24 as the dielectric film.

Note that, in FIG. 69, similarly to FIG. 40 of the above-described sixth embodiment, illustration of an upper layer than the sidewall spacers 41a, 41b, and 41c is omitted for convenience of description.

### <Second Modification>

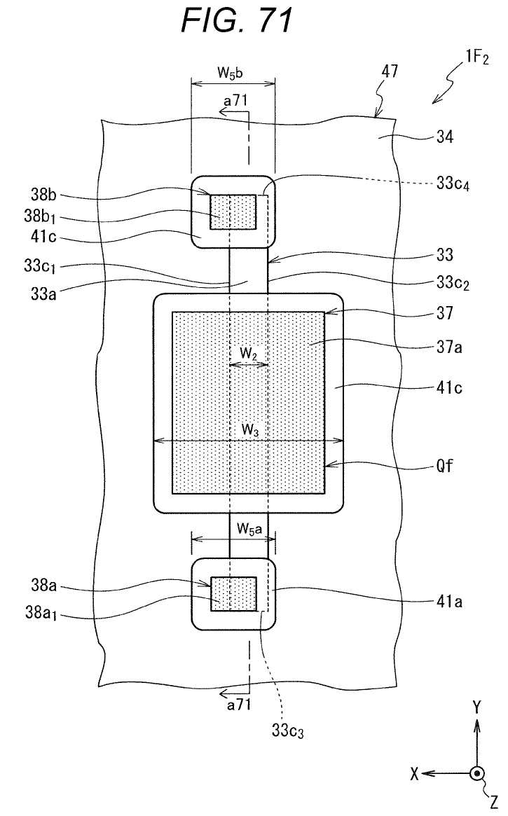

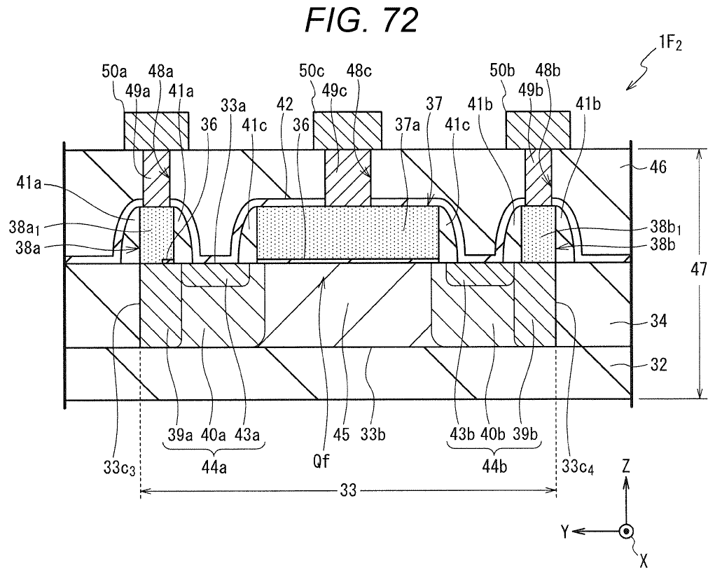

In addition, as a side surface connection form, as illustrated in FIGS. 71 and 72, the contact electrodes 38a and 38b may be connected to any one of the two side surface portions 33c₁ and 33c₂ located in the lateral direction (X direction) of the semiconductor portion 33, and may not be connected to the side surface portion located in the longitudinal direction (Y direction) of the semiconductor portion 33. In this case, the contact electrodes 38a and 38b are connected to the upper surface portion 33a of the semiconductor portion 33, and are connected to one of the three side surface portions 33c₁, 33c₂/and 33c₃ (or 33c₄) of the semiconductor portion 33.

Note that, in FIG. 71, similarly to FIG. 40 of the above-described sixth embodiment, illustration of an upper layer than the sidewall spacers 41a, 41b, and 41c is omitted for convenience of description.

Also in the semiconductor device 1F₂ according to the second modification of the sixth embodiment, effects similar to those of the semiconductor device 1F according to the sixth embodiment described above can be obtained.

Furthermore, in the second modification of the sixth embodiment, similarly to the arrangement illustrated in FIG. 26 of the second embodiment described above, in a case where the two semiconductor portions 33 are arranged in series in the Y direction with a predetermined interval in a direction in which the longitudinal directions (Y directions) of each are the same, the interval Ly (see FIG. 26) between the two semiconductor portions 33 can be narrowed, so that the field effect transistor Qf can be arranged more densely.

Note that, in FIGS. 71 and 72, the side surface portion of the head portion 38a₁ of the contact electrode 38a is flush with the side surface portion 33c₃ on one end portion side in the longitudinal direction (Y direction) of the semiconductor portion 33 in plan view. However, in the case of a side surface connection form in which the contact electrode 38a is not connected to the side surface portion 33c₃ of the semiconductor portion 33, similarly to the second embodiment described above, the contact electrode 38a is preferably located closer to the gate electrode 37 than the side surface portion 33c₃ of the semiconductor portion 33. In addition, similarly, in a case of a side surface connection form in which the contact electrode 38b is not connected to the side surface portion 33c₄ of the semiconductor portion 33, it is preferable that the contact electrode 38b is located closer to the gate electrode 37 than the side surface portion 33c₄ of the semiconductor portion 33.

### <Third Modification>

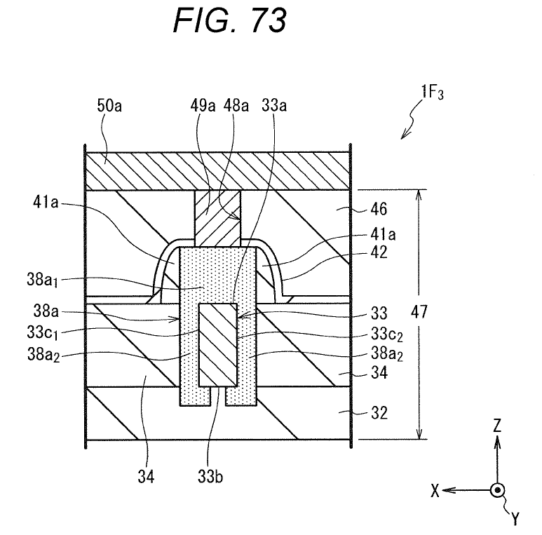

In the above-described sixth embodiment, as illustrated in FIGS. 41 and 43, the configuration in which each of the contact electrodes 38a and 38b is connected to the upper surface portion 3a and the three side surface portions 3c₁, 3c₂, and 33c₃ (or 33c₄) of the semiconductor portion 33 has been described. However, as illustrated in FIG. 73, the contact electrode 38a may also be connected to the lower surface portion 33b of the semiconductor portion 33.

That is, the contact electrode 38a of the third modification is connected to each of the upper surface portion 33a of the semiconductor portion 33 and the three side surface portions 33c₁, 33c₂, and 33c₃, and is also connected to the lower surface portion 33b of the semiconductor portion 33.

According to the semiconductor device 1F₃ according to the third modification of the sixth embodiment, as compared with the semiconductor device 1F according to the sixth embodiment described above, the contact area between the semiconductor portion 33 (one main electrode region 44a) and the contact electrode 38a increases, and the contact resistance between the semiconductor portion 33 (one main electrode region 11a) and the contact electrode 38a can be further reduced.

Further, in FIG. 73, as an example, a configuration in which the central portion of the lower surface portion 33b in the lateral direction (X direction) of the semiconductor portion 33 is not selectively covered with the contact electrode 38a is exemplified. However, as in the modification illustrated in FIG. 27 of the second embodiment described above, the contact electrode 38a may continuously cover the lower surface portion 33b of the semiconductor portion 33 along the lateral direction of the semiconductor portion 33.

Note that, in FIG. 73, the contact electrode 38a is exemplified as an example, but the contact electrode 38b preferably has a configuration similar to that of the contact electrode 38a.

### Seventh Embodiment

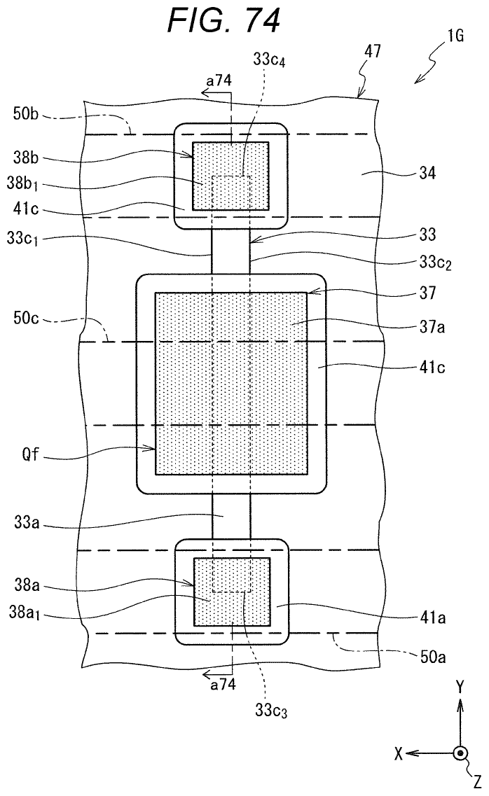

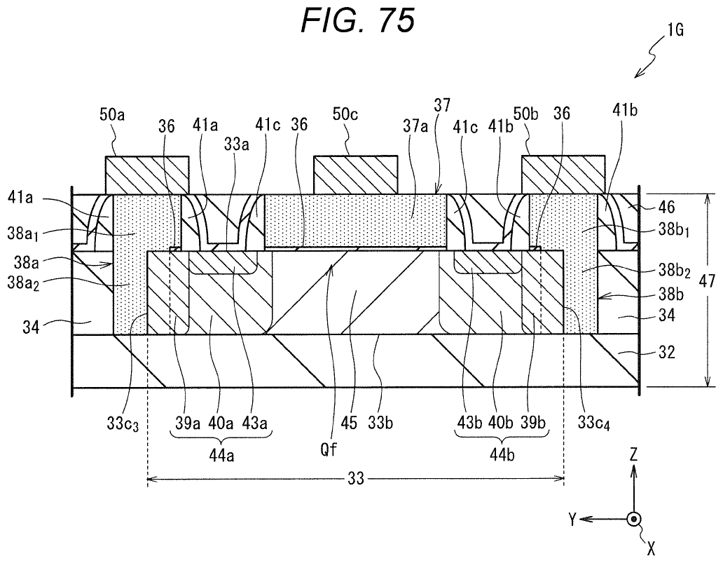

As illustrated in FIGS. 74 and 75, a semiconductor device 1G according to a seventh embodiment of the present technology basically has a configuration similar to that of the semiconductor device 1F according to the above-described sixth embodiment, and the following configuration is different.

That is, as illustrated in FIGS. 41, 42, and 43, in the semiconductor device 1F according to the above-described sixth embodiment, the wiring 50a is electrically connected to the contact electrode 38a via the contact electrode 49a, and the wiring 50b is electrically connected to the contact electrode 38b via the contact electrode 49b. In addition, the wiring 50c is electrically connected to the gate electrode 37 via the contact electrode 49c. That is, two connection portions exist between the wirings 50a, 50b, and 50c, and the contact electrodes 38a and 38b and the gate electrode 37, respectively.

Meanwhile, in the semiconductor device 1G according to the seventh embodiment, the wiring 50a is directly connected to the contact electrode 38a, and the wiring 50b is directly connected to the contact electrode 38b. Furthermore, the wiring 50c is directly connected to the gate electrode 37. That is, in the seventh embodiment, one connection portion exists between each of the wirings 50a, 50b, and 50c and each of the contact electrodes 38a and 38b and the gate electrode 37.

Then, in the semiconductor device 1G according to the seventh embodiment, similarly to the above-described sixth embodiment, since each of the contact electrodes 38a and 38b is formed in the same layer as the gate electrode 37, the thicknesses Th₁ and Th₂ of the respective portions (head portion 38a₁ and head portion 38b₁) of the contact electrodes 38a and 38b overlapping the semiconductor portion 33 in plan view and the thickness Th₃ of the portion (head portion 37a) of the gate electrode 37 overlapping the semiconductor portion 33 in plan view can be made substantially the same, so that the wirings 50a, 50b, and 50c can be directly connected to the contact electrode 38a, the contact electrode 38b, and the gate electrode 37, respectively.

As a result, the resistance (wiring resistance) of each of the conductive path electrically connecting the wiring 50a and one end portion side (one main electrode region 44a) in the longitudinal direction (Y direction) of the semiconductor portion 33, the conductive path electrically connecting the wiring 50b and the other end portion side (the other main electrode region 44b) in the longitudinal direction of the semiconductor portion 33, and the conductive path electrically connecting the wiring 50c and the gate electrode 37 can be lowered. Therefore, according to the semiconductor device 1G according to the seventh embodiment, it is possible to increase the operation speed of the field effect transistor Qf.

Note that, also in the semiconductor device 1G according to the seventh embodiment, the first modification to the third modification of the above-described sixth embodiment can be applied as a connection form in which the contact electrodes 38a and 38b are connected to the side surface portion of the semiconductor portion 33.

Note that, in FIG. 74, similarly to FIG. 40 of the above-described sixth embodiment, illustration of an upper layer than the sidewall spacers 41a, 41b, and 41c is omitted for convenience of description.

### Eighth Embodiment

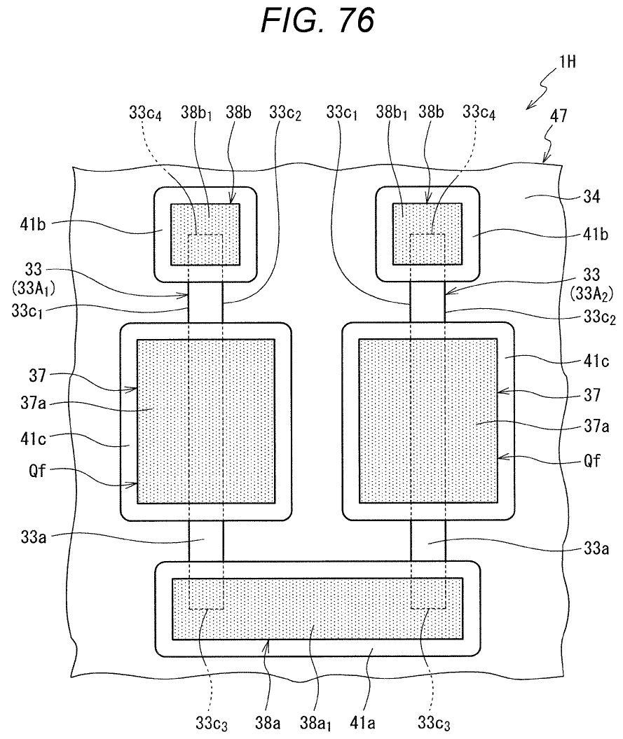

As illustrated in FIG. 76, a semiconductor device 1H according to an eighth embodiment of the present technology basically has a configuration similar to that of the semiconductor device 1F according to the above-described sixth embodiment, and the following configuration is different.

That is, as illustrated in FIG. 76, in the semiconductor device 1H according to the eighth embodiment, the two semiconductor portions 33 (33A₁ and 33A₂) are arranged in parallel at a predetermined interval in the X direction in a direction in which the longitudinal directions (Y directions) of each are the same direction. That is, in the two semiconductor portions 33 (33A₁ and 3A₂), the other side surface portion 3c₂ of the two side surface portions 33c₁ and 33c₂ located in the lateral direction (X direction) of the one semiconductor portion 33 (3A₁) and the one side surface portion 33c₁ of the two side surface portions 33c₁ and 33c₂ located in the lateral direction (X direction) of the other semiconductor portion 33 (33A₂) are adjacent to each other in the X direction and arranged in parallel. Then, the field effect transistor Qf is provided in each of the two semiconductor portions 33 (33A₃ and 33A₄).

In addition, the contact electrode 38a extends over the two semiconductor portions 33 (33A₁ and 33A₂) on one end portion side in the longitudinal direction of each of the two semiconductor portions 33 (33A₁ and 33A₂). Then, the contact electrode 38a is connected to the upper surface portion 33a of each of the two semiconductor portions 33 (33A₁ and 33A₂), and is connected to the three side surface portions 33c₁, 33c₂, and 33c₃ of each of the two semiconductor portions 33 (33A₁ and 33A₂). That is, in the eighth embodiment, one contact electrode 38a is shared by two semiconductor portions 33 (33A₁ and 33A₂).

Also in the semiconductor device 1H according to the eighth embodiment, effects similar to those of the semiconductor device 1F according to the sixth embodiment described above can be obtained.

In addition, since the contact electrode 38a is formed in the same layer as the gate electrode 37, the contact electrode 38a shared by the two semiconductor portions 33 (33A₁ and 33A₂) can be easily formed only by changing the shape of the mask when patterning the polycrystalline silicon film 37X as an electrode formation material.

Note that, in FIG. 76, a case where one contact electrode 38a is shared by two semiconductor portions 33 (33A₁ and 33A₂) is illustrated as an example, but one contact electrode 38b can also be shared by two semiconductor portions 33 (33A₁ and 33A₂).

Furthermore, in the eighth embodiment, the first to third modifications of the above-described sixth embodiment can be applied as a connection form in which the contact electrode 38a is connected to the side surface portion of each of the two semiconductor portions 33 (33A₁ and 33A₂).

Note that, in FIG. 76, similarly to FIG. 40 of the above-described sixth embodiment, illustration of an upper layer than the sidewall spacers 41a, 41b, and 41c is omitted for convenience of description.

### <<Modification of Eighth Embodiment>>

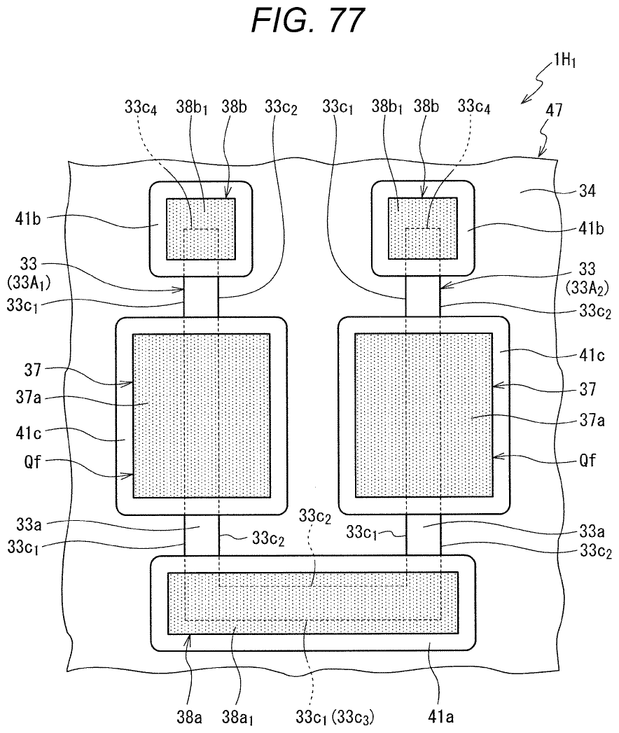

As illustrated in FIG. 77, one end sides of the two semiconductor portions in the longitudinal direction may be connected to each other. Also in this modification, since the contact electrode 38a is formed in the same layer as the gate electrode 37, the contact electrode 38a shared by the two semiconductor portions 33 (33A₁ and 33A₂) can be easily formed only by changing the shape of the mask when patterning the polycrystalline silicon film 37X as an electrode formation material.

Also in the semiconductor device 1H₁ according to the modification of the eighth embodiment, effects similar to those of the semiconductor device 1F according to the sixth embodiment described above can be obtained.

Note that, in FIG. 77, similarly to FIG. 40 of the above-described sixth embodiment, illustration of an upper layer than the sidewall spacers 41a, 41b, and 41c is omitted for convenience of description.

### Ninth Embodiment

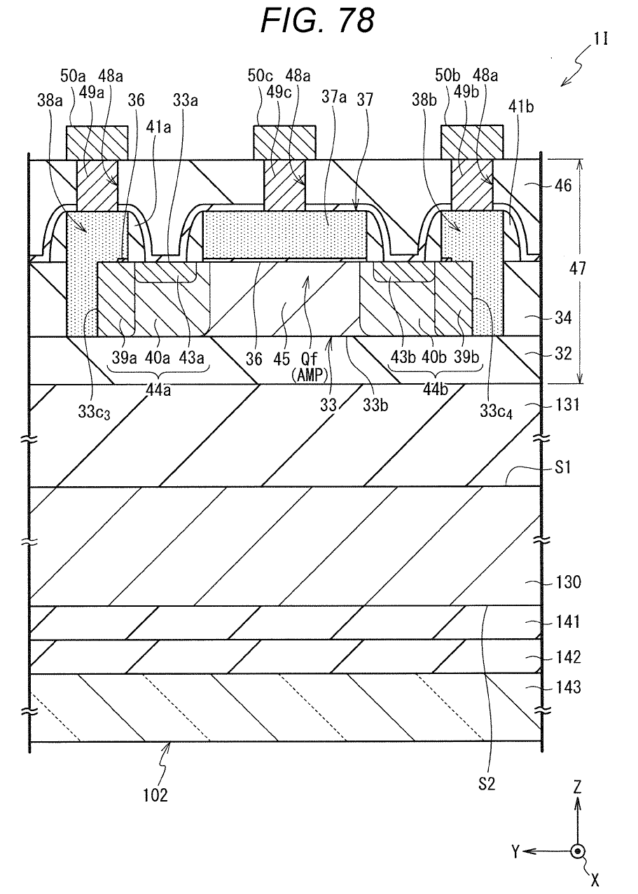

In a ninth embodiment, an example in which the present technology is applied to a solid-state imaging device called a back-illuminated CMOS image sensor as a light detection device included in a semiconductor device will be described with reference to FIG. 78.

As illustrated in FIG. 78, a solid-state imaging device 1I according to the ninth embodiment of the present technology basically has a configuration similar to that of the solid-state imaging device 1E according to the fifth embodiment described above, and the following configuration is different.

That is, as illustrated in FIG. 78, the solid-state imaging device 1I according to the ninth embodiment includes a field effect transistor Of and contact electrodes 38a and 38b instead of the field effect transistor Qa and the contact electrodes 17a and 17b illustrated in FIG. 39 of the fifth embodiment described above. Other configurations are substantially similar to those of the fifth embodiment described above. Hereinafter, it will be described with reference to FIG. 76 while referring to FIGS. 36 to 38 of the fifth embodiment described above.

In the ninth embodiment, each of the photoelectric conversion unit 124, the transfer transistor TR, and the charge holding region FD illustrated in FIG. 38 of the above-described fifth embodiment is provided in the semiconductor layer 130 illustrated in FIG. 78 although not illustrated in detail. Meanwhile, each of the pixel transistors (AMP, SEL, RST, and FDG) included in the pixel circuit 115 illustrated in FIG. 38 includes the field effect transistor Qf illustrated in FIG. 78. Then, in FIG. 78, an amplification transistor AMP including a field effect transistor Of is illustrated as an example.

### <<Main Effects of Ninth Embodiment>>

In the solid-state imaging device 1I according to the ninth embodiment, each of the pixel transistors (AMP, SEL, RST, and FDG) included in the pixel circuit 115 includes a field effect transistor Of provided in the semiconductor portion 33. Then, contact electrodes 38a and 38b are provided on both end portion sides in the longitudinal direction (Y direction) of the semiconductor portion 33 so as to overlap with the semiconductor portion 33. Similarly to the above-described sixth embodiment, the contact electrode 38a is connected to the upper surface portion 33a of the semiconductor portion 33, and is connected to each of the three side surface portions 3c₁, 3c₂, and 3c₃ as the side surface portion of the semiconductor portion 33. Furthermore, the contact electrode 38b is also connected to the upper surface portion 33a of the semiconductor portion 33 similarly to the above-described sixth embodiment, and is also connected to each of the three side surface portions 3c₁, 3c₂, and 3c₄ as the side surface portion of the semiconductor portion 33.

Therefore, according to the solid-state imaging device 1I according to the ninth embodiment, it is possible to improve the transconductance (gm) of each of the pixel transistors (AMP, SEL, RST, and FDG) included in the pixel circuit 115, similarly to the above-described sixth embodiment.

In addition, even when the width W₂ in the lateral direction (Y direction) of the semiconductor portion 33 and the widths W₁a and W₁b (diameter and width of thickness) of the contact electrodes 38a and 38b decrease with the miniaturization of the pixel transistors (AMP, SEL, RST, and FDG) included in the pixel circuit 115, an increase in contact resistance between the semiconductor portion 33 and the contact electrodes 38a and 38b can be suppressed, so that it is possible to suppress a decrease in transconductance (gm) while miniaturizing the pixel transistors (AMP, SEL, RST, and FDG).

Here, in the amplification transistor AMP, it is important to suppress deterioration of noise resistance such as 1/f noise or RTS noise as compared with a pixel transistor (SEL, RST, and FDG) functioning as a switching element. Therefore, the effectiveness is particularly high in a case where the present technology is applied to the connection between the semiconductor portion 33 provided with the amplification transistor AMP included in the pixel circuit 115 and the contact electrodes 38a and 38b.

Note that, in the ninth embodiment described above, the case where the connection form of the sixth embodiment described above is applied as the connection form for connecting the contact electrodes 38a and 38b to the semiconductor portion 33 has been described, but it is a matter of course that the connection forms of the first to third modifications of the sixth embodiment described above can be applied.

Furthermore, at least one of the pixel transistors (AMP, SEL, RST, or FDG) included in the pixel circuit 115 may be configured by the field effect transistor Of provided in the semiconductor portion 33.

### 10th Embodiment

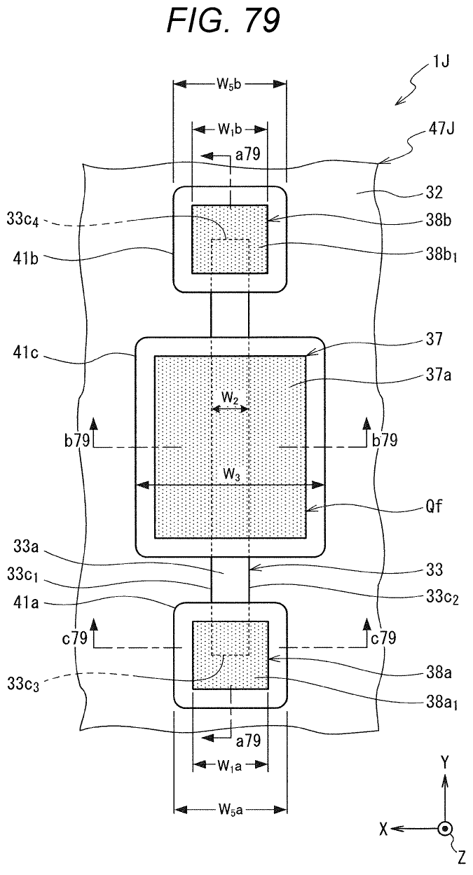

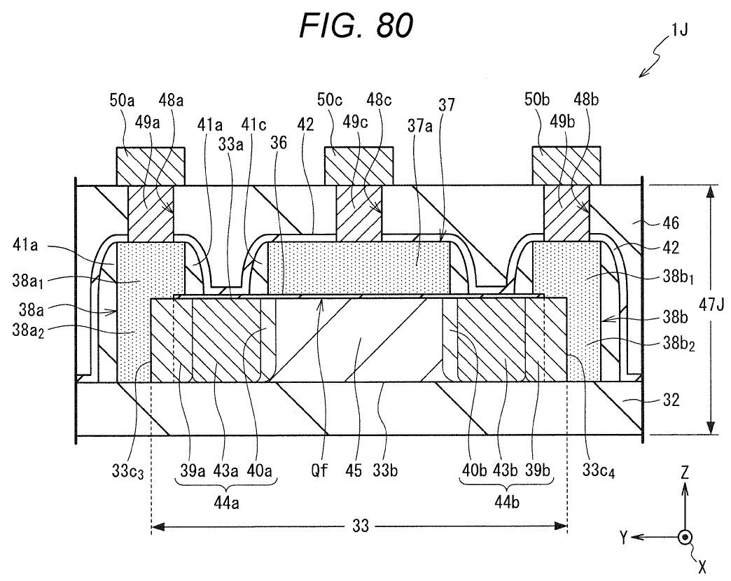

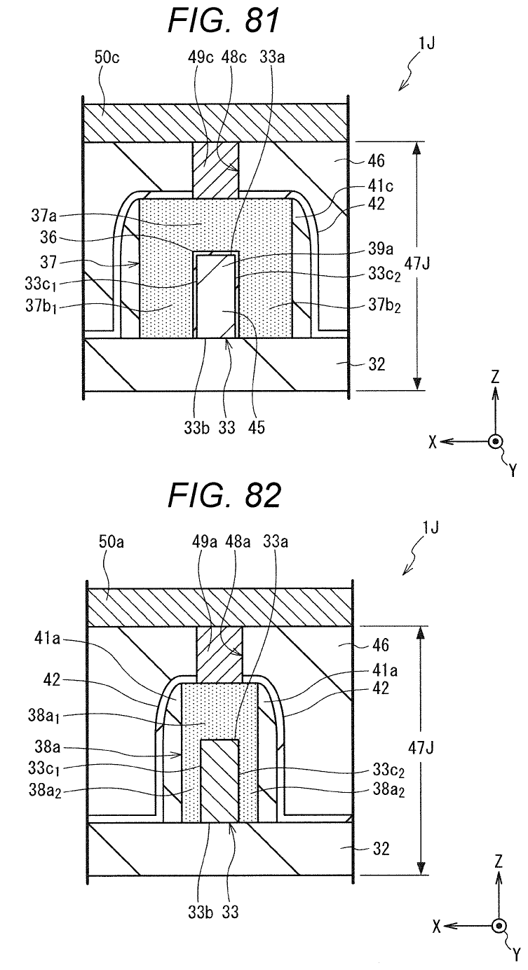

As illustrated in FIGS. 79 to 82, a semiconductor device 1J according to a 10th embodiment of the present technology basically has a configuration similar to that of the semiconductor device 1F according to the above-described sixth embodiment, and the following configuration is different.

That is, as illustrated in FIGS. 79 to 82, the semiconductor device 1J according to the 10th embodiment of the present technology includes an insulating layer 47J instead of the insulating layer 47 illustrated in FIG. 41 of the above-described sixth embodiment.

Specifically, the insulating layer 47 of the above-described sixth embodiment has a multilayer structure including a first insulating film (base insulating film) 32, a second insulating film (surrounding insulating film) 34, and a third insulating film (covering insulating film) 46.

Meanwhile, as illustrated in FIGS. 79 to 82, the insulating layer 47J of the 10th embodiment has a multilayer structure including the first insulating film 32 and the third insulating film 46 except for the second insulating film 34 (see FIG. 41). Then, the semiconductor portion 33 and the field effect transistor Qf are covered with the third insulating film 46.

In addition, in the semiconductor device 1J according to the 10th embodiment of the present technology, the shapes of the sidewall spacers 41a, 41b, and 41c are different from those of the sidewall spacers 41a, 41b, and 41c illustrated in FIGS. 40 to 43 of the above-described sixth embodiment.

Specifically, as illustrated in FIGS. 79 to 82, in the sidewall spacers 41a, 41b, and 41c of the 10th embodiment, the height along the thickness direction (Z direction) of the semiconductor portion 33 is different between the semiconductor portion 33 and the outside of the semiconductor portion 33, and the height on the outside of the semiconductor portion 33 is higher than the height on the semiconductor portion 33.

Furthermore, in the semiconductor device 1J according to the 10th embodiment of the present technology, the n-type semiconductor regions 43a and 43b are configured to have a depth reaching the lower surface portion 33b from the upper surface portion 33a side of the semiconductor portion 33. Other configurations are substantially similar to those of the sixth embodiment described above.

Note that, in the 10th embodiment, the term in the sixth embodiment is continuously referred to and the insulating film is referred to as the third insulating film 46 from the relationship with the above-described sixth embodiment, but the term is not limited to this term, and may be referred to as the second insulating film 46, or may be simply referred to as the insulating film 46.

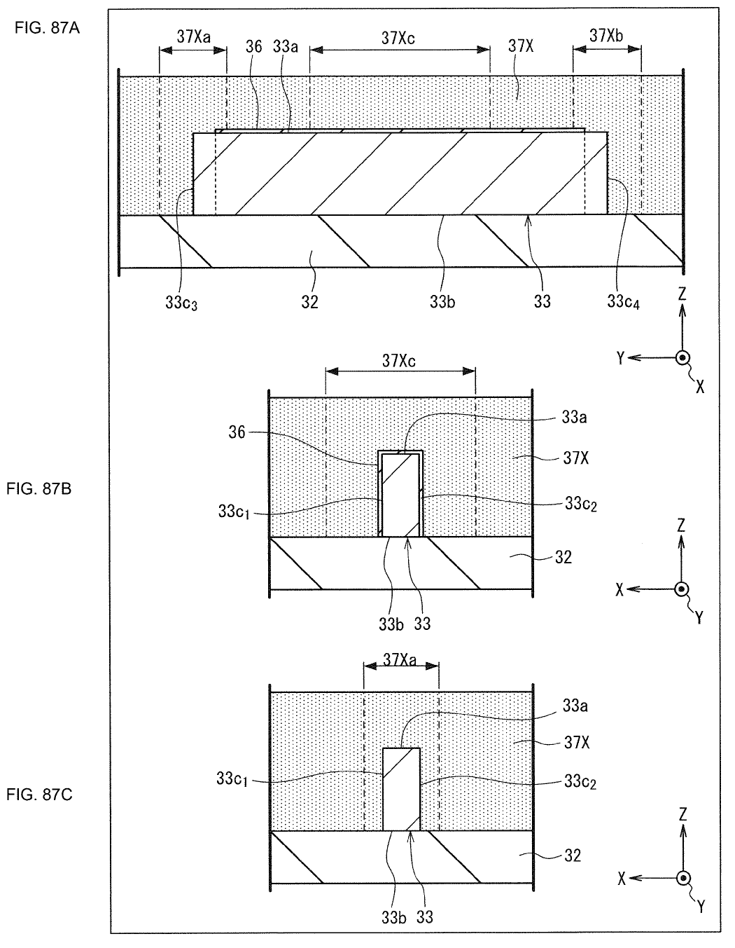

In addition, in FIGS. 87, 89, 91, and 92, contact electrode formation regions 37Xa and 37Xb and a gate electrode formation region 37Xc are illustrated in the polycrystalline silicon film 37X. The contact electrode formation regions 37Xa and 37Xb and the gate electrode formation region 37Xc become the contact electrodes 38a and 38b and the gate electrode 37 by patterning the polycrystalline silicon film 37X in a manufacturing method to be described later.

### <<Method for Manufacturing Semiconductor Device>>

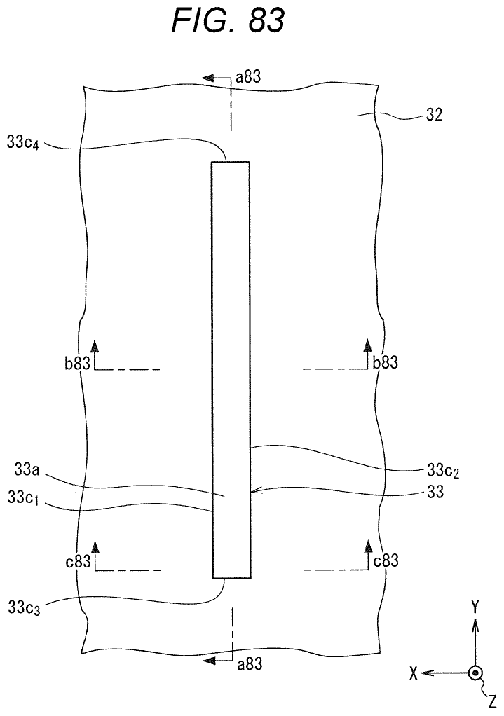

Next, a method for manufacturing the semiconductor device 1J according to the 10th embodiment will be described with reference to FIGS. 83 to 102.

Also in the 10th embodiment, similarly to the above-described sixth embodiment, the description will be made focusing on the formation of the field effect transistor Qf and the formation of the contact electrodes 38a and 38b included in the method for manufacturing the semiconductor device.

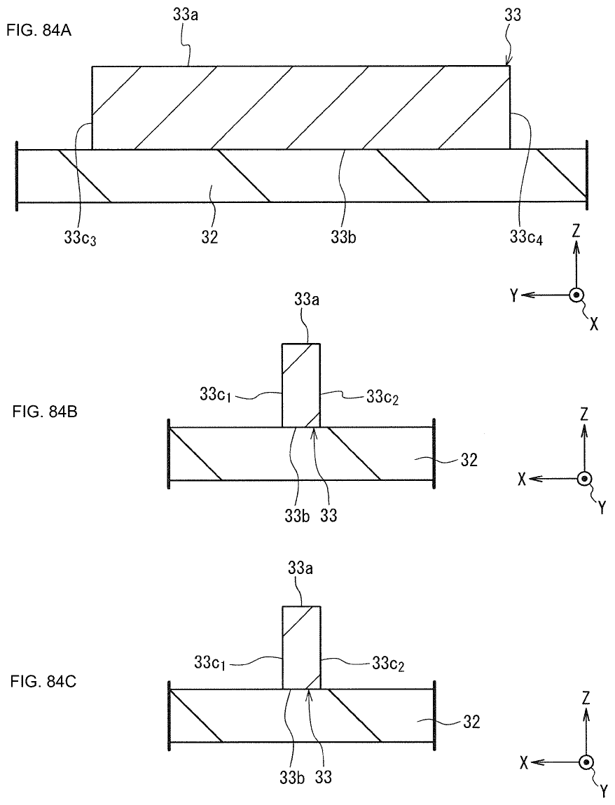

First, as illustrated in FIGS. 83 and 84 ((a), (b), and (c)), the island-shaped semiconductor portion 33 is formed on the first insulating film 32. The island-shaped semiconductor portion 33 is formed by a method similar to that of the above-described sixth embodiment. That is, the semiconductor portion 33 is formed in, for example, a rectangular parallelepiped shape having an upper surface portion 33a, a lower surface portion (bottom surface portion) 33b, and four side surface portions 33c₁, 33c₂, 33c₃, and 33c₄. The semiconductor portion 33 is supported by the first insulating film 32.

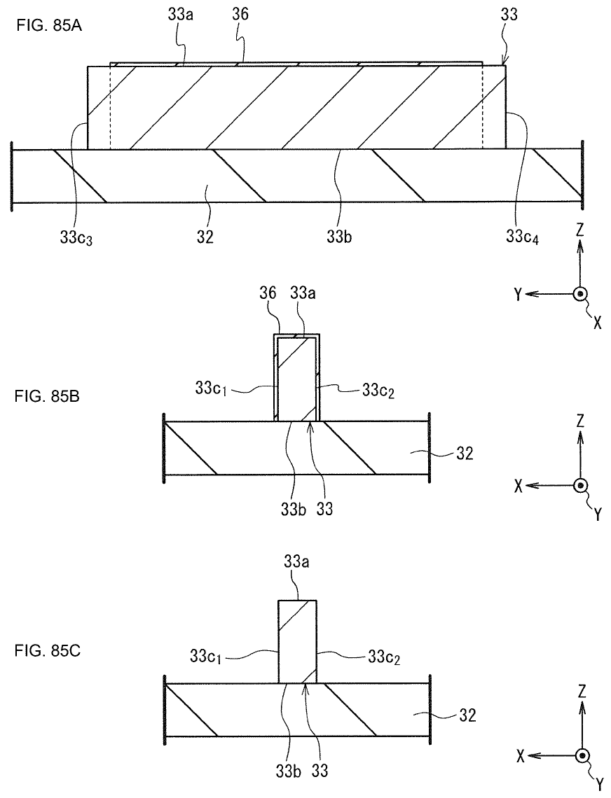

Next, similarly to the above-described sixth embodiment, the gate insulating film 36 is formed on the semiconductor portion 33, and then the gate insulating film 36 is patterned to selectively remove the gate insulating film 36 on one end portion side (side surface portion 33c₃ side) and the other end portion side (side surface portion 33c₄ side) in the longitudinal direction (Y direction) of the semiconductor portion 33 as illustrated in FIG. 85 ((a), (b), and (c)), similarly to the above-described sixth embodiment, selectively expose the upper surface portion 33a and the three side surface portions 33c₁/33c₂, and 33c₃ on one end portion side in the longitudinal direction of the semiconductor portion 33, and selectively expose the upper surface portion 33a and the three side surface portions 33c₁, 33c₂, and 33c₄ on the other end portion side in the longitudinal direction of the semiconductor portion 33. Patterning of the gate insulating film 36 can be performed using a known photolithography technique, dry etching technique, or the like.

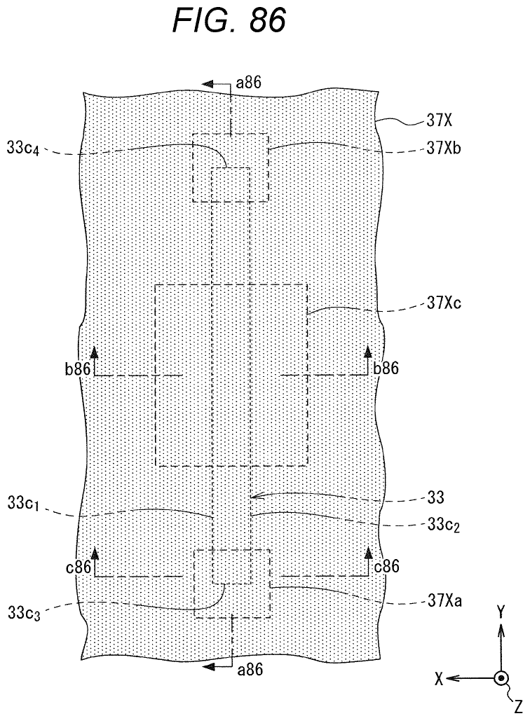

Next, as illustrated in FIGS. 86 and 87 ((a), (b), and (c)), a polycrystalline silicon film (non-doped polysilicon film) 37X into which, for example, impurities for reducing the resistance value are not introduced is formed as an electrode formation material on the entire surface of the first insulating film 32. The polycrystalline silicon film 37X is formed on the first insulating film 32 by, for example, a CVD method so as to cover the semiconductor portion 33.

Here, referring to FIG. 51D and FIG. 51E of the above-described sixth embodiment, also in the 10th embodiment, an extremely thin natural oxide film 33X is formed in a gate insulating film removal region (upper surface portion 33a and side surface portions 33c₁ to 33c₄) of the semiconductor portion 33 by movement between steps after selectively removing the gate insulating film 36 of the semiconductor portion 33 or the like. Therefore, also in the 10th embodiment, in the gate insulating film removal region on one end portion side in the longitudinal direction (Y direction) of the semiconductor portion 33, the extremely thin natural oxide film 33X having a film thickness of, for example, about 2 nm remains at the interface portion between the polycrystalline silicon film 37X and the upper surface portion 33a and the three side surface portions 33c₁, 33c₂, and 33c₃ on one end portion side in the longitudinal direction of the semiconductor portion 33.

Furthermore, in the gate insulating film removal region on the other end portion side in the longitudinal direction (Y direction) of the semiconductor portion 33, the natural oxide film 33X remains at the interface portion between the polycrystalline silicon film 37X and the upper surface portion 33a and the three side surface portions 33c₁, 33c₂, and 33c₄ on the other end portion side in the longitudinal direction of the semiconductor portion 33.

These natural oxide films 33X spread in a planar shape (film shape) over the upper surface portion 33a of the semiconductor portion 33 and the three side surface portions 33c₁, 33c₂, and 33c₃ (or 33c₄).

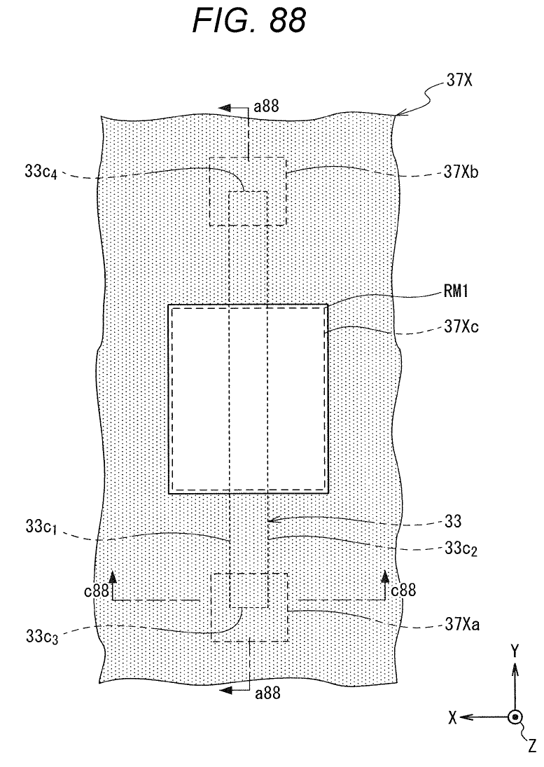

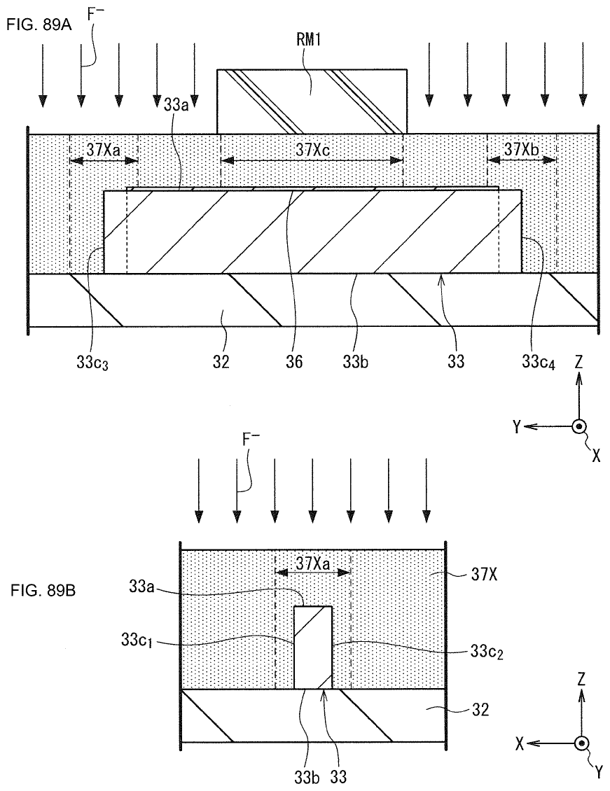

Next, similarly to the above-described sixth embodiment, a mask RM1 as an impurity introduction mask is selectively formed on the gate electrode formation region of the polycrystalline silicon film 37X, and thereafter, using the mask RM1 as an impurity introduction mask, for example, fluorine ions (F⁻) are implanted as impurities into the polycrystalline silicon film 37X outside the mask RM1 as illustrated in FIGS. 88 and 89 ((a) and (b)). This implantation of fluorine ions is performed under conditions similar to those of the sixth embodiment described above.

In this step, the gate electrode formation region 37Xc of the polycrystalline silicon film 37X is covered with the mask RM1, and implantation of fluorine ions (F⁻) into the gate electrode formation region 37Xc is blocked by the mask RM1. Meanwhile, the contact electrode formation regions 37Xa and 37Xb of the polycrystalline silicon film 37X are not covered with the mask RM1, and fluorine ions (F⁻) are implanted (introduced) into the contact electrode formation regions 37Xa and 37Xb.

Next, after the mask RM1 is removed, a heat treatment for activating fluorine ions (F⁻) implanted into the polycrystalline silicon film 37X is performed.

In this step, with reference to FIGS. 51D, 51E, 54A, and 54B of the above-described sixth embodiment, fluorine ions (F⁻) diffuse into the polycrystalline silicon film 37X, and fluorine ions (F⁻) diffuse into the natural oxide film 33X illustrated in FIGS. 51D and 51E, similarly to the above-described 10th embodiment. Then, the natural oxide film 33X containing fluorine ions (F⁻) is fluidized by heat treatment, and as illustrated in FIGS. 54A and 54B, it is changed to a granular (spherical) oxide 33Y at an interface portion between the semiconductor portion 33 (the upper surface portion 33a and the side surface portions 33c₁, 33c₂, 33c₃, and 33c₄) and the polycrystalline silicon film 37X.

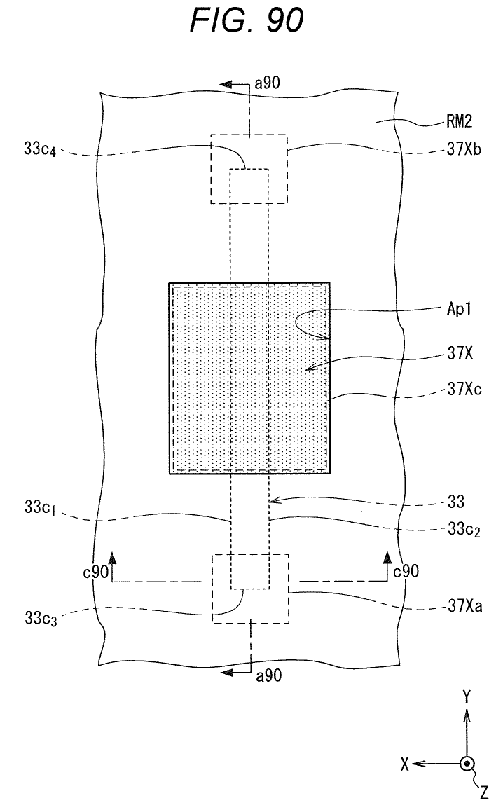

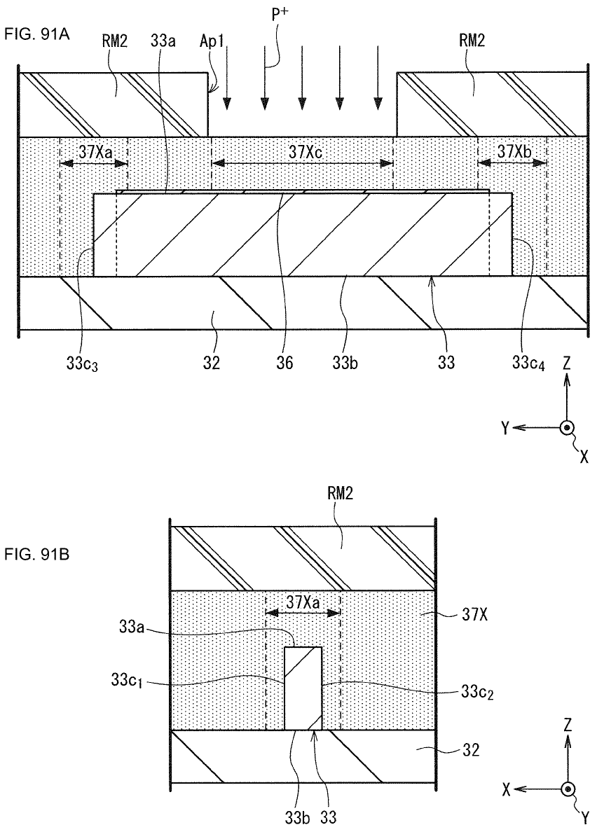

Next, as illustrated in FIGS. 90 and 91 ((a) and (b)), a mask RM2 as an impurity introduction mask having an opening Ap1 in the gate electrode formation region 37Xc of the polycrystalline silicon film 37X is formed on the polycrystalline silicon film 37X. Then, using the mask RM2 as an impurity introduction mask, as illustrated in FIG. 91 ((a) and (b)), for example, phosphorus ions (P⁺) are selectively implanted as n-type impurities into the gate electrode formation region 37Xc of the polycrystalline silicon film 37X through the opening Ap1 of the mask RM2. The implantation of phosphorus ions (P⁺) is performed under conditions similar to those of the sixth embodiment described above. Arsenic ions (As⁺) may be used as the n-type impurity.

In this step, the contact electrode formation regions 37Xa and 37Xb of the polycrystalline silicon film 37X are covered with the mask RM2, and introduction of phosphorus ions (P⁺) into the contact electrode formation regions 37Xa and 37Xb is blocked by the mask RM2. Meanwhile, phosphorus ions (P⁺) are selectively implanted (introduced) into the gate electrode formation region 37Xc of the polycrystalline silicon film 37X.

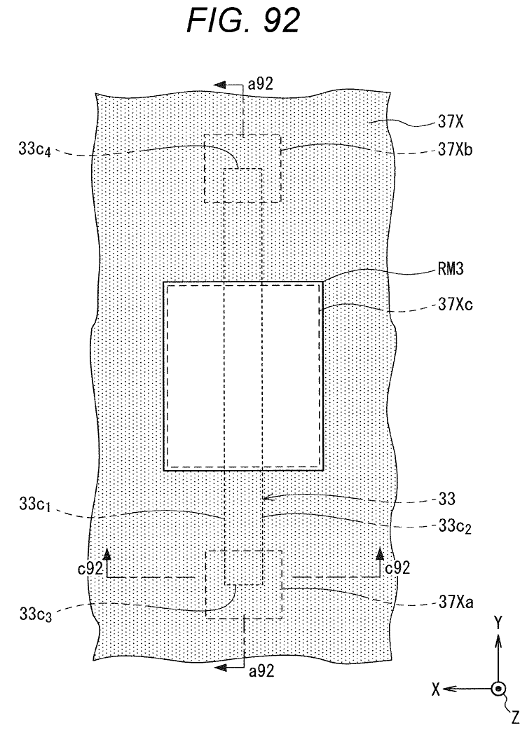

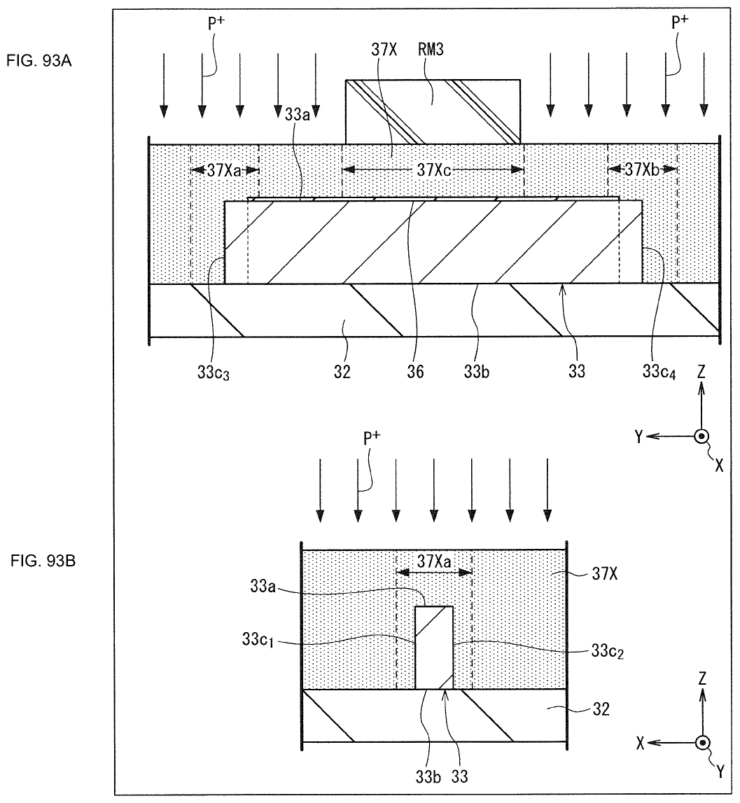

Next, after the mask RM2 is removed, as illustrated in FIGS. 92 and 93 ((a) and (b)), a mask RM3 is formed as an impurity introduction mask that selectively covers the gate electrode formation region 37Xc of the polycrystalline silicon film 37X. Then, as illustrated in FIGS. 92 and 93 ((a) and (b)), the mask RM3 is used as an impurity introduction mask, and for example, phosphorus ions are implanted as n-type impurities into the polycrystalline silicon film 37X outside the mask RM3.

This implantation of phosphorus ions (P⁺) is for reducing the resistance value of the contact electrode formation region of the polycrystalline silicon film 37X, and for forming n-type semiconductor regions 39a and 39b described later on both end portion sides in the longitudinal direction (Y direction) of the semiconductor portion 33. The implantation of phosphorus ions (P⁺) is performed under conditions similar to those of the sixth embodiment described above. Arsenic ions (As⁺) may be used as the n-type impurity.

In this step, the contact electrode formation regions 37Xa and 37Xb of the polycrystalline silicon film 37X are not covered with the mask RM3, and phosphorus ions (P⁺) are implanted (introduced) into the contact electrode formation regions 37Xa and 37Xb. Meanwhile, the gate electrode formation region 37Xc of the polycrystalline silicon film 37X is covered with the mask RM3, and implantation (introduction) of phosphorus ions (P⁺) into the gate electrode formation region 37Xc is blocked by the mask RM3.

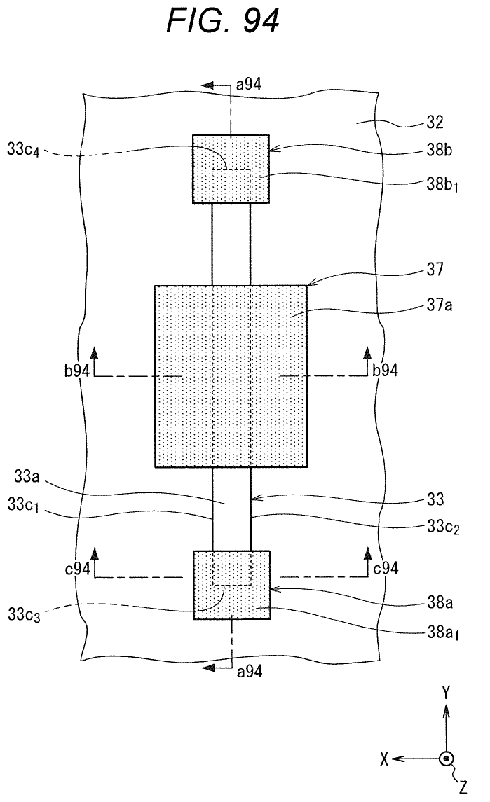

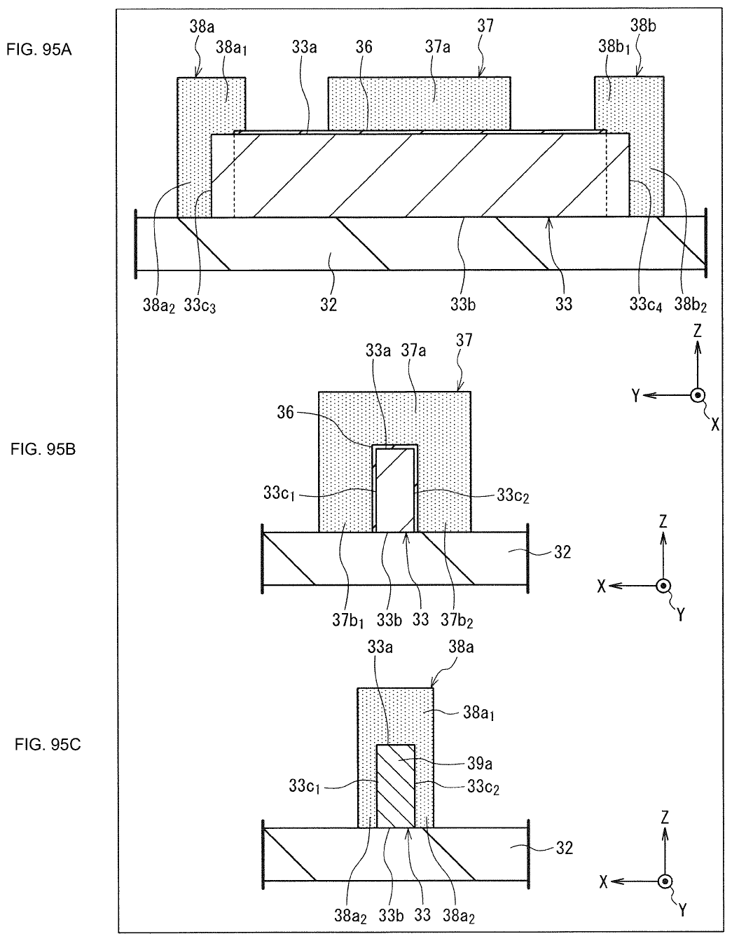

Next, the polycrystalline silicon film 37X is patterned to form the gate electrode 37 including the gate electrode formation region 37Xc of the polycrystalline silicon film 37X as illustrated in FIGS. 94 and 95 ((a), (b), and (c)), and form the contact electrode 38a including the contact electrode formation region 37Xa of the polycrystalline silicon film 37X and the contact electrode 38b including the contact electrode formation region 37Xb of the polycrystalline silicon film 37X. That is, the contact electrodes 38a and 38b are constituted by the same layer (the same step and the same material) as the gate electrode 37. The patterning of the polycrystalline silicon film 37X can be performed using a known photolithography technique, dry etching technique, and the like.

In this step, the gate electrode 37 is formed to face the upper surface portion 33a of the semiconductor portion 33 and each of the two side surface portions 33c₁ and 33c₂ with the gate insulating film 36 interposed therebetween. Specifically, the gate electrode 37 includes a head portion (first portion) 37a provided on the upper surface portion 33a side of the semiconductor portion 33 with the gate insulating film 36 interposed therebetween, and two leg portions (second portions) 37b₁ and 37b₂ integrated with the head portion 37a and provided outside each of the two side surface portions 3c₁ and 3c₂ located on opposite sides in the lateral direction (X direction) of the semiconductor portion 33 with the gate insulating film 36 interposed therebetween. The head portion 37a protrudes upward from the semiconductor portion 33. The two leg portions 37b₁ and 37b₂ are separately provided outside the semiconductor portion 33 so as to sandwich the semiconductor portion 33.

In addition, in this step, the contact electrode 38a is formed to overlap the semiconductor portion 33 in plan view on one side surface portion 33c₃ side of the two side surface portions 33c₃ and 33c₄ located in the longitudinal direction (Y direction) of the semiconductor portion 33. Then, the contact electrode 38a includes a head portion 38a₁ protruding upward from the semiconductor portion 33, and a leg portion 38a₂ integrated with the head portion 38a₁ and provided so as to surround one end portion side (side surface portion 33c₃ side) in the longitudinal direction of the semiconductor portion 33. Then, in the contact electrode 38a, on one end portion side (side surface portion 33c₃ side) in the longitudinal direction of the semiconductor portion 33, the head portion 38a₁ is connected to the upper surface portion 33a of the semiconductor portion 33, and the leg portion 38a₂ is connected to the three side surface portions 33c₁, 33c₂, and 33c₃ of the semiconductor portion 33.

Furthermore, in this step, the contact electrode 38b is formed to overlap the semiconductor portion 33 in plan view on the side of the other side surface portion 33c₄ of the two side surface portions 33c₃ and 33c₄ located in the longitudinal direction (Y direction) of the semiconductor portion 33. Then, the contact electrode 38b has a head portion 38b₁ protruding upward from the semiconductor portion 33 and a leg portion 38b₂ integrated with the head portion 38b₁ and provided on the other end portion side (side surface portion 33c₄ side) in the longitudinal direction of the semiconductor portion 33. Then, in the contact electrode 38b, on the other end portion side (side surface portion 33c₄ side) in the longitudinal direction of the semiconductor portion 33, the head portion 38b₁ is connected to the upper surface portion 33a of the semiconductor portion 33, and the leg portion 38b₂ is connected to the three side surface portions 33c₁, 33c₂, and 33c₄ of the semiconductor portion 33.

Further, in this step, the gate insulating film 36 selectively remains (is interposed) between the gate electrode 37 side of the contact electrode 38a and the semiconductor portion 33 over the upper surface portion 33a and the two side surface portions 33c₁ and 33c₂ of the semiconductor portion 33, and the gate insulating film 36 selectively remains (is interposed) between the gate electrode 37 side of the contact electrode 38b and the semiconductor portion 33 over the upper surface portion 33a and the two side surface portions 33c₁ and 33c₂ of the semiconductor portion 33.

Then, in the 10th embodiment, unlike the above-described sixth embodiment, the gate insulating film 36 remains also in the semiconductor portion 33 between the gate electrode 37 and the contact electrodes 38a and 38b. That is, in the 10th embodiment, even after the gate electrode 37 and the two contact electrodes 38a and 38b are formed by patterning the polycrystalline silicon film 37X, the upper surface portion 33a of the semiconductor portion 33 and the two side surface portions 33c₁ and 33c₂ are covered with the gate insulating film 36 over the two contact electrodes 38a and 38b.

Note that, in this step, the gate insulating film 36 in the semiconductor portion 33 between the gate electrode 37 and the contact electrode 38a and the semiconductor portion 33 between the gate electrode 37 and the contact electrode 38b may be selectively removed by over-etching during patterning of the polycrystalline silicon film 33X in a case where the film thickness of the gate insulating film 36 is thin.

Next, after the mask RM3 is removed, a heat treatment is performed to activate the impurity (phosphorus ion (P⁺)) implanted into the gate electrode 37 to electrically conduct the gate electrode 37 (reduce the resistance value of the gate electrode 37), and activate the impurity (phosphorus ion (P⁺)) implanted into each of the contact electrodes 38a and 38b to electrically conduct the contact electrodes 38a and 38b (reduce the resistance value of each of the contact electrodes 38a and 38b).

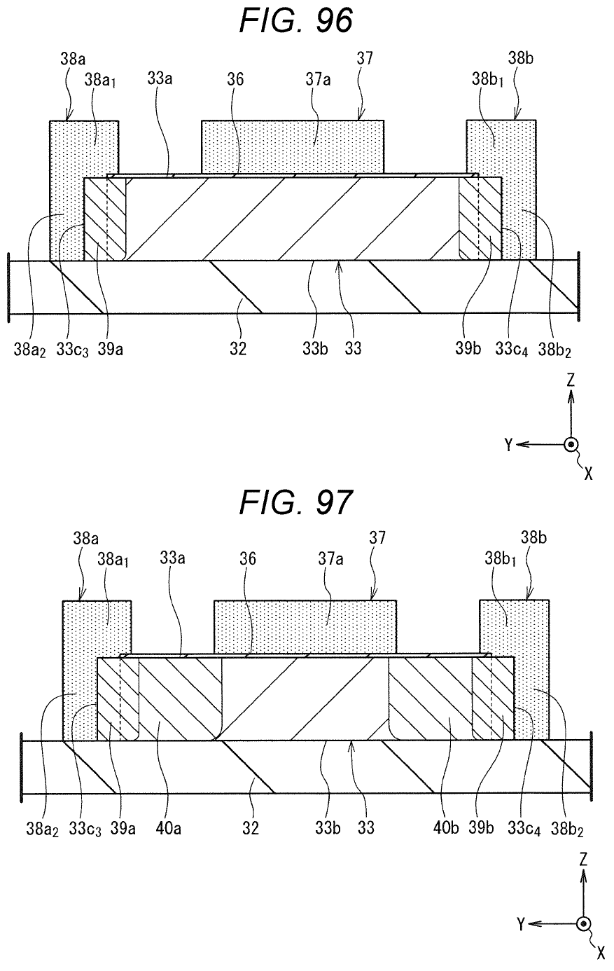

In this step, impurities (phosphorus ions (P⁺)) of each of the contact electrodes 38a and 38b are diffused (leaked) to both end portions in the longitudinal direction (Y direction) of the semiconductor portion 33, and as illustrated in FIG. 96, the n-type semiconductor region 39a is formed on one end portion side (side surface portion 33c₃ side) in the longitudinal direction (Y direction) of the semiconductor portion 33, and the n-type semiconductor region 39b is formed on the other end portion side (side surface portion 33c₄ side).

The n-type semiconductor region 39a is three-dimensionally (three-dimensionally) formed from the upper surface portion 33a to the lower surface portion 33b along the three side surface portions 33c₁, 33c₂, and 33c₃ of the semiconductor portion 33. In addition, the n-type semiconductor region 39b is also three-dimensionally (three-dimensionally) formed from the upper surface portion 33a to the lower surface portion 33b along the three side surface portions 33c₁, 33c₂, and 33c₄ of the semiconductor portion 33. Each of the n-type semiconductor regions 39a and 39b is formed in the semiconductor portion 33 at a depth reaching the first insulating film 32 on the lower surface portion 33b side from the upper surface portion 33a side of the semiconductor portion 33.

Also in the heat treatment in this step, a phenomenon in which the natural oxide film 33X (see FIGS. 51D and 51E) is fluidized and changed into the granular oxide 33Y (see FIGS. 54A and 54B) can be caused.

Next, as illustrated in FIG. 97, a pair of n-type semiconductor regions 40a and 40b having an impurity concentration lower than that of the n-type semiconductor regions 39a and 39b is formed in each of the semiconductor portions 33 on both sides of the gate electrode 37 in the gate length direction (Y direction). Each of the pair of n-type semiconductor regions 40a and 40b functions as an extension region.

Each of the pair of n-type semiconductor regions 40a and 40b can be formed by using the gate electrode 37 and the contact electrodes 38a and 38b as an impurity introduction mask, implanting, for example, arsenic ions (As⁺) as n-type impurities into each of the semiconductor portions 33 on both sides of the gate electrode 37 in the gate length direction (Y direction), and then subjecting the semiconductor portions to a heat treatment for activating the impurities. The implantation of arsenic ions (As⁺) is performed, for example, under conditions where the dose amount is about 1×10¹⁴/cm² and the acceleration energy is about 80 to 150 keV, which is different from the above-described sixth embodiment. Phosphorus ions (P⁺) may be used as the n-type impurity.

In this step, each of the pair of n-type semiconductor regions 40a and 40b is formed on each of the semiconductor portions 33 on both sides of the gate electrode 37 in the gate length direction (Y direction) so as to be aligned with the head portion 37a of the gate electrode 37.

In addition, one semiconductor region 40a of the pair of n-type semiconductor regions 40a and 40b is formed in the semiconductor portion 33 in contact with the n-type semiconductor region 39a, and the other semiconductor region 40b is formed in the semiconductor portion 33 in contact with the n-type semiconductor region 39b.

In addition, each of the n-type semiconductor regions 40a and 40b is formed in the semiconductor portion 33 at a depth reaching the first insulating film 32 on the lower surface portion 33b side from the upper surface portion 33a side of the semiconductor portion 33.

Furthermore, in the heat treatment in this step, a phenomenon in which the natural oxide film 33X (see FIGS. 51D and 51E) is fluidized and changed into the granular oxide 33Y (see FIGS. 54A and 54B) can be caused.

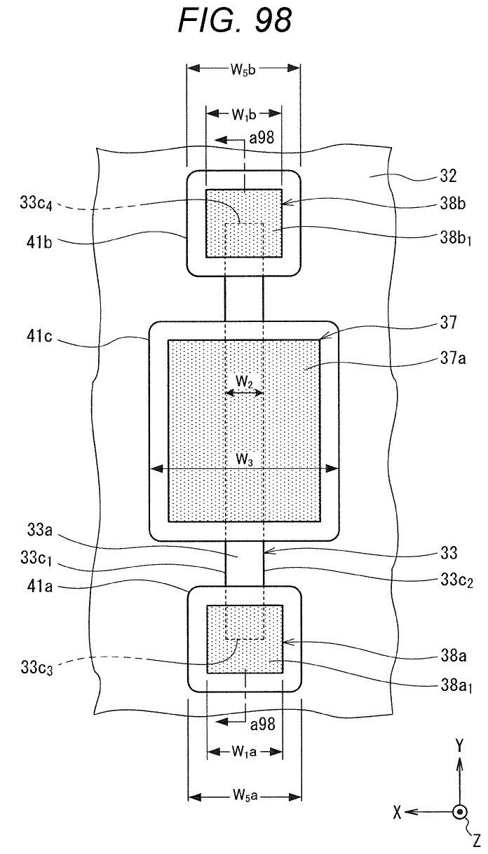

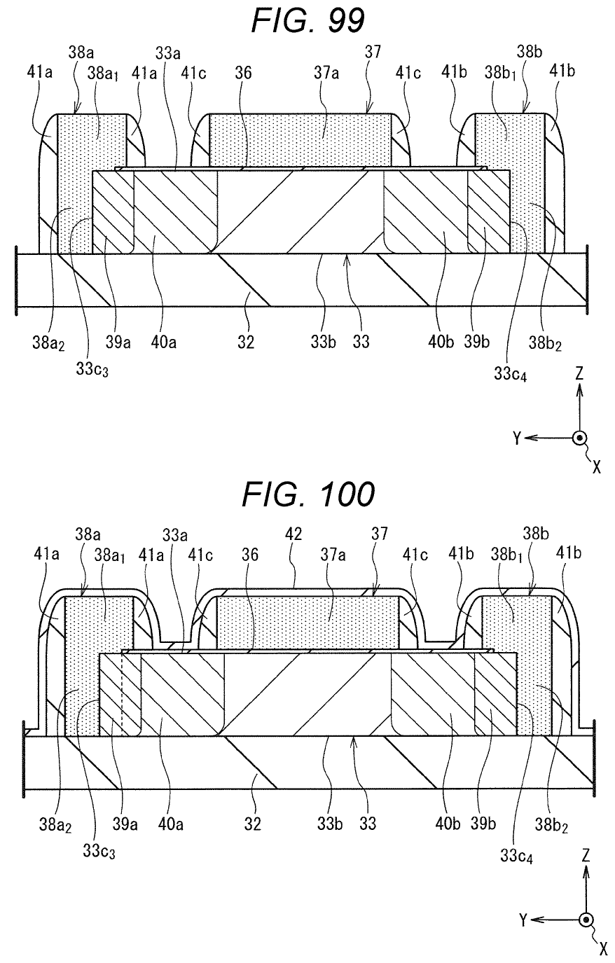

Next, as illustrated in FIGS. 98 and 99, the sidewall spacer 41c is formed on the sidewall of the gate electrode 37, and the sidewall spacers 41a and 41b are formed on the sidewalls of the contact electrodes 38a and 38b, respectively.

Each of the sidewall spacers 41a, 41b, and 41c can be formed by forming, for example, a silicon nitride film as an insulating film having selectivity with respect to the silicon oxide film on the entire surface of the first insulating film 32 by a CVD method so as to cover the contact electrodes 38a and 38b and the gate electrode 37, and then applying anisotropic dry etching such as RIE to the silicon nitride film.

The sidewall spacer 41a is formed so as to surround the contact electrode 38a, and is formed so as to be aligned with the contact electrode 38a. The sidewall spacer 41b is formed so as to surround the contact electrode 38b, and is formed so as to be aligned with the contact electrode 38b. The sidewall spacer 41c is formed so as to surround the gate electrode 37, and is formed so as to be aligned with the gate electrode 37.

Each of the sidewall spacers 41a, 41b, and 41c is formed on the first insulating film 32 and the semiconductor portion 33 so as to cross the semiconductor portion 33. The sidewall spacer 41a is formed adjacent to the head portion 38a₁ of the contact electrode 38a on the semiconductor portion 33, and is formed adjacent to the head portion 38a₁ and the leg portion 38a₂ of the contact electrode 38a outside the semiconductor portion 33. The sidewall spacer 41b is formed adjacent to the head portion 38b₁ of the contact electrode 38b on the semiconductor portion 33, and is formed adjacent to the head portion 38b₁ and the leg portion 38b₂ of the contact electrode 38b outside the semiconductor portion 33. The sidewall spacer 41c is formed adjacent to the head portion 37a of the gate electrode 37 on the semiconductor portion 33, and is formed adjacent to the head portion 37a and the leg portions 37b₁ and 37b₂ of the gate electrode 37 outside the semiconductor portion 33. That is, in each of the sidewall spacers 41a, 41b, and 41c, the length along the thickness direction (Z direction) of the semiconductor portion 33 differs between the portion overlapping the semiconductor portion 33 in plan view and the portion not overlapping the semiconductor portion 33, and the length of the portion not overlapping the semiconductor portion 33 is longer than the length of the portion overlapping the semiconductor portion 33.

Next, as illustrated in FIG. 100, a buffer insulating film 42 is formed. The buffer insulating film 42 is formed so as to cover each of the head portion 37a of the gate electrode 37, the head portion 38a₁ and 38b₁ of each of the two contact electrodes 38a and 38b, and the sidewall spacers 41a, 41b, and 41c, and to cover the semiconductor portion 33 between the head portion 37a of the gate electrode 37 and the contact electrodes 38a and 38b. The buffer insulating film 42 is used as a buffer film at the time of ion implantation of impurities in a step of forming n-type semiconductor regions 43a and 43b to be described later. As the buffer insulating film 42, for example, a silicon oxide film can be used.

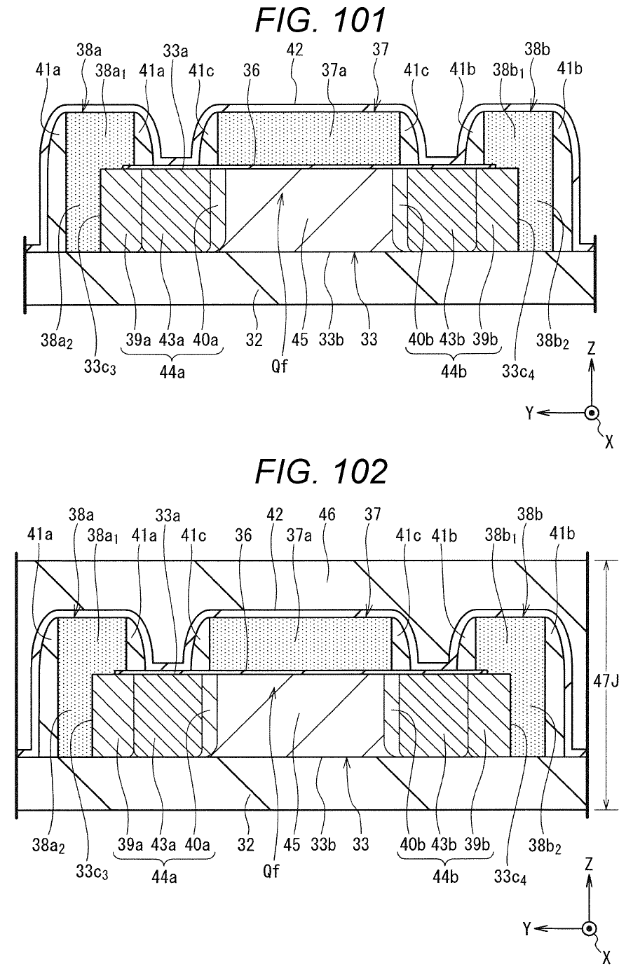

Next, as illustrated in FIG. 101, a pair of n-type semiconductor regions 43a and 43b having a higher impurity concentration than the n-type semiconductor regions 39a and 39b is formed in each of the semiconductor portions 33 on both sides of the gate electrode 37 in the gate length direction (Y direction).

Each of the pair of n-type semiconductor regions 43a and 43b can be formed by using the gate electrode 37, the contact electrodes 38a and 38b, and the sidewall spacers 41a, 41b, and 41c as an impurity introduction mask, implanting, for example, phosphorus ions (P⁺) as an n-type impurity through the buffer insulating film 42 into the semiconductor portion 33 between the sidewall spacer 41c of the sidewall of the gate electrode 37 and the sidewall spacer 41a of the sidewall of the contact electrode 38a and the semiconductor portion 33 between the sidewall spacer 41c of the sidewall of the gate electrode 37 and the sidewall spacer 41b of the contact electrode 38b, respectively, and then subjecting the semiconductor portion to a heat treatment for activating the impurity.

The implantation of phosphorus ions (P⁺) is performed under conditions different from those of the sixth embodiment described above. For example, the implantation of phosphorus ions (P⁺) is performed under conditions where the dose amount is about 8×10¹⁵/cm² and the acceleration energy is about 10 keV. Arsenic ions (As⁺) may be used as the n-type impurity.

In this step, since phosphorus ions (P⁺) are implanted into the semiconductor portion 33 through the buffer insulating film 42, damage to the semiconductor portion 33 due to ion implantation can be suppressed.

Furthermore, in this step, the n-type semiconductor region 43a is formed so as to be aligned with the sidewall spacer 41c of the sidewall of the gate electrode 37 and the sidewall spacer 41a of the sidewall of the contact electrode 38a. Furthermore, the n-type semiconductor region 43b is formed so as to be aligned with the sidewall spacer 41c of the sidewall of the gate electrode 37 and the sidewall spacer 41b of the sidewall of the contact electrode 38b.

In addition, in this step, unlike the above-described sixth embodiment, the n-type semiconductor regions 43a and 43b extend from the upper surface side to the lower surface side of the semiconductor portion 33, and are formed at a depth reaching the first insulating film 32.

Furthermore, in this step, the main electrode region 44a including the n-type semiconductor region 39a, the n-type semiconductor region 40a, and the n-type semiconductor region 43a is formed, and the main electrode region 44b including the n-type semiconductor region 39b, the n-type semiconductor region 40b, and the n-type semiconductor region 43b is formed.

Furthermore, in this step, the channel formation portion 45 is formed in the semiconductor portion 33 between the pair of main electrode regions 44a and 44b.

Furthermore, in this step, the field effect transistor Qf including the gate insulating film 36, the gate electrode 37, the pair of main electrode regions 44a and 44b, the channel formation portion 45, and the like is formed in the semiconductor portion 33.

Furthermore, in the heat treatment in this step, a phenomenon in which the natural oxide film 33X (see FIGS. 51D and 51E) is fluidized and changed into the granular oxide 33Y (see FIGS. 54A and 54B) can be caused.

Next, as illustrated in FIG. 102, a third insulating film 46 (second insulating film 46 or insulating film 46) is formed on the entire surface of the buffer insulating film 42 so as to cover the semiconductor portion 33, the gate electrode 37, and the contact electrodes 38a and 38b. The third insulating film 46 can be formed by forming, for example, a silicon oxide film as an insulating film on the entire surface of the buffer insulating film 42 including the gate electrode 37 and the head portions 37a, 38a₁, and 38b₁ of the contact electrodes 38a and 38b, and then planarizing the surface of the silicon oxide film by a CMP method or the like.

In this step, the insulating layer 47J including the first insulating film 32, the buffer insulating film 42, and the third insulating film 46 and including the semiconductor portion 33 and the field effect transistor Qf is formed.

Next, steps similar to those of the above-described sixth embodiment are performed to form the dug portions 48a, 48b, and 48c, the contact electrodes 49a, 49b, and 49c, and the wirings 50a, 50b, and 50c, thereby obtaining the states illustrated in FIGS. 79 to 82.

Note that, in a case where the gate insulating film 36 remains in the semiconductor portion 33 between the gate electrode 37 and the contact electrodes 38a and 38b as in the 10th embodiment, the buffer insulating film 42 may be omitted. In this case, the insulating layer 47J does not include the buffer insulating film 42.

In addition, in the manufacturing method of the 10th embodiment, fluorine ions (F⁻) for promoting the change from the natural oxide film 33X to the granular oxide 33Y are implanted into the polycrystalline silicon film 37X, but in a case where introduction of impurities to such an extent that the natural oxide film 33X is fluidized by heat treatment is secured, the implantation of the fluorine ions (F⁻) may be omitted.

In addition, in the manufacturing method of the 10th embodiment, the heat treatment for activating the impurities of the n-type semiconductor regions 40a and 40b and the heat treatment for activating the impurities of the n-type semiconductor regions 43a and 43b are performed in separate steps, but the heat treatment for activating the impurities of the n-type semiconductor regions 40a and 40b may be performed in the same step as the heat treatment for activating the impurities of the n-type semiconductor regions 43a and 43b.

### <<Main Effects of 10th Embodiment>>

Similarly to the semiconductor device 1F according to the above-described sixth embodiment, the semiconductor device 1J according to the 10th embodiment includes contact electrodes 38a and 38b provided to overlap the semiconductor portions 33 on both sides in the gate length direction (Y direction) of the gate electrode 37 in plan view. Then, the contact electrode 38a is connected to each of the upper surface portion 33a of the semiconductor portion 33 and the three side surface portions 33c₁, 33c₂, and 33c₃ on one end portion side in the longitudinal direction (Y direction) of the semiconductor portion 33. Similarly, the contact electrode 38b is also connected to each of the upper surface portion 33a of the semiconductor portion 33 and the three side surface portions 33c₁, 33c₂, and 33c₄ on the other end portion side in the longitudinal direction (Y direction) of the semiconductor portion 33.

Therefore, effects similar to those of the semiconductor device 1F according to the above-described sixth embodiment can be obtained also in the semiconductor device 1J according to the 10th embodiment.

Furthermore, in the method for manufacturing the semiconductor device 1J according to the 10th embodiment, unlike the method for manufacturing the semiconductor device 1F according to the sixth embodiment described above, the step of forming the second insulating film 34 and the step of forming the dug portions 35c₁, 35c₂, 35a, and 35b in the second insulating film 34 are omitted. Therefore, according to the method for manufacturing the semiconductor device 1J according to the 10th embodiment, the number of manufacturing steps can be reduced as compared with the method for manufacturing the semiconductor device 1F according to the above-described sixth embodiment, and the transconductance (gm) of the field effect transistor Qf can be improved at low cost.

In addition, it is possible to eliminate damage in the process of the semiconductor portion 33 caused by etching when the dug portions 35c₁, 35c₂, 35a, and 35b are formed in the second insulating film 34, and thus, it is possible to suppress variations in characteristics of the field effect transistor Qf and to manufacture the field effect transistor Qf with higher reliability.

In addition, according to the method for manufacturing the semiconductor device 1J according to the 10th embodiment, similarly to the above-described sixth embodiment, the respective head portions 37a, 38a₁, and 38b₁ of the gate electrode 37, the contact electrode 38a, and the contact electrode 38b have substantially the same height, and thus, when each of the dug portions 48a, 48b, and 48c is formed in the insulating film 46 by dry etching, the amount of over-etching can be reduced, so that the opening width of each dug portion can be reduced, and variation can be reduced. As a result, variations in contact resistance, wiring resistance, and wiring capacitance can be suppressed, and the semiconductor device 1J having excellent robustness can be provided.

Note that the field effect transistor Qf and the contact electrodes 38a and 38b according to the 10th embodiment can be applied to the solid-state imaging device 1I according to the above-described ninth embodiment. Also in this case, effects similar to those of the solid-state imaging device 1I according to the ninth embodiment described above can be obtained.

Furthermore, in the semiconductor device 1J according to the 10th embodiment, similarly to the semiconductor device 1G according to the seventh embodiment described above, the contact electrodes 49a, 49b, and 49c may be omitted, and each of the wirings 50a, 50b, and 50c may be directly connected to each of the contact electrodes 38a and 38b and the gate electrode 37.

### 11th Embodiment

### <<Application Example to Electronic Apparatus>>

The present technology (technology according to the present disclosure) can be applied to, for example, various electronic apparatuses such as an imaging device such as a digital still camera or a digital video camera, a mobile phone having an imaging function, or another apparatus having an imaging function.

FIG. 103 is a diagram illustrating a schematic configuration of an electronic apparatus (for example, a camera) according to the 10th embodiment of the present technology.

As illustrated in FIG. 103, the electronic apparatus 200 includes a solid-state imaging device 201, an optical lens 202, a shutter device 203, a drive circuit 204, and a signal processing circuit 205. The electronic apparatus 200 illustrates an embodiment in a case where the solid-state imaging device 1E according to the fifth embodiment of the present technology or the solid-state imaging device 1I according to the ninth embodiment is used as the solid-state imaging device 201 in an electronic apparatus (for example, a camera).

The optical lens 202 forms an image of image light (incident light 206) from a subject on an imaging surface of the solid-state imaging device 201. As a result, signal charges are accumulated in the solid-state imaging device 201 over a certain period. The shutter device 203 controls a light irradiation period and a light shielding period for the solid-state imaging device 201. The drive circuit 204 supplies a drive signal for controlling the transfer operation of the solid-state imaging device 201 and the shutter operation of the shutter device 203. A signal of the solid-state imaging device 201 is transferred by a drive signal (timing signal) supplied from the drive circuit 204. The signal processing circuit 205 performs various types of signal processing on a signal (pixel signal (image signal)) output from the solid-state imaging device 201. The video signal subjected to the signal processing is stored in a storage medium such as a memory or output to a monitor.

With such a configuration, in the electronic apparatus 200 according to the 11th embodiment, the transconductance of the pixel transistor is improved in the solid-state imaging device 201, so that image quality can be improved.

Note that the electronic apparatus 200 to which the solid-state imaging device of the above-described embodiment can be applied is not limited to the camera, and can also be applied to other electronic apparatuses. For example, the present invention may be applied to an imaging device such as a camera module for a mobile apparatus such as a mobile phone or a tablet terminal.

Furthermore, in addition to the solid-state imaging device as the image sensor described above, the present technology can be applied to all light detection devices including a distance measurement sensor that is called a time of flight (ToF) sensor and measures a distance or the like. The distance measurement sensor is a sensor that emits irradiation light toward an object, detects reflected light obtained by reflecting the irradiation light on a surface of the object, and calculates a distance to the object on the basis of a flight time from emission of the irradiation light to reception of the reflected light. The above-described structure of the element isolation region can be adopted as the structure of the element isolation region of the distance measurement sensor.

### Other Embodiments

In the above-described embodiment, the case where the field effect transistor is provided in the rectangular parallelepiped semiconductor portion extending in the Y direction has been described. However, the present technology is not limited to a rectangular parallelepiped semiconductor portion.

For example, the present technology can also be applied to a semiconductor device having a field effect transistor in which a channel formation portion and a gate electrode are provided at a corner portion of a semiconductor portion having an L-shaped planar shape.

Furthermore, in the first to 10th embodiments described above, the island-shaped semiconductor portions 3 and 33 provided on the first insulating films 2 and 32 have been described as the semiconductor portions to which the contact electrodes are connected. However, the present technology is not limited to the island-shaped semiconductor portions 3 and 33 provided on the insulating films 2 and 22.

For example, the present technology can also be applied to a case where a contact electrode is connected to an island-shaped semiconductor portion protruding integrally with a base portion constituted by a semiconductor.

Note that the present technology may have the following configuration.
(1)

A semiconductor device including:
a semiconductor portion having an island shape having an upper surface portion and a side surface portion;
a field effect transistor having a gate electrode provided on the semiconductor portion with a gate insulating film interposed therebetween;
an insulating layer covering the field effect transistor; and
a contact electrode provided on the insulating layer to overlap the semiconductor portion outside the gate electrode in plan view,
in which the contact electrode is connected to the upper surface portion and the side surface portion of the semiconductor portion.
(2)

The semiconductor device according to (1), in which the gate electrode is provided over the upper surface portion and the side surface portion in a first direction of the semiconductor portion, and
the contact electrode is located closer to the gate electrode than an end portion of the semiconductor portion in a second direction intersecting the first direction.
(3)

The semiconductor device according to (2), in which the contact electrode is connected to at least one of two of the side surface portion located on opposite sides in the first direction of the semiconductor portion.
(4)

The semiconductor device according to any one of (1) to (3), in which the semiconductor portion further includes a lower surface portion opposite to the upper surface portion, and
the contact electrode is also connected to the lower surface portion.
(5)

The semiconductor device according to any one of (2) to (4), in which the field effect transistor further includes a sidewall spacer provided on a sidewall of the gate electrode, and
in the first direction of the semiconductor portion, a width of the contact electrode is narrower than a width including the gate electrode and the sidewall spacers on both sides of the gate electrode.
(6)

The semiconductor device according to any one of (1) to (7), further including a through contact electrode that penetrates the insulating layer and is provided on an outer side of the semiconductor portion in the first direction to be adjacent to the contact electrode,
in which the contact electrode is connected to the side surface portion of the semiconductor portion on a side opposite to a side of the through contact electrode.
(7)

The semiconductor device according to any one of (1) to (6), in which the field effect transistor further includes a pair of main electrode regions provided on the semiconductor portion on both sides of the gate electrode in a gate length direction, and
the contact electrode is electrically connected to one main electrode region of the pair of main electrode regions.
(8)

The semiconductor device according to any one of (1) to (7), further including: a photoelectric conversion unit; and a pixel circuit that converts a signal charge photoelectrically converted by the photoelectric conversion unit into a pixel signal,
in which at least one of a plurality of pixel transistors included in the pixel circuit is configured by the field effect transistor.
(9)

The semiconductor device according to (8), further including a semiconductor layer arranged to overlap the semiconductor portion in plan view and provided with the photoelectric conversion unit.
(10)

A semiconductor device including: a semiconductor portion having an island shape having an upper surface portion and a side surface portion;
a field effect transistor having a gate electrode provided on the semiconductor portion with a gate insulating film interposed therebetween;
an insulating layer covering the field effect transistor; and
a contact electrode provided on the insulating layer to overlap the semiconductor portion outside the gate electrode in plan view,
in which the contact electrode is connected to the upper surface portion and the side surface portion of the semiconductor portion, and is formed in a same layer as the gate electrode.
(11)

The semiconductor device according to (10), in which the semiconductor portion is constituted by a single crystal, and
the contact electrode is constituted by a polycrystalline semiconductor material.
(12)

The semiconductor device according to (10) or (11), in which a plurality of insulators is scattered between the semiconductor portion and the contact electrode.
(13)

The semiconductor device according to any one of (10) to (12), in which the gate insulating film is selectively provided between a side of the gate electrode of the contact electrode and the semiconductor portion over the upper surface portion and the side surface portion.
(14)

The semiconductor device according to any one of (10) to (13), in which the gate electrode and the contact electrode have same thickness at a portion overlapping the semiconductor portion in plan view.
(15)

The semiconductor device according to any one of (10) to (14), in which the gate electrode is provided over the upper surface portion and the side surface portion in a first direction of the semiconductor portion, and
the contact electrode is located closer to the gate electrode than an end portion of the semiconductor portion in a second direction intersecting the first direction.
(16)

The semiconductor device according to (15), in which the contact electrode is connected to at least one of two of the side surface portion located on opposite sides in the first direction of the semiconductor portion.
(17)

The semiconductor device according to any one of (1) to (16), in which the semiconductor portion further includes a lower surface portion opposite to the upper surface portion, and
the contact electrode is also connected to the lower surface portion.
(18)

The semiconductor device according to any one of (10) to (17), in which the contact electrode is a first contact electrode,
the semiconductor device further including a second contact electrode connected to the first contact electrode while overlapping the first contact electrode in the plan view.
(19)

The semiconductor device according to any one of (10) to (18), in which a wiring provided on a side opposite to a side of the semiconductor portion of the insulating layer is connected to the contact electrode.
(20)

An electronic apparatus including:
a semiconductor device;
an optical lens that forms an image of image light from a subject on an imaging surface of the semiconductor device; and
a signal processing circuit that performs signal processing on a signal output from the semiconductor device,
the semiconductor device including:
a semiconductor portion having an island shape having an upper surface portion and a side surface portion;
a field effect transistor having a gate electrode provided on the upper surface portion and the side surface portion of the semiconductor portion with a gate insulating film interposed therebetween;
an insulating layer covering the field effect transistor; and
a contact electrode provided on the insulating layer to overlap the semiconductor portion outside the gate electrode in plan view,
in which the contact electrode is connected to the upper surface portion and the side surface portion of the semiconductor portion.

The scope of the present technology is not limited to the illustrated and described exemplary embodiments, but also includes all embodiments that provide equivalent effects to those for which the present technology is intended. Furthermore, the scope of the present technology is not limited to the combinations of the features of the invention defined by the claims, but may be defined by any desired combination of specific features among all the disclosed respective features.

### REFERENCE SIGNS LIST

1A, 1B, 1C, 1D, 1F, 1F₁, 1F₂, 1F₃, 1G, 1H, 1J Semiconductor device
1E, 1I Solid-state imaging device
2 First insulating film (base insulating film)
3 Semiconductor portion (first semiconductor layer)
3a Upper surface portion
3b Lower surface portion
3c₁, 3c₂, 3c₃, 3c₄ Side surface portion
4 Second insulating film (surrounding insulating film)
5a, 5b Dug portion (gate electrode dug portion)
6 Gate insulating film
7 Gate electrode
7a Head portion (first portion)
7b₁, 7b₂, 7b₃ Leg portion (second portion)
7X Gate material
8 Extension region
9 Sidewall spacer
10 Contact region
11a, 11b Main electrode region
12 Channel formation portion
13 Third insulating film (covering insulating film)
14 Insulating layer (including insulating layer)
15a, 15b, 15c Dug portion
16a, 16b, 16c Barrier metal film
17a, 17 b, 17c Contact electrode
22 Layer
23 Dug portion
24 Through contact electrode
32 First insulating film (base insulating film)
33 Semiconductor portion (first semiconductor layer)
33a Upper surface portion
33b Lower surface portion
33c₁, 3c₂, 3c₃, 3c₄ Side surface portion
33X Natural oxide film
33Y Oxide
34 Second insulating film (surrounding insulating film)
35a, 35b, 35c₁, 35c₂ Dug portion
36 Gate insulating film
37 Gate electrode
37a Head portion (first portion)
37b₁, 37b₂ Leg portion (second portion)
38a, 38b Contact electrode (first contact electrode)
38a₁, 38b₁ Head portion (first portion)
38a₂, 38b₂ Leg portion (second portion)
39a, 39b n-type semiconductor region
40a, 40b n-type semiconductor region (extension region)
41a, 41b, 41c Sidewall spacer
42 Buffer insulating film
43a, 43b n-type semiconductor region
44a, 44b Main electrode region
45 Channel formation portion
46 Third insulating film (covering insulating film)
47, 47J Insulating layer (including insulating layer)
48a, 48b, 48c Dug portion
49a, 49b, 49c Contact electrode (second contact electrode)
50a, 50b, 50c Wiring
102 Semiconductor chip
102A Pixel array unit
102B Peripheral portion
103 Pixel
104 Vertical drive circuit
105 Column signal processing circuit
106 Horizontal drive circuit
107 Output circuit
108 Control circuit
110 Pixel drive line
111 Vertical signal line
113 Logic circuit
114 Bonding pad
115 Pixel circuit
124 Photoelectric conversion unit
130 Semiconductor layer (second semiconductor layer)
131 Insulating layer
141 Planarization layer
142 Color filter layer
143 Lens layer
200 Electronic apparatus
201 Solid-state imaging device
202 Optical lens
203 Shutter device
204 Drive circuit
205 Signal processing circuit
206 Incident light

1. A semiconductor device comprising:
a semiconductor portion having an island shape having an upper surface portion and a side surface portion;
a field effect transistor having a gate electrode provided on the semiconductor portion with a gate insulating film interposed therebetween;
an insulating layer covering the field effect transistor; and
a contact electrode provided on the insulating layer to overlap the semiconductor portion outside the gate electrode in plan view,
wherein the contact electrode is connected to the upper surface portion and the side surface portion of the semiconductor portion.

2. The semiconductor device according to claim 1, wherein the gate electrode is provided over the upper surface portion and the side surface portion in a first direction of the semiconductor portion, and
the contact electrode is located closer to the gate electrode than an end portion of the semiconductor portion in a second direction intersecting the first direction.

3. The semiconductor device according to claim 2, wherein the contact electrode is connected to at least one of two of the side surface portion located on opposite sides in the first direction of the semiconductor portion.

4. The semiconductor device according to claim 1, wherein the semiconductor portion further includes a lower surface portion opposite to the upper surface portion, and
the contact electrode is also connected to the lower surface portion.

5. The semiconductor device according to claim 2, wherein the field effect transistor further includes a sidewall spacer provided on a sidewall of the gate electrode, and
in the first direction of the semiconductor portion, a width of the contact electrode is narrower than a width including the gate electrode and the sidewall spacers on both sides of the gate electrode.

6. The semiconductor device according to claim 1, further comprising a through contact electrode that penetrates the insulating layer and is provided on an outer side of the semiconductor portion in the first direction to be adjacent to the contact electrode,
wherein the contact electrode is connected to the side surface portion of the semiconductor portion on a side opposite to a side of the through contact electrode.

7. The semiconductor device according to claim 1, wherein the field effect transistor further includes a pair of main electrode regions provided on the semiconductor portion on both sides of the gate electrode in a gate length direction, and
the contact electrode is electrically connected to one main electrode region of the pair of main electrode regions.

8. The semiconductor device according to claim 1, further comprising: a photoelectric conversion unit; and a pixel circuit that converts a signal charge photoelectrically converted by the photoelectric conversion unit into a pixel signal,
wherein at least one of a plurality of pixel transistors included in the pixel circuit is configured by the field effect transistor.

9. The semiconductor device according to claim 8, further comprising a semiconductor layer arranged to overlap the semiconductor portion in plan view and provided with the photoelectric conversion unit.

10. A semiconductor device comprising: a semiconductor portion having an island shape having an upper surface portion and a side surface portion;
a field effect transistor having a gate electrode provided on the semiconductor portion with a gate insulating film interposed therebetween;
an insulating layer covering the field effect transistor; and
a contact electrode provided on the insulating layer to overlap the semiconductor portion outside the gate electrode in plan view,
wherein the contact electrode is connected to the upper surface portion and the side surface portion of the semiconductor portion, and is formed in a same layer as the gate electrode.

11. The semiconductor device according to claim 10, wherein the semiconductor portion is constituted by a single crystal, and
the contact electrode is constituted by a polycrystalline semiconductor material.

12. The semiconductor device according to claim 10, wherein a plurality of insulators is scattered between the semiconductor portion and the contact electrode.

13. The semiconductor device according to claim 10, wherein the gate insulating film is selectively provided between a side of the gate electrode of the contact electrode and the semiconductor portion over the upper surface portion and the side surface portion.

14. The semiconductor device according to claim 10, wherein the gate electrode and the contact electrode have same thickness at a portion overlapping the semiconductor portion in plan view.

15. The semiconductor device according to claim 10, wherein the gate electrode is provided over the upper surface portion and the side surface portion in a first direction of the semiconductor portion, and
the contact electrode is located closer to the gate electrode than an end portion of the semiconductor portion in a second direction intersecting the first direction.

16. The semiconductor device according to claim 15, wherein the contact electrode is connected to at least one of two of the side surface portion located on opposite sides in the first direction of the semiconductor portion.

17. The semiconductor device according to claim 10, wherein the semiconductor portion further includes a lower surface portion opposite to the upper surface portion, and
the contact electrode is also connected to the lower surface portion.

18. The semiconductor device according to claim 10, wherein the contact electrode is a first contact electrode,
the semiconductor device further comprising a second contact electrode connected to the first contact electrode while overlapping the first contact electrode in the plan view.

19. The semiconductor device according to claim 10, wherein a wiring provided on a side opposite to a side of the semiconductor layer of the insulating layer is connected to the contact electrode.

20. An electronic apparatus comprising:
a semiconductor device;
an optical lens that forms an image of image light from a subject on an imaging surface of the semiconductor device; and
a signal processing circuit that performs signal processing on a signal output from the semiconductor device,
the semiconductor device including:
a semiconductor portion having an island shape having an upper surface portion and a side surface portion;
a field effect transistor having a gate electrode provided on the upper surface portion and the side surface portion of the semiconductor portion with a gate insulating film interposed therebetween;
an insulating layer covering the field effect transistor; and
a contact electrode provided on the insulating layer to overlap the semiconductor portion outside the gate electrode in plan view,
wherein the contact electrode is connected to the upper surface portion and the side surface portion of the semiconductor portion.
